(19) United States
(12) Patent Application Publication
(10) Pub. No.: US 2025/0017109 A1
(43) Pub. Date: Jan. 9, 2025

(54) LIGHT-EMITTING DEVICE, LIGHT-EMITTING APPARATUS, ORGANIC COMPOUND, ELECTRONIC DEVICE, AND LIGHTING DEVICE

(71) Applicant: SEMICONDUCTOR ENERGY LABORATORY CO., LTD., Atsugi-shi, Kanagawa-ken (JP)

(72) Inventors: Akira NAGASAKA, Atsugi, Kanagawa (JP); Yuji IWAKI, Isehara, Kanagawa (JP); Sachiko KAWAKAMI, Atsugi, Kanagawa (JP); Tsunenori SUZUKI, Yokohama, Kanagawa (JP); Tatsuyoshi TAKAHASHI, Atsugi, Kanagawa (JP); Takuya HARUYAMA, Atsugi, Kanagawa (JP); Satoshi SEO, Sagamihara, Kanagawa (JP)

(21) Appl. No.: 18/708,907

(22) PCT Filed: Nov. 16, 2022
(86) PCT No.: PCT/IB2022/061007

§ 371 Date: May 9, 2024

(30) Foreign Application Priority Data
Nov. 26, 2021 (JP) 2021-192479

(51) Int. Cl. H10K 85/60; C07F 5/02; C09K 11/02; C09K 11/06; H10K 50/12

(52) U.S. Cl. CPC H10K 85/658; C07F 5/027; C09K 11/02; C09K 11/06; C09K 2211/1007; C09K 2211/1018; H10K 50/12

(57) ABSTRACT

A fluorescent light-emitting device using a host material that is less likely to form an oxygen adduct and having a high emission efficiency is provided. In addition, a highly reliable electronic device or light-emitting device is provided. A light-emitting device including at least a light-emitting layer between an anode and a cathode is provided. The light-emitting layer includes a first organic compound that is a light-emitting substance emitting fluorescent light and a second organic compound having a fluoranthene skeleton. The maximum peak wavelength of the first organic compound is λₘₐₓ (nm), and in the case where λₙ (nm) represents a wavelength of an intensity corresponding to 1/e of a maximum peak intensity in an emission spectrum of the first organic compound, λ₁ (nm) represents the shortest wavelength λₙ in a wavelength longer than the λₘₐₓ, and λ₂ (nm) represents the longest wavelength Ln in a wavelength shorter than λₘₐₓ, a difference between the λ₁ and the λ₂ is greater than or equal to 5 nm and less than or equal to 45 nm.

### TECHNICAL FIELD

An embodiment of the present invention relates to a light-emitting device, a light-emitting apparatus, an electronic device, and a lighting device. An embodiment of the present invention relates to an organic compound that can be used in a light-emitting device.

### BACKGROUND ART

A light-emitting device including an organic compound that is a light-emitting substance between a pair of electrodes (also referred to as an organic EL element) has characteristics such as thinness, light weight, high-speed response, and low-voltage drive; thus, displays including such light-emitting devices are under development. When a voltage is applied to the light-emitting device, electrons and holes injected from the electrodes recombine to put the light-emitting substance into an excited state, and then light is emitted in returning from the excited state to the ground state. The excited state can be a singlet excited state (S*) and a triplet excited state (T*): light emission from the singlet excited state is referred to as fluorescence, and light emission from the triplet excited state is referred to as phosphorescence. The statistical generation ratio thereof in the light-emitting device is estimated to be S*:T*=1:3.

Among light-emitting substances described above, a compound capable of converting singlet excitation energy into light emission is called a fluorescent compound (a fluorescent material), and a compound capable of converting triplet excitation energy into light emission is called a phosphorescent compound (a phosphorescent material).

Accordingly, on the basis of the above generation ratio, the theoretical limit of the internal quantum efficiency (the ratio of generated photons to injected carriers) of a light-emitting device using each of the above light-emitting substances is 25% in the case of using a fluorescent material and 75% in the case of using a phosphorescent material.

Since light-emitting layers of such light-emitting devices can be successively formed two-dimensionally, planar light emission can be obtained. This feature is difficult to realize with point light sources typified by incandescent lamps and LEDs or linear light sources typified by fluorescent lamps; thus, the light-emitting devices also have high value in use as planar light sources, which can be used for lighting and the like.

To improve device characteristics of the light-emitting devices, development of a substance, improvement of a device structure, and the like have been carried out. For example, Patent Document 1 discloses a light-emitting device or the like in which a novel anthracene derivative is used as a host material to obtain a light-emitting element with high emission efficiency.

### REFERENCE

### Patent Document

[Patent Document 1] Japanese Published Patent Application No. 2014-76999

### SUMMARY OF THE INVENTION

### Problems to be Solved by the Invention

As described above, for the improvement of the characteristics of light-emitting devices, organic compounds with characteristics suitable for light-emitting devices have been developed. In blue fluorescent light-emitting devices, for example, high emission efficiency can be obtained when an anthracene derivative is used as a host material; thus, many materials using an anthracene derivative have been developed. However, an anthracene skeleton easily results in formation of an oxygen adduct by reacting with oxygen in an oxygen-present environment. When oxygen is added to an anthracene skeleton, the characteristics of a light-emitting device using the anthracene derivative are decreased. Hence, one embodiment of the present invention provides a fluorescent light-emitting device with high emission efficiency by using a host material that is less likely to form an oxygen adduct. In addition, a fluorescent light-emitting device with high emission efficiency using a novel organic compound of one embodiment of the present invention is provided. Furthermore, a highly reliable light-emitting device is provided.

### Means for Solving the Problems

One embodiment of the present invention is a light-emitting device including at least a light-emitting layer between an anode and a cathode, and the light-emitting layer includes a first organic compound that is a light-emitting substance that emits fluorescent light and a second organic compound having a fluoranthene skeleton.

One embodiment of the present invention is a light-emitting device including at least a light-emitting layer between an anode and a cathode, the light-emitting layer includes a first organic compound that is a light-emitting substance emitting fluorescent light and a second organic compound having a fluoranthene skeleton. The maximum peak wavelength of the first organic compound is λₘₐₓ (nm), and in a case where λₙ (nm) represents a wavelength of an intensity corresponding to lie of a maximum peak intensity in an emission spectrum of the first organic compound, λ₁ (nm) represents the shortest wavelength λₙ in a wavelength longer than the λₘₐₓ, and λ₂ (nm) represents the longest wavelength λₙ in a wavelength shorter than λₘₐₓ, a difference between the λ₁ and the λ₂ is greater than or equal to 5 nm and less than or equal to 45 nm.

Another embodiment of the present invention is a light-emitting device including at least a light-emitting layer between an anode and a cathode, the light-emitting layer includes a first organic compound that is a light-emitting substance emitting fluorescent light and a second organic compound having a fluoranthene skeleton. The maximum peak wavelength of the first organic compound is λₘₐₓ (nm), and in a case where λₙ (nm) represents a wavelength of an intensity corresponding to 1/e of a maximum peak intensity in an emission spectrum of the first organic compound, λ₁ (nm) represents the shortest wavelength λₙ in a wavelength longer than the λₘₐₓ, and λ₂ (nm) represents the longest wavelength λₙ in a wavelength shorter than λₘₐₓ, a difference between the λ₁ and the λ₂ is greater than or equal to 5 nm and less than or equal to 45 nm, and the difference between an absorption peak located at the longest wavelength of the first organic compound and an emission peak located at the shortest wavelength of the first organic compound is 30 nm or less.

Another embodiment of the present invention is a light-emitting device in which the emission spectrum of the first organic compound is a photoluminescence spectrum of the first organic compound in a solution state.

Another embodiment of the present invention is a light-emitting device in which the absorption spectrum of the first organic compound is a photoluminescence spectrum of the first organic compound in the solution state.

Another embodiment of the present invention is a light-emitting device in which a solvent of the solution is toluene.

Another embodiment of the present invention is a light-emitting device in which the difference in wavelength between the absorption peak located at the longest wavelength of the first organic compound and the emission peak located at the shortest wavelength of the first organic compound is 16 nm or less.

Another embodiment of the present invention is a light-emitting device including at least a light-emitting layer between an anode and a cathode, the light-emitting layer includes a first organic compound that is a light-emitting substance emitting fluorescent light and a second organic compound having a fluoranthene skeleton, and the first organic compound is a heterocyclic compound including boron.

Another embodiment of the present invention is a light-emitting device including at least a light-emitting layer between an anode and a cathode, the light-emitting layer includes a first organic compound that is a light-emitting substance emitting fluorescent light and a second organic compound having a fluoranthene skeleton, and the first organic compound is represented by General Formula (G1).

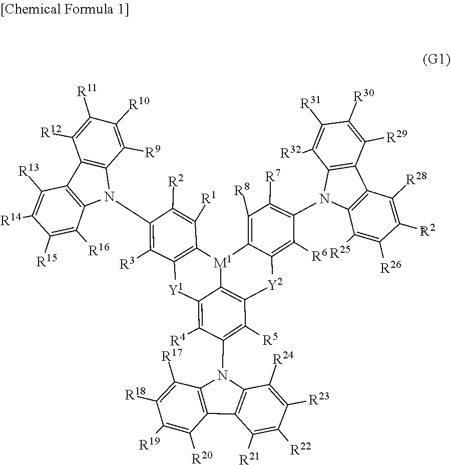

Note that in General Formula (G1) above, M¹ represents any one of boron, nitrogen, aluminum, gallium, indium, phosphorus, arsenic, silicon, germanium, tin, antimony, and bismuth, and phosphorus, antimony, or bismuth may form a double bond with oxygen or sulfur and may include a first substituent and a second substituent. The first substituent and the second substituent are each independently any one of a substituted or unsubstituted alkyl group having 1 to 10 carbon atoms, an alkoxy group having 1 to 10 carbon atoms, a substituted or unsubstituted cycloalkyl group having 3 to 10 carbon atoms, and a substituted or unsubstituted aryl group having 6 to 25 carbon atoms, carbon atoms of the two substituents (the first substituent and the second substituent) may be bonded to each other with a single bond or a double bond, and a condensed ring may be formed when the double bond is formed. In addition, silicon, germanium, or tin includes a third substituent, and the third substituent is any one of a substituted or unsubstituted alkyl group having 1 to 10 carbon atoms, an alkoxy group having 1 to 10 carbon atoms, a substituted or unsubstituted cycloalkyl group having 3 to 10 carbon atoms, and a substituted or unsubstituted aryl group having 6 to 25 carbon atoms. In addition, Y¹ and Y² each independently represent any one of oxygen, sulfur, and nitrogen: when the Y¹ and the Y² are nitrogen, the nitrogen includes a fourth substituent; the fourth substituent is any one of a substituted or unsubstituted aryl group having 6 to 25 carbon atoms and a substituted or unsubstituted heteroaryl group having 1 to 25 carbon atoms: when the aryl group or the heteroaryl group includes a substituent, the aryl group or the heteroaryl group may include a plurality of substituents; the plurality of substituents each independently represent any of deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms. Moreover, R¹ to R¹² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms; and R¹ and R⁸ may be directly bonded to each other: when R¹ and R⁸ are directly bonded to each other, one of R¹ and R⁸ is oxygen, sulfur, or nitrogen including a substituent; when one of R¹ and R⁸ is oxygen, an ether bond is formed; when one of R¹ and R⁸ is sulfur, a thioether bond is formed; or when one of R¹ and R⁸ is nitrogen, a secondary or tertiary amine is formed; and nitrogen may include a substituted or unsubstituted alkyl group having 3 to 10 carbon atoms, a substituted or unsubstituted cycloalkyl group having 3 to 10 carbon atoms, a substituted or unsubstituted aryl group having 6 to 25 carbon atoms, a substituted or unsubstituted heteroaryl group having 1 to 25 carbon atoms, hydrogen, or deuterium.

Another embodiment of the present invention is a light-emitting device including at least a light-emitting layer between an anode and a cathode, and the light-emitting layer includes a first organic compound that is a light-emitting substance emitting fluorescent light and a second organic compound having a fluoranthene skeleton, and the first organic compound is represented by General Formula (G2).

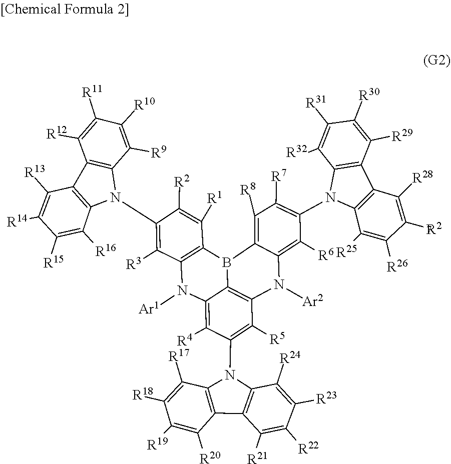

In General Formula (G2), Ar¹ and Ar² each independently represent any one of a substituted or unsubstituted aryl group having 6 to 25 carbon atoms and a substituted or unsubstituted heteroaryl group having 3 to 30 carbon atoms; when Ar¹ and Ar² each include a substituent, the substituent represents deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, or a substituted or unsubstituted aryl group having 6 to 25 carbon atoms. R¹ to R⁸ each independently represent any one of hydrogen and deuterium, and R⁹ to R¹² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

Another embodiment of the present invention is a light-emitting device including at least a light-emitting layer between an anode and a cathode, the light-emitting layer includes a first organic compound that is a light-emitting substance emitting fluorescent light and a second organic compound having a fluoranthene skeleton, and the first organic compound is represented by any one of Structural Formula (100) to Structural Formula (105).

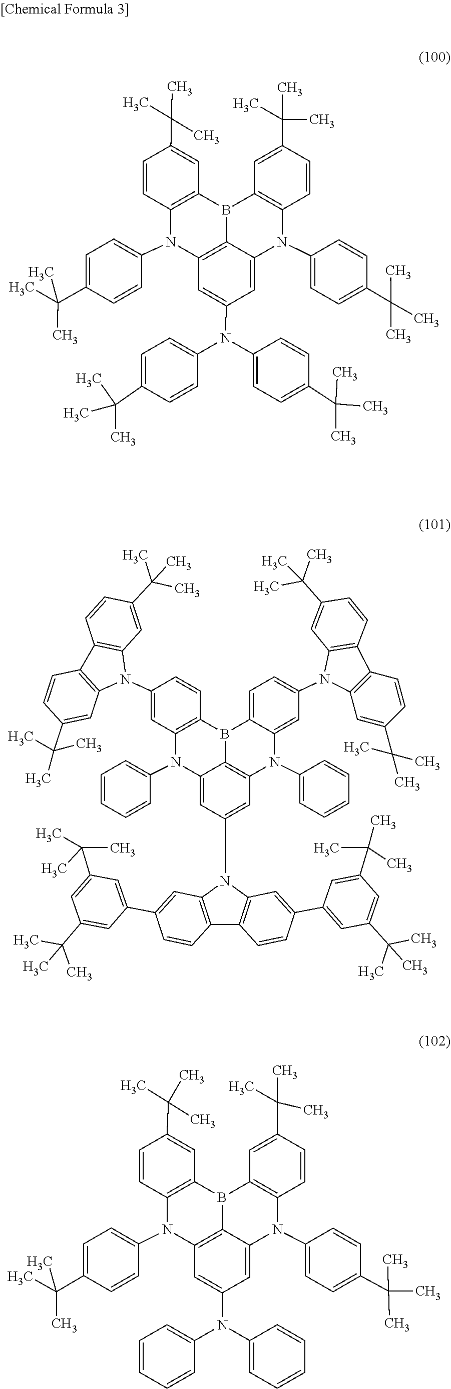

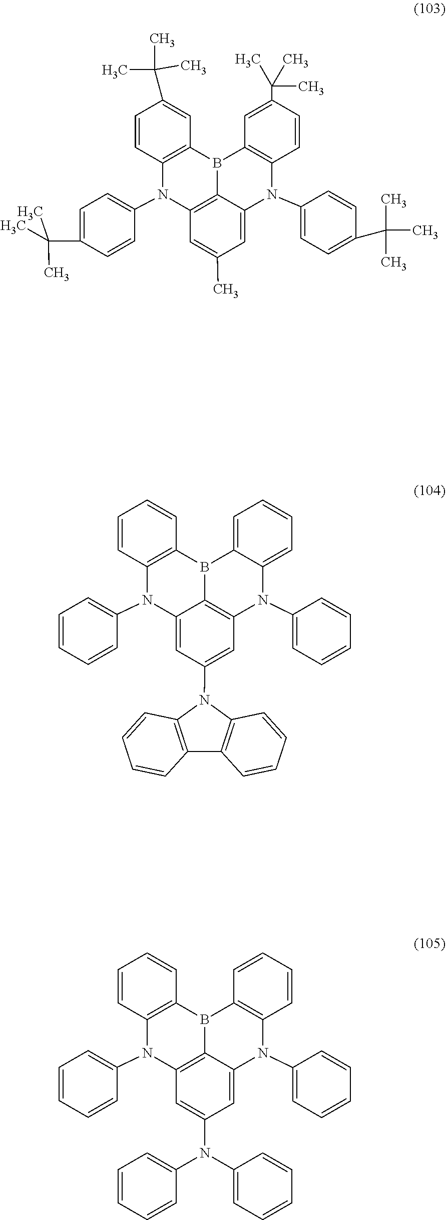 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; c1ccc(N2c3ccccc3B3c4ccccc4N(c4ccccc4)c4cc(-n5c6ccccc6c6ccccc65)cc2c43)cc1 ; c1ccc(N(c2ccccc2)c2cc3c4c(c2)N(c2ccccc2)c2ccccc2B4c2ccccc2N3c2ccccc2)cc1]

Another embodiment of the present invention is a light-emitting device in which the difference between a lowest singlet excitation energy level and a lowest triplet excitation energy level of the first organic compound is 0.3 eV or greater.

Another embodiment of the present invention is a light-emitting device in which the first organic compound emits blue light.

Another embodiment of the present invention is a light-emitting device in which the second organic compound includes a condensed aromatic ring or a condensed heteroaromatic ring.

Another embodiment of the present invention is a light-emitting apparatus including the light-emitting device described in any one of the above structures and a transistor or a substrate.

Another embodiment of the present invention is an organic compound represented by General Formula (G3).

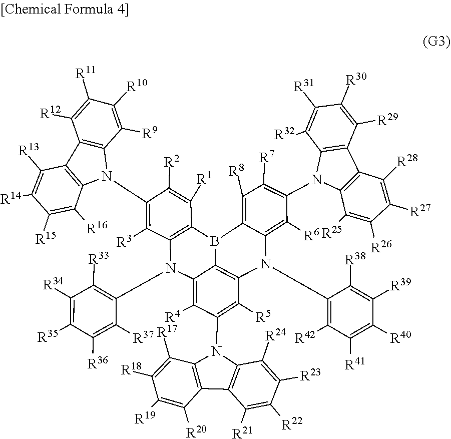

Note that in General Formula (G3), R¹ to R⁸ and R³³ to R⁴² each independently represent any one of hydrogen and deuterium, and R⁹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

Another embodiment of the present invention is a light-emitting device including the organic compound represented by General Formula (G3).

Another embodiment of the present invention is an organic compound represented by Structural Formula (100).

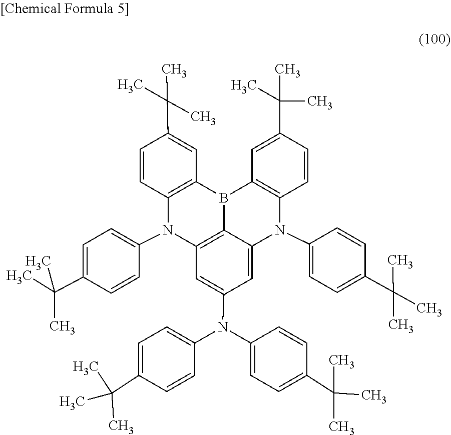 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1]

Another embodiment of the present invention is a light-emitting device including the organic compound represented by Structural Formula (100).

Another embodiment of the present invention is a light-emitting apparatus including the light-emitting device described in any one of the above structures and a transistor or a substrate.

Another embodiment of the present invention is an electronic device including the light-emitting apparatus described in any one of the above structures and a detecting portion, an input portion, or a communication portion.

Another embodiment of the present invention is a lighting device including the light-emitting apparatus described in any one of the above structures and a housing.

### Effect of the Invention

According to one embodiment of the present invention, a fluorescent light-emitting device with high emission efficiency can be provided which uses a host material in which an oxygen adduct is less likely to be formed. In addition, a fluorescent light-emitting device with high emission efficiency can be provided by using a novel organic compound of one embodiment of the present invention. A light-emitting device having high reliability can be provided. In addition, a light-emitting device emitting fluorescent light with high emission efficiency can be provided by using a novel organic compound of one embodiment of the present invention. Moreover, a light-emitting device, a light-emitting apparatus, an electronic device, or a lighting device with low power consumption can be provided.

### BRIEF DESCRIPTION OF THE DRAWINGS

FIG. 1A to FIG. 1C are diagrams illustrating structures of light-emitting devices of an embodiment.

FIG. 2A to FIG. 2E are diagrams illustrating structures of light-emitting devices according to an embodiment.

FIG. 3A to FIG. 3D are diagrams illustrating a light-emitting apparatus according to an embodiment.

FIG. 4A to FIG. 4C are diagrams illustrating a method for manufacturing a light-emitting apparatus according to an embodiment.

FIG. 5A to FIG. 5C are diagrams illustrating the method for manufacturing the light-emitting apparatus according to the embodiment.

FIG. 6A to FIG. 6C are diagrams illustrating the method for manufacturing the light-emitting apparatus according to the embodiment.

FIG. 7A to FIG. 7D are diagrams illustrating the method for manufacturing the light-emitting apparatus according to the embodiment.

FIG. 8A to FIG. 8E are diagrams illustrating the method for manufacturing the light-emitting apparatus according to the embodiment.

FIG. 9A to FIG. 9F are diagrams illustrating an apparatus and pixel arrangements according to an embodiment.

FIG. 10A to FIG. 10C are diagrams illustrating pixel circuits according to an embodiment.

FIG. 11 is a diagram illustrating a light-emitting apparatus according to an embodiment.

FIG. 12A to FIG. 12E are diagrams illustrating electronic devices according to an embodiment.

FIG. 13A to FIG. 13E are diagrams illustrating electronic devices according to an embodiment.

FIG. 14A and FIG. 14B are diagrams illustrating electronic devices according to an embodiment.

FIG. 15A and FIG. 15B are diagrams illustrating a lighting apparatus according to an embodiment.

FIG. 16 is a diagram illustrating a lighting apparatus according to an embodiment.

FIG. 17A to FIG. 17C are diagrams illustrating a light-emitting device and a light-receiving device according to an embodiment.

FIG. 18A and FIG. 18B are diagrams illustrating a light-emitting device and a light-emitting device according to an embodiment.

FIG. 19 is a diagram illustrating the structure of a sample.

FIG. 20 is a diagram showing analysis results of samples in Example.

FIG. 21 is a diagram showing analysis results of samples in Example.

FIG. 22 is a diagram showing analysis results of samples in Example.

FIG. 23 shows absorption and emission spectra of BD-1 in a toluene solution.

FIG. 24 is a diagram illustrating a structure of a light-emitting device in Example.

FIG. 25 is a graph showing luminance-current density characteristics of light-emitting devices in Example.

FIG. 26 is a graph showing current efficiency-luminance characteristics of light-emitting devices in Example.

FIG. 27 is a graph showing luminance-voltage characteristics of light-emitting devices in Example.

FIG. 28 is a diagram illustrating current density-voltage characteristics of light-emitting devices in Example.

FIG. 29 is a graph showing external quantum efficiency-luminance characteristics of light-emitting devices in Example.

FIG. 30 is a diagram illustrating emission spectra of light-emitting devices in Example.

FIG. 31 is a diagram illustrating temporal changes in luminance of light-emitting devices in Example.

### MODE FOR CARRYING OUT THE INVENTION

### Embodiment 1

In this embodiment, a light-emitting device of one embodiment of the present invention will be described.

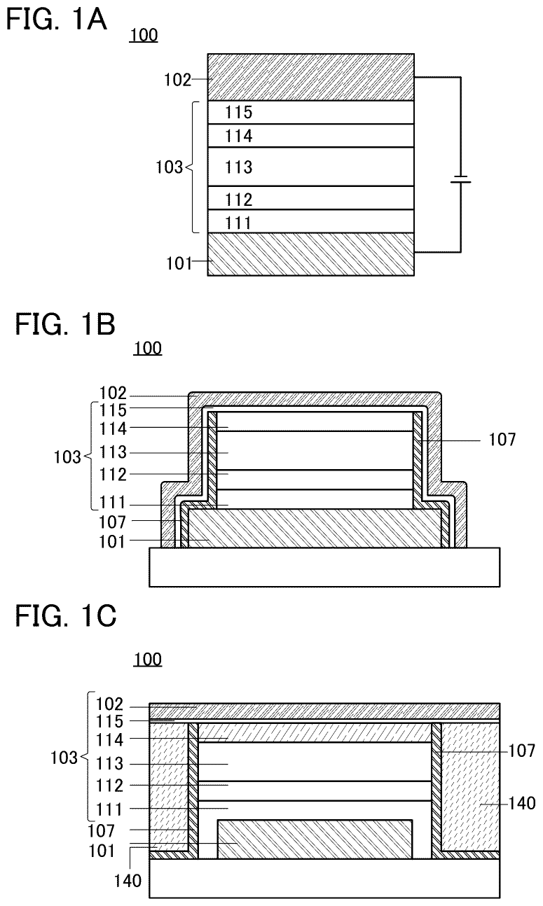

FIG. 1A illustrates a structure of a light-emitting device 100 of one embodiment of the present invention. As illustrated in FIG. 1A, the light-emitting device 100 includes a first electrode 101, a second electrode 102, and between the first electrode 101 and the second electrode 102, an EL layer 103 in which a hole-injection layer 111, a hole-transport layer 112, a light-emitting layer 113, an electron-transport layer 114, and an electron-injection layer 115 are sequentially stacked.

The light-emitting layer 113 includes at least a light-emitting substance. In one embodiment of the present invention, a first organic compound that is a light-emitting substance and a second organic compound having a fluoranthene skeleton are preferably used for the light-emitting layer 113.

Note that the first organic compound is preferably a light-emitting substance with a narrow emission spectrum width. Specifically, it is preferable to use a light-emitting substance having an emission spectrum where the distance between two points at an intensity corresponding to 1/e (e is the base of a natural logarithm) of the maximum peak intensity of the emission spectrum is greater than or equal to 5 nm and less than or equal to 45 nm, preferably greater than or equal to 5 nm and less than or equal to 35 nm. In addition, the maximum peak (local maximum value) is preferably located in the range of greater than or equal to 420 nm and less than or equal to 550 nm in wavelength, further preferably greater than or equal to 420 nm and less than or equal to 500 nm in wavelength, still further preferably greater than or equal to 450 nm and less than or equal to 460 nm in wavelength.

In the light-emitting device including a light-emitting substance having a narrow emission spectrum, employing a microcavity structure enables efficient light amplification, resulting in favorable external quantum efficiency. In particular, in one embodiment of the present invention, the amplification effect due to the microcavity structure can be significantly increased also by using a low refractive index layer.

Note that a half width is one of indices that are used to express the shape of a peak in an emission spectrum. Although the half width of the emission spectrum is represented by the distance between two points at the intensity corresponding to half the peak intensity at the local maximum value, the emission spectrum of an organic compound often has a plurality of emission components; hence, in some cases, the half width does not accurately reflect the influence of the peak shape in some cases.

For example, in the case where light emitted from a light-emitting substance has a mix of emission components derived from two vibration levels and accordingly includes an emission component P1 having the highest intensity and an emission component P2 having a lower intensity than the emission component P1, the emission spectrum of the light-emitting substance has a shape in which P1 and P2 are added. In such a case, when the intensity of P2 is smaller than half the intensity of P1, the half width is less likely to reflect P2.

However, P2 has a broader spectrum than P1 in some cases; thus, when a light-emitting device containing a light-emitting substance that exhibits such an emission spectrum employs a microcavity structure using a low refractive index layer, a large amount of light is attenuated. Therefore, even in the case of using a light-emitting substance with a small half width, the effect of increasing the efficiency may be small because of the influence of P2; hence, there is a large difference in efficiency between light-emitting substances having similar half widths.

Thus, in one embodiment of the present invention, the distance between two points at the intensity corresponding to 1/e of the maximum peak intensity of an emission spectrum (specifically a difference between λ₁ and λ₂, where λₙ (nm) represents a wavelength at the intensity corresponding to 1/e of the maximum peak intensity, λ₁ (nm) represents the shortest wavelength λₙ in a wavelength longer than the maximum peak wavelength λₘₐₓ (nm) of the light-emitting substance, and λ₂ (nm) represents the longest wavelength λₙ in a wavelength shorter than λₘₐₓ) is also used as an indicator expressing a peak shape in an optical spectrum.

Specifically, it is preferable to use a light-emitting substance with an emission spectrum where the distance (λ₁-λ₂) between the two points at the intensity corresponding to 1/e of the maximum peak intensity is greater than or equal to 5 nm and less than or equal to 45 nm, preferably greater than or equal to 5 nm and less than or equal to 35 nm. It is further preferable to use a light-emitting substance with an emission spectrum where the distance between the two points at the intensity corresponding to 1/e of the maximum peak intensity is greater than or equal to 5 nm and less than or equal to 45 nm, preferably greater than or equal to 5 nm and less than or equal to 35 nm and the half width is greater than or equal to 5 nm and less than or equal to 25 nm.

Note that the width of the wavelength can also be expressed by being converted into energy. That is, a preferred light-emitting substance that can be favorably used in one embodiment of the present invention is a light-emitting substance having an energy difference greater than or equal to 0.03 eV and less than or equal to 0.27 eV, which is obtained by converting the two points at the intensity corresponding to lie of the maximum peak intensity of the emission spectrum to energies. It is further preferable to use a light-emitting substance in which the distance between the two points at the intensity corresponding to 1/e of the maximum peak intensity into energy is greater than or equal to 0.03 eV and less than or equal to 0.27 eV and the half width is greater than or equal to 0.03 eV and less than or equal to 0.15 eV.

Note that the width of the emission spectrum can be calculated using a photoluminescence spectrum of a light-emitting substance in a solution state. Since the relative permittivity of the organic compound included in the EL layer of the light-emitting device is approximately 3, in order to reduce as much as possible inconsistency with the emission spectrum in the case of being used in the light-emitting device, the relative permittivity of the solvent for bringing the light-emitting substance into a solution state is preferably greater than or equal to 1 and less than or equal to 10, further preferably greater than or equal to 2 and less than or equal to 5 at room temperature. Specific examples include hexane, benzene, toluene, diethyl ether, ethyl acetate, chloroform, chlorobenzene, and dichloromethane. A solvent that has a relative permittivity greater than or equal to 2 and less than or equal to 5 at room temperature, has high solubility, and is versatile is further preferred, especially, toluene and chloroform are preferred, for example.

As the first organic compound, it is preferable to use an organic compound where a difference (ΔE_{ST}) between the lowest singlet excitation energy level and the lowest triplet excitation energy level is 0.3 eV or larger. Thus, the EL layer 103 can emit fluorescent light.

An emission spectrum obtained from the organic compound used as a light-emitting substance and the organometallic complex is a band spectrum with high intensity with respect to a particular wavelength of the substance. Since a color filter cuts off light other than light with a desired wavelength and a microcavity structure amplifies light with a desired wavelength and diminishes light with the other wavelengths, light with a broad spectrum tends to result in a significant energy loss.

Thus, the first organic compound with a narrow emission spectrum width and the second organic compound having a maximum peak intensity of an emission spectrum that is close to that of the first organic compound are used, whereby the broad width of light emitted from the device can be reduced. Furthermore, in the case where the difference between the absorption peak located at the longest wavelength and the emission peak located at the shortest wavelength of the first organic compound is small, the broad width can be further reduced; thus, the above energy loss can be reduced, so that a light-emitting device with high emission efficiency can be obtained.

Thus, the difference between the absorption peak located at the longest wavelength and the emission peak located at the shortest wavelength of the first organic compound is preferably less than or equal to 30 nm.

A light-emitting device using a light-emitting material with a small difference between the absorption peak located at the longest wavelength and the emission peak located at the shortest wavelength and a narrow emission spectrum width can exhibit light emission with high color purity.

### <First Organic Compound>

Specifically, an organic compound represented by General Formula (Gx) can also be used as the first organic compound.

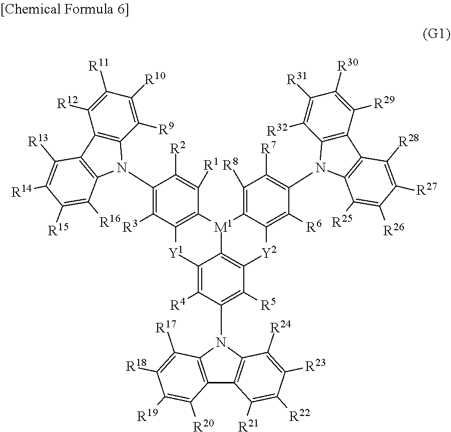

In General Formula (G1) above, M¹ represents any one of boron, nitrogen, aluminum, gallium, indium, phosphorus, arsenic, silicon, germanium, tin, antimony, and bismuth. Phosphorus, antimony, or bismuth may form a double bond with oxygen or sulfur and may include a first substituent and a second substituent. The first substituent and the second substituent are each independently any one of a substituted or unsubstituted alkyl group having 1 to 10 carbon atoms, an alkoxy group having 1 to 10 carbon atoms, a substituted or unsubstituted cycloalkyl group having 3 to 10 carbon atoms, and a substituted or unsubstituted aryl group having 6 to 25 carbon atoms, carbon atoms of the two substituents (the first substituent and the second substituent) may be bonded to each other with a single bond or a double bond, and a condensed ring may be formed when the double bond is formed. In addition, silicon, germanium, or tin includes a third substituent, and the third substituent is any one of a substituted or unsubstituted alkyl group having 1 to 10 carbon atoms, an alkoxy group having 1 to 10 carbon atoms, a substituted or unsubstituted cycloalkyl group having 3 to 10 carbon atoms, and a substituted or unsubstituted aryl group having 6 to 25 carbon atoms. In addition, Y¹ and Y² each independently represent any one of oxygen, sulfur, and nitrogen: when the Y¹ and the Y² are nitrogen, the nitrogen includes a fourth substituent; the fourth substituent is any one of a substituted or unsubstituted aryl group having 6 to 25 carbon atoms and a substituted or unsubstituted heteroaryl group having 1 to 25 carbon atoms: when the aryl group or the heteroaryl group includes a substituent, the aryl group or the heteroaryl group may include a plurality of substituents; the plurality of substituents each independently represent any of deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms. Moreover, R¹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms; and R¹ and R⁸ may be directly bonded to each other: when R¹ and R⁸ are directly bonded to each other, one of R¹ and R⁸ is oxygen, sulfur, or nitrogen including a substituent; when one of R¹ and R⁸ is oxygen, an ether bond is formed; when one of R¹ and R⁸ is sulfur, a thioether bond is formed; or when one of R¹ and R⁸ is nitrogen, a secondary or tertiary amine is formed; and nitrogen may include a substituted or unsubstituted alkyl group having 3 to 10 carbon atoms, a substituted or unsubstituted cycloalkyl group having 3 to 10 carbon atoms, a substituted or unsubstituted aryl group having 6 to 25 carbon atoms, a substituted or unsubstituted heteroaryl group having 1 to 25 carbon atoms, hydrogen, or deuterium.

Further preferably, an organic compound represented by General Formula (G2) below can be used as the first organic compound.

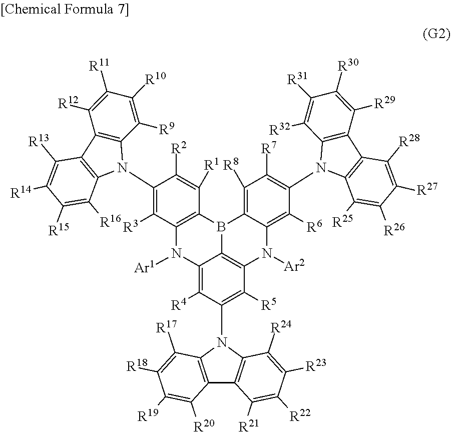

In General Formula (G2) above, Ar¹ and Ar² each independently represent any one of a substituted or unsubstituted aryl group having 6 to 25 carbon atoms and a substituted or unsubstituted heteroaryl group having 3 to 30 carbon atoms. In the case where the above Ar¹ and Ar² each include a substituent, the substituent represents deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, or a substituted or unsubstituted aryl group having 6 to 25 carbon atoms. R¹ to R⁸ each independently represent any one of hydrogen and deuterium. R⁹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

Further preferably, an organic compound represented by General Formula (G3) below can be used as the first organic compound.

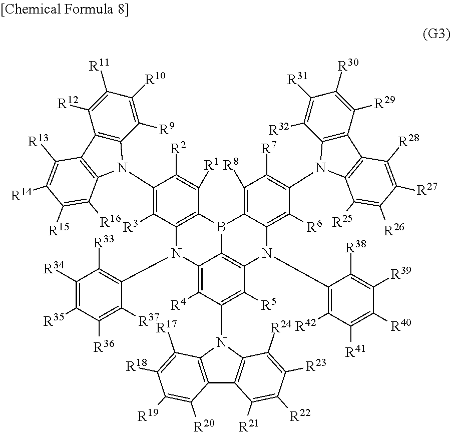

In General Formula (G3) above, R¹ to R⁸ and R³³ to R⁴² each independently represent any one of hydrogen and deuterium. R⁹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

In General Formula (G1) and General Formula (G2) above, examples of the substituted or unsubstituted aryl group having 6 to 25 carbon atoms include benzene, naphthalene, phenanthrene, anthracene, stilbene, fluorene, chrysene, triphenylene, tetracene, pyrene, perylene, fluoranthene, and spirobifluorene.

In General Formula (G1) and General Formula (G2) above, examples of the substituted or unsubstituted heteroaryl group having 3 to 30 carbon atoms include triazine, pyridazine, pyrimidine, pyrazine, pyridine, quinoline, quinoxaline, quinazoline, acridine, acridone, phenoxazine, phenothiazine, coumarin, quinacridone, dibenzofuran, dibenzothiophene, carbazole, and naphthobisbenzofuran.

In General Formula (G1), General Formula (G2), and General Formula (G3) above, specific examples of the substituted or unsubstituted alkyl group having 3 to 10 carbon atoms include a propyl group, an isopropyl group, a butyl group, a tert-butyl group, an isobutyl group, a sec-butyl group, a pentyl group, a hexyl group, an octyl group, and a decanyl group.

In General Formula (G1), General Formula (G2), and General Formula (G3) above, examples of the substituted or unsubstituted cycloalkyl group having 3 to 10 carbon atoms include a cyclopropyl group, a cyclobutyl group, a cyclopentyl group, a cyclohexyl group, an adamantyl group, a bicyclo[2.2.1]heptyl group, a tricyclo[5.2.1.0^{2,6}]decanyl group, and a noradamantyl group.

In General Formula (G1), General Formula (G2), and General Formula (G3) above, specific examples of the substituted or unsubstituted trialkylsilyl group having 3 to 12 carbon atoms include a trimethylsilyl group, a triethylsilyl group, and a tert-butyl dimethylsilyl group.

In General Formula (G1), General Formula (G2), and General Formula (G3) above, examples of the substituted or unsubstituted aryl group having 6 to 25 carbon atoms include a phenyl group, a naphthyl group, an anthryl group, a phenanthrenyl group, a triphenylenyl group, a pyrenyl group, a biphenyl group, a fluorenyl group, a fluoranthenyl group, and a spirobifluorenyl group.

Specific structures of the first organic compound represented by General Formula (G1) to General Formula (G3) above are shown in Structural Formula (100) to Structural Formula (165).

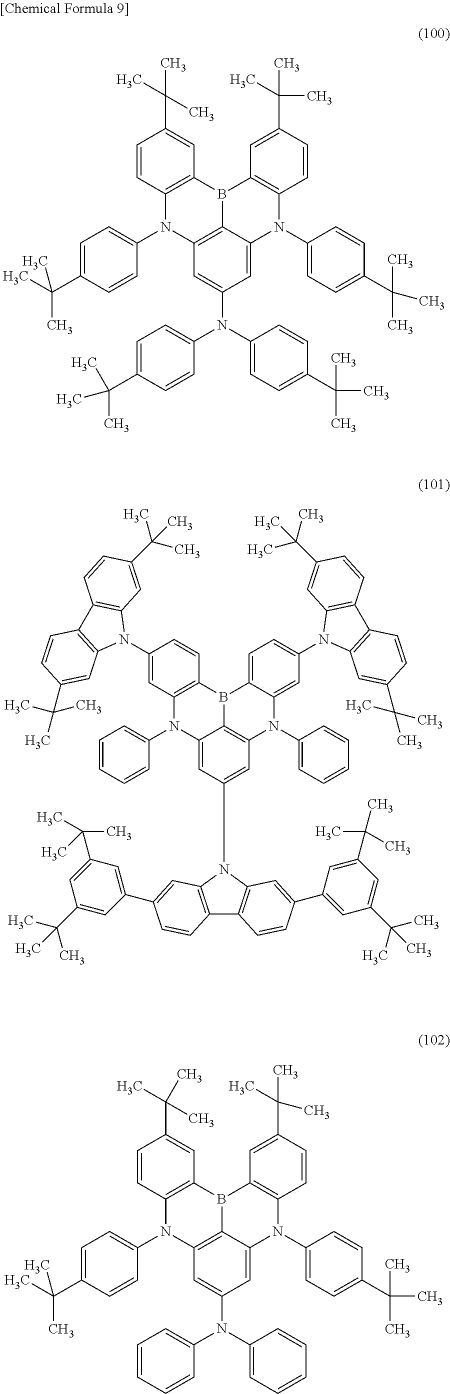

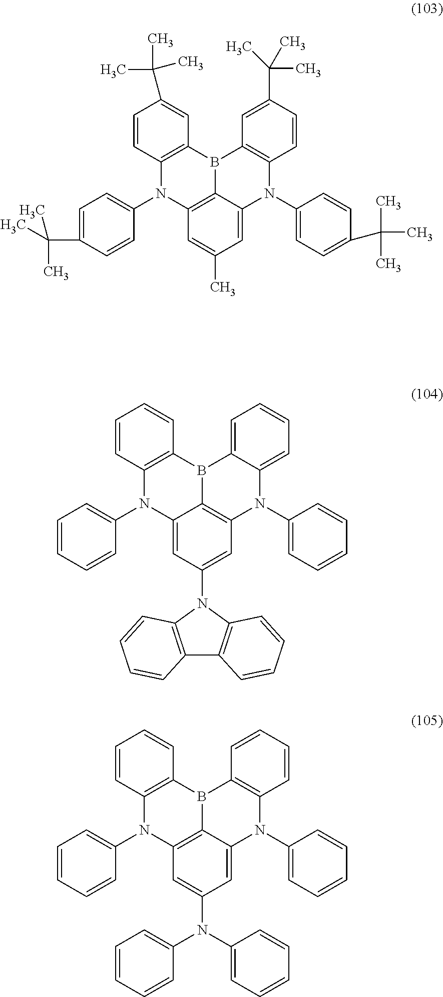

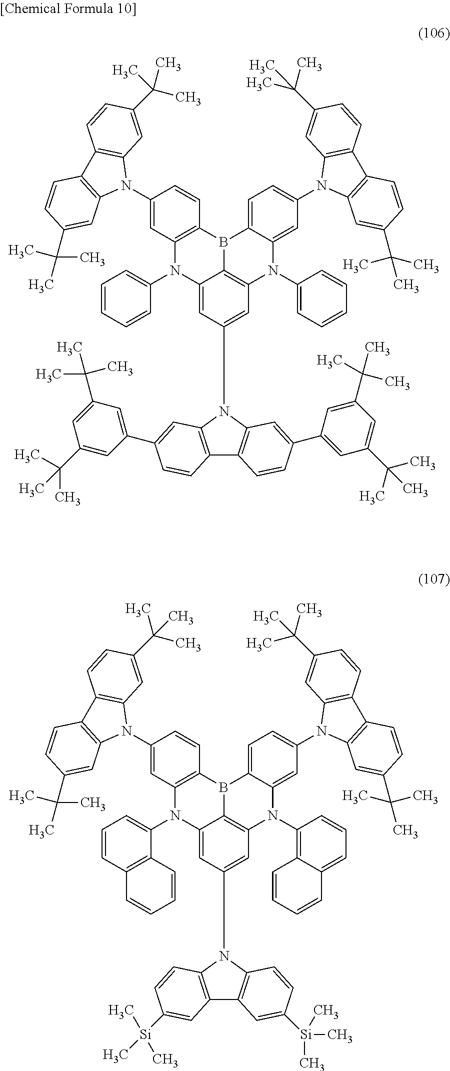

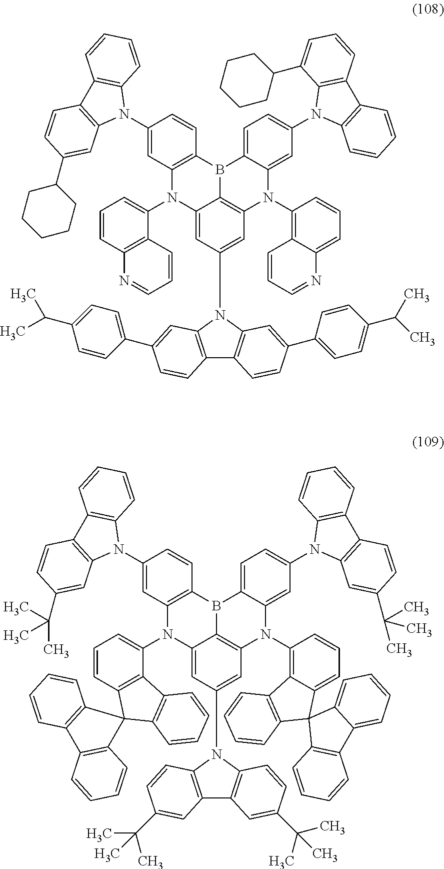

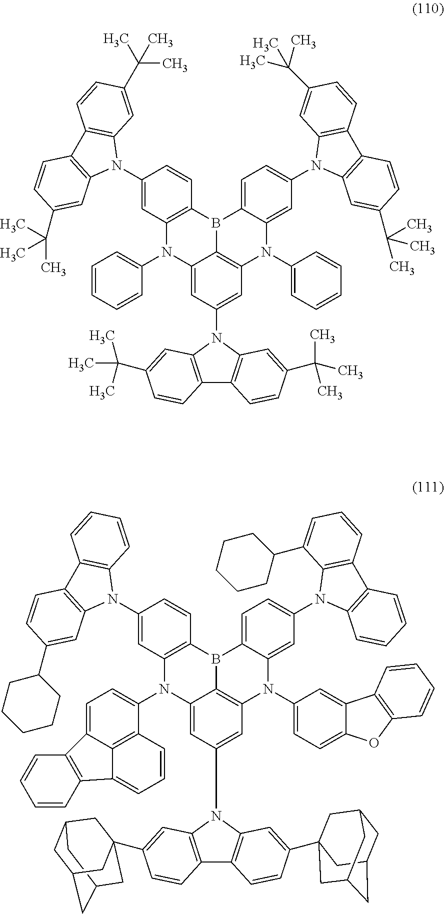

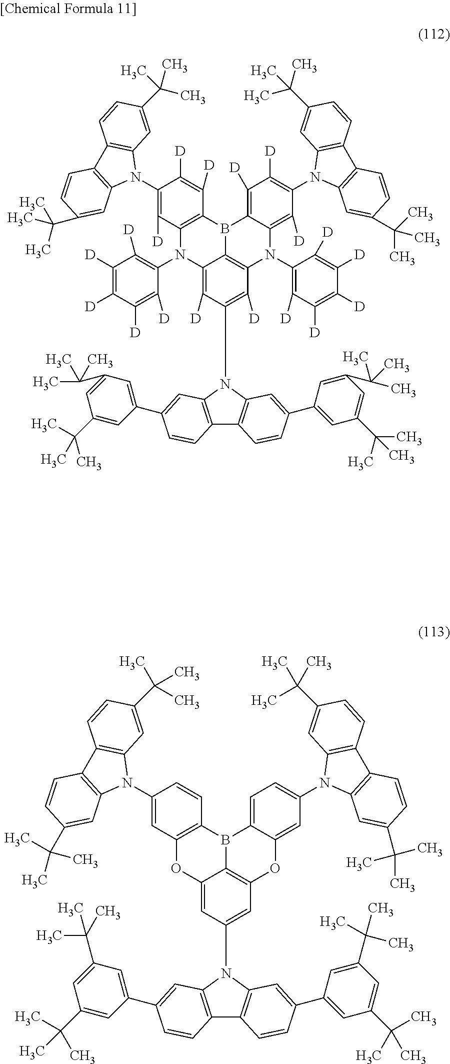

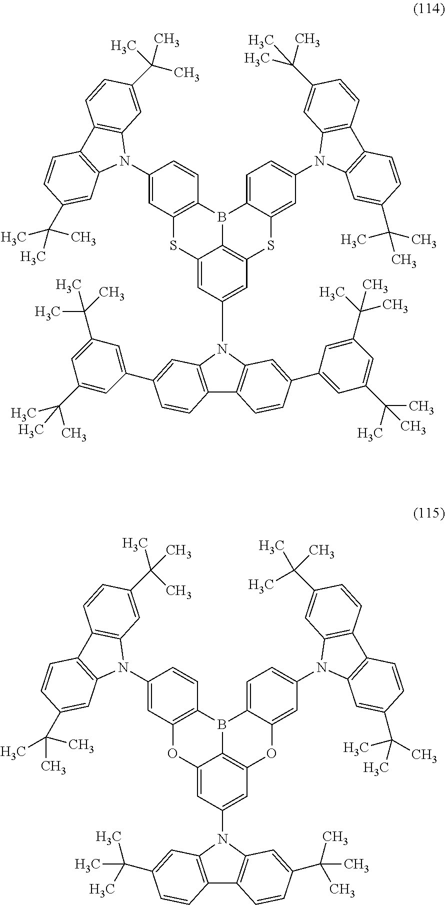

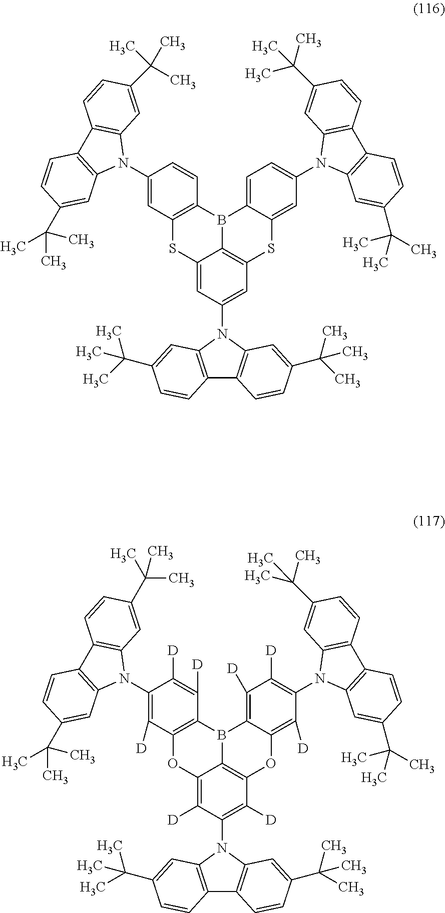

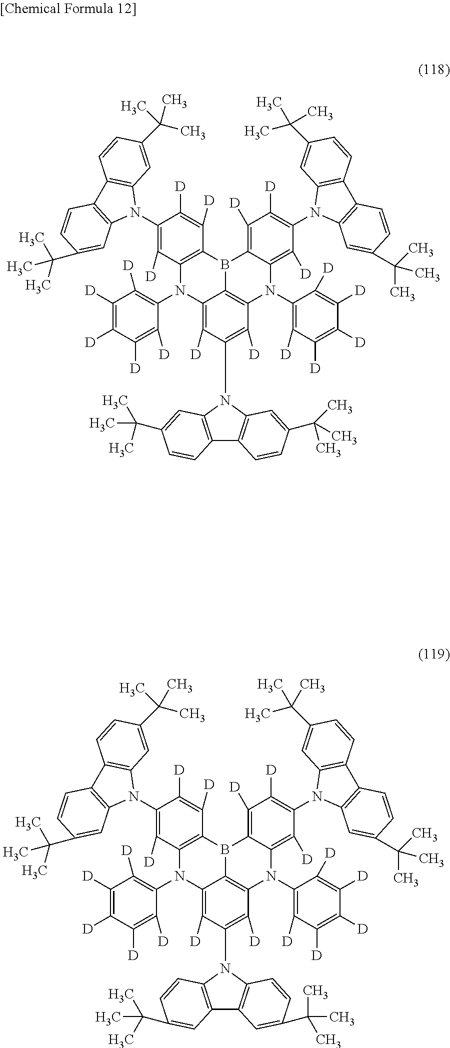

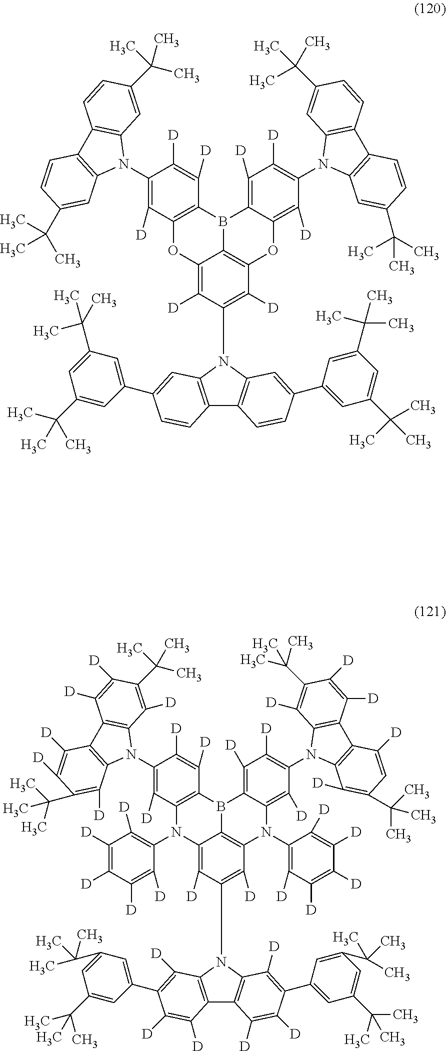

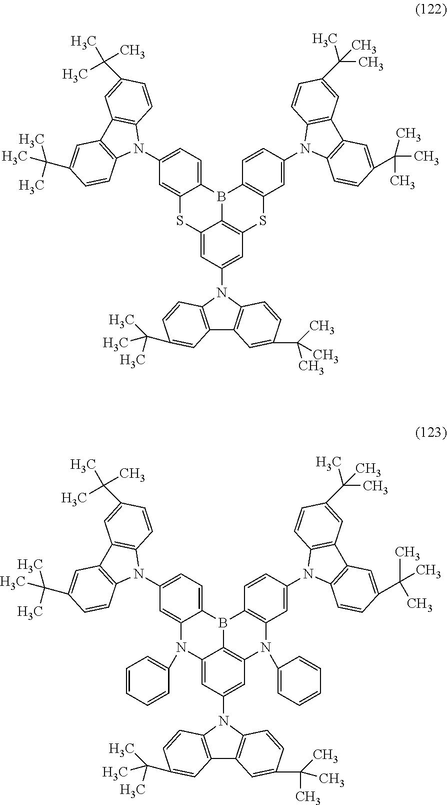

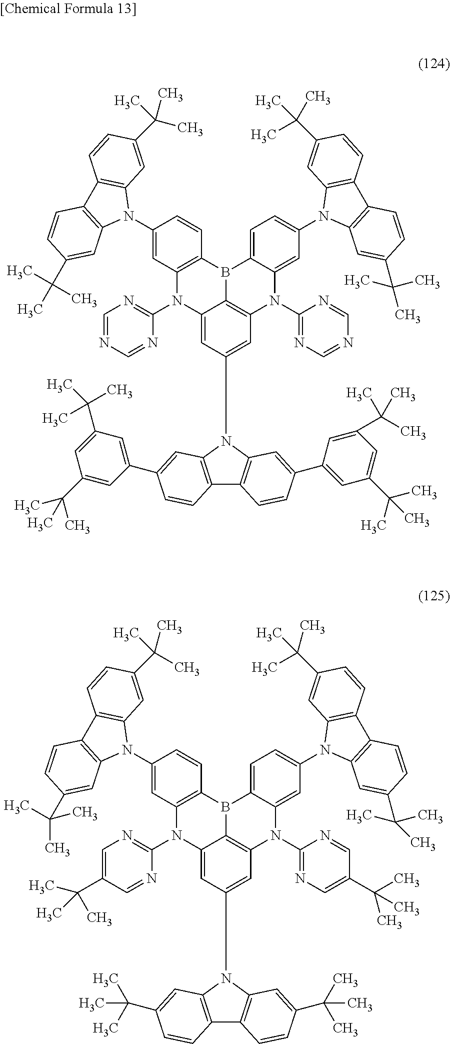

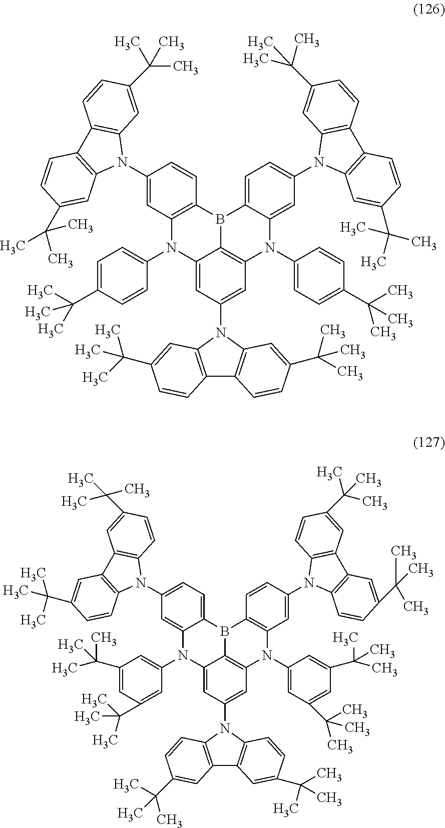

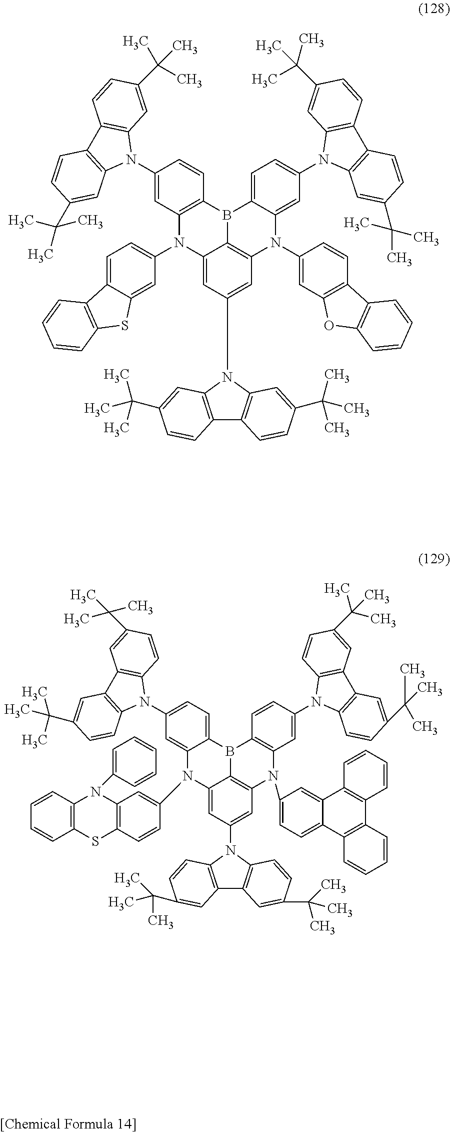

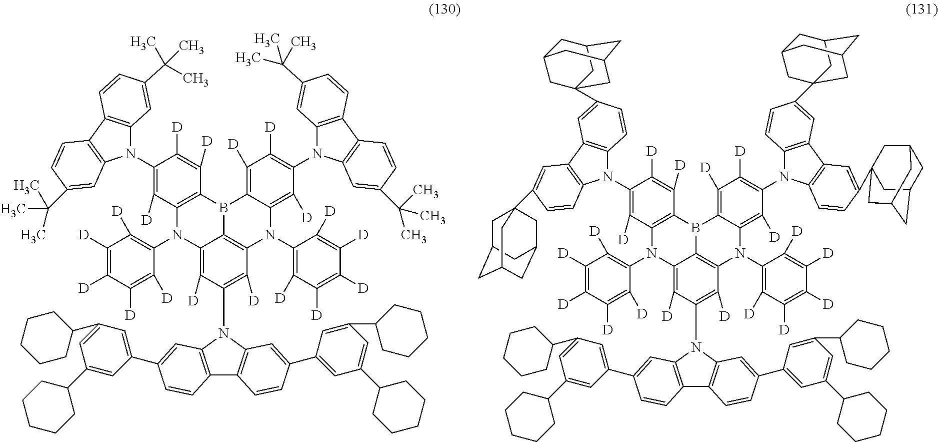

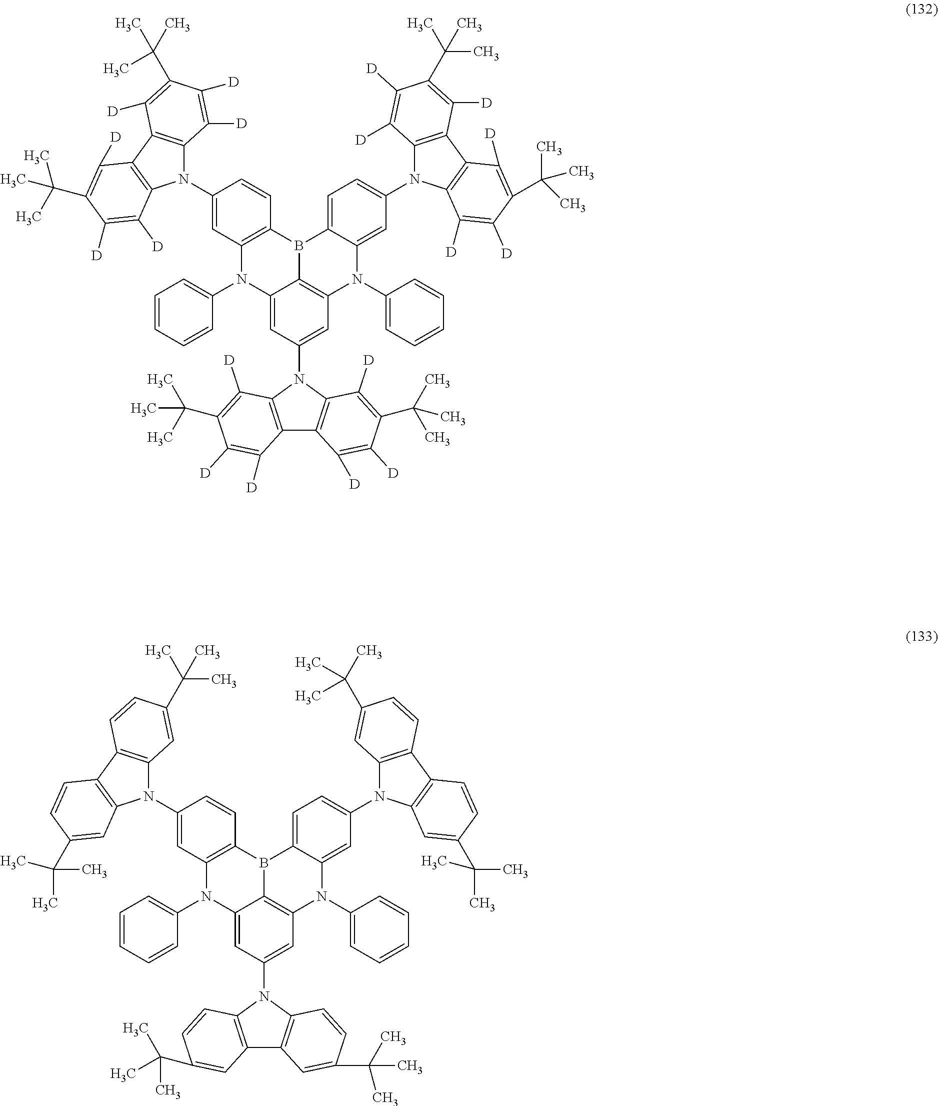

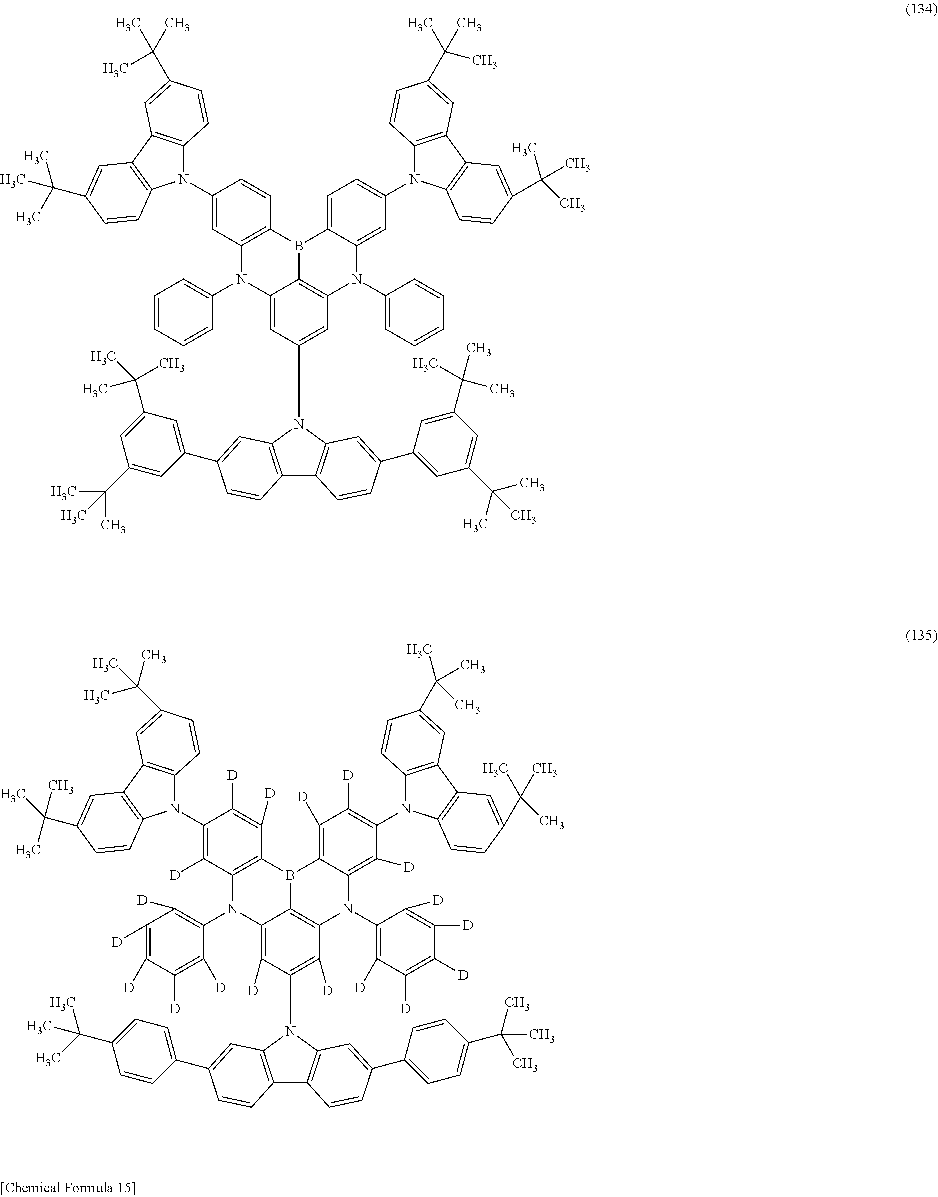

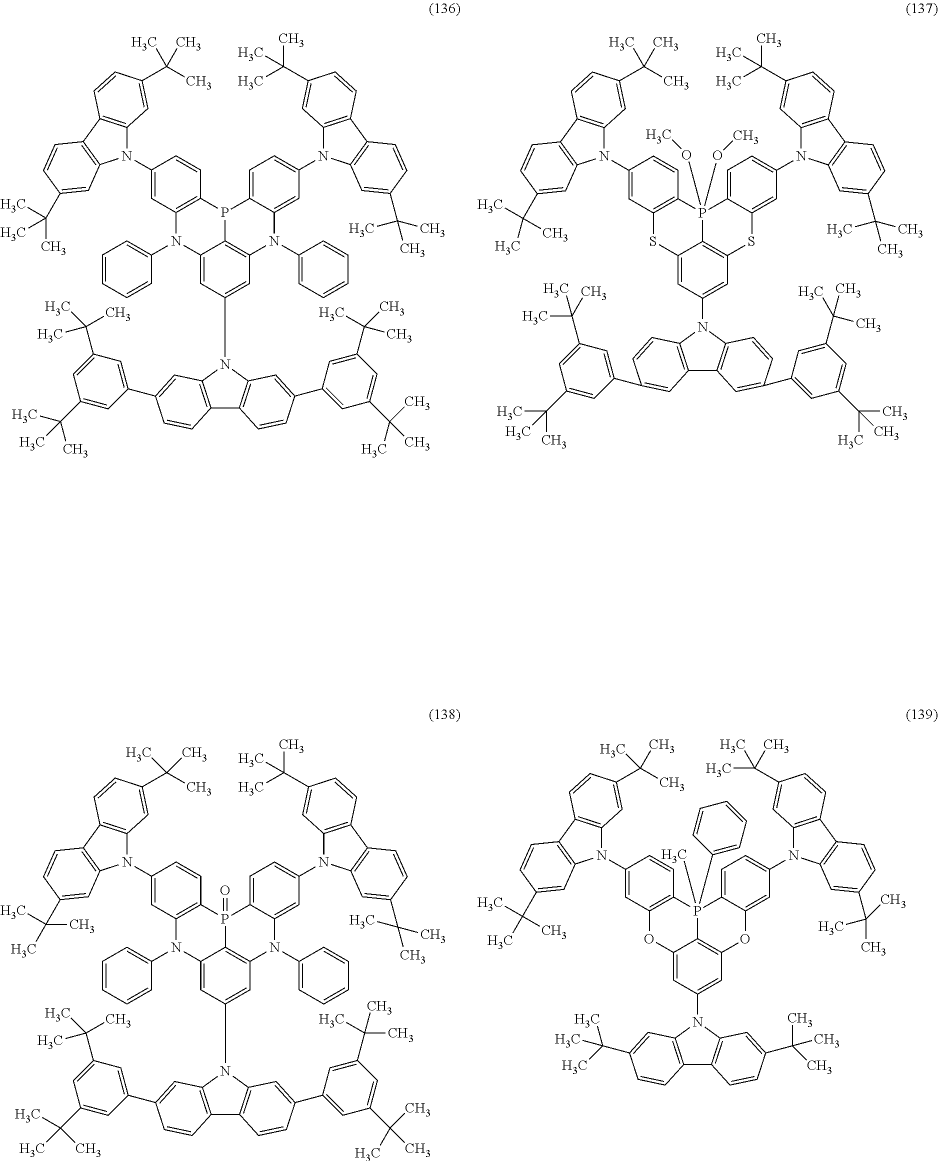

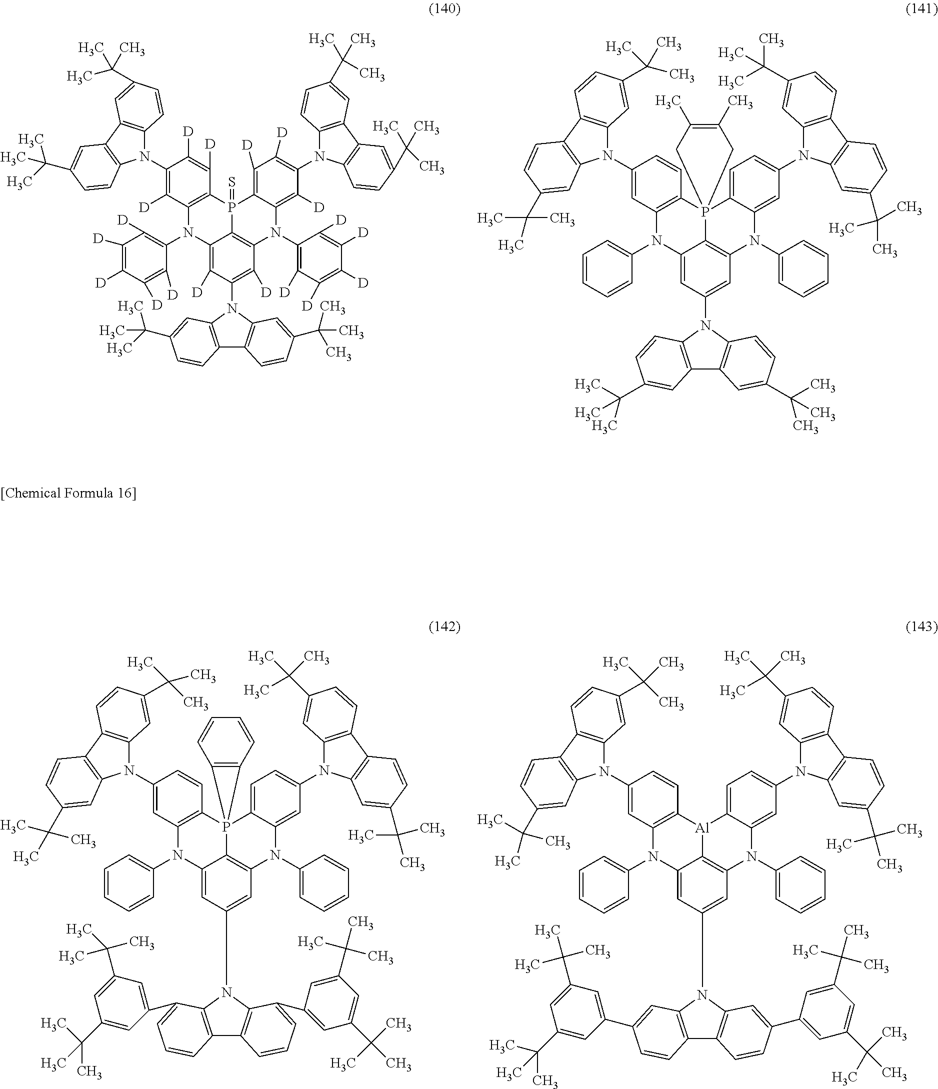

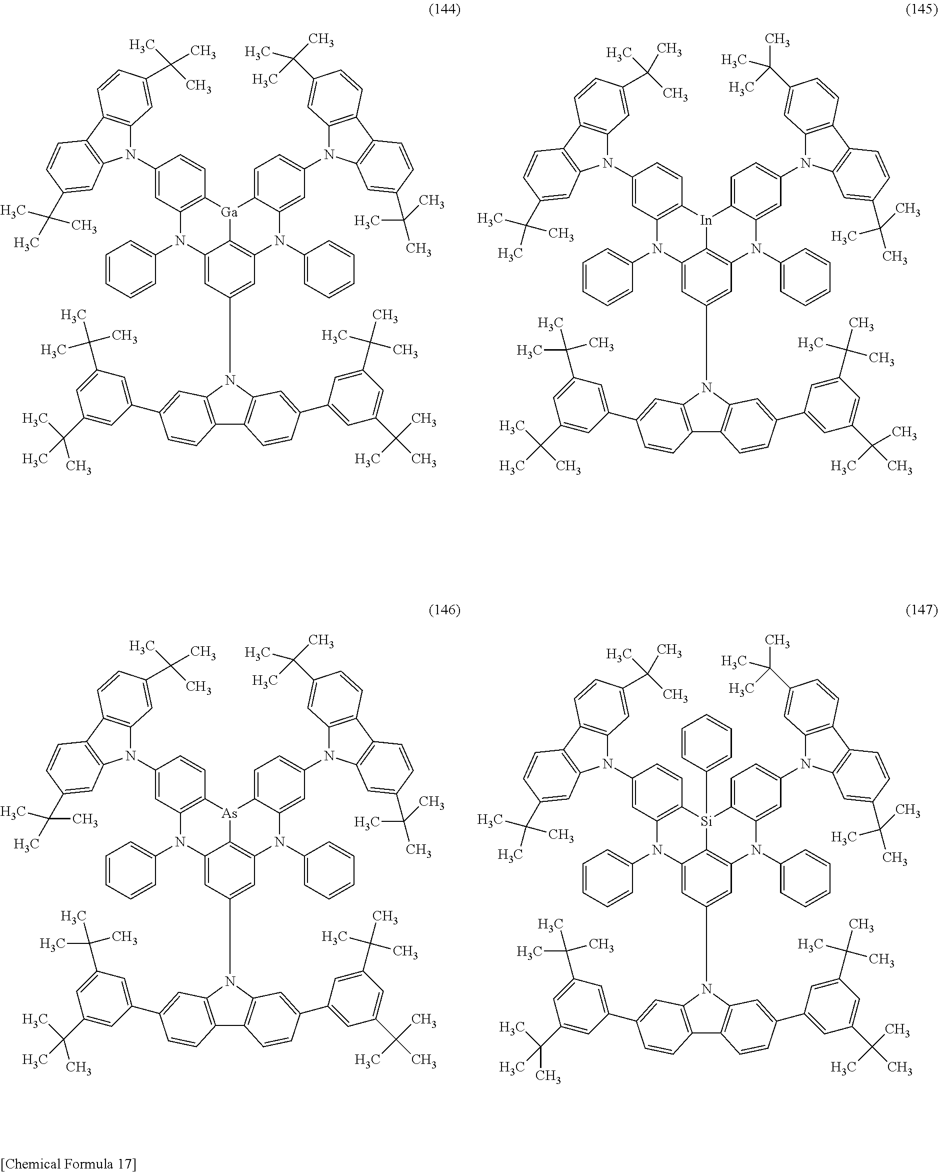

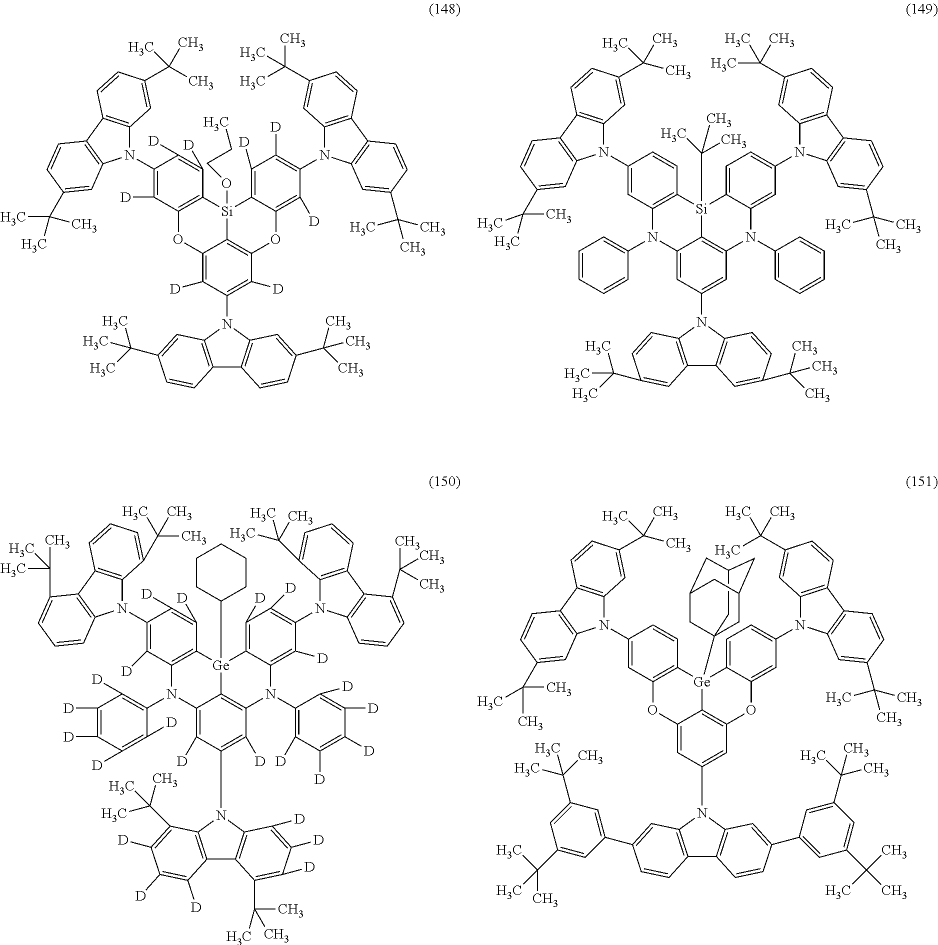

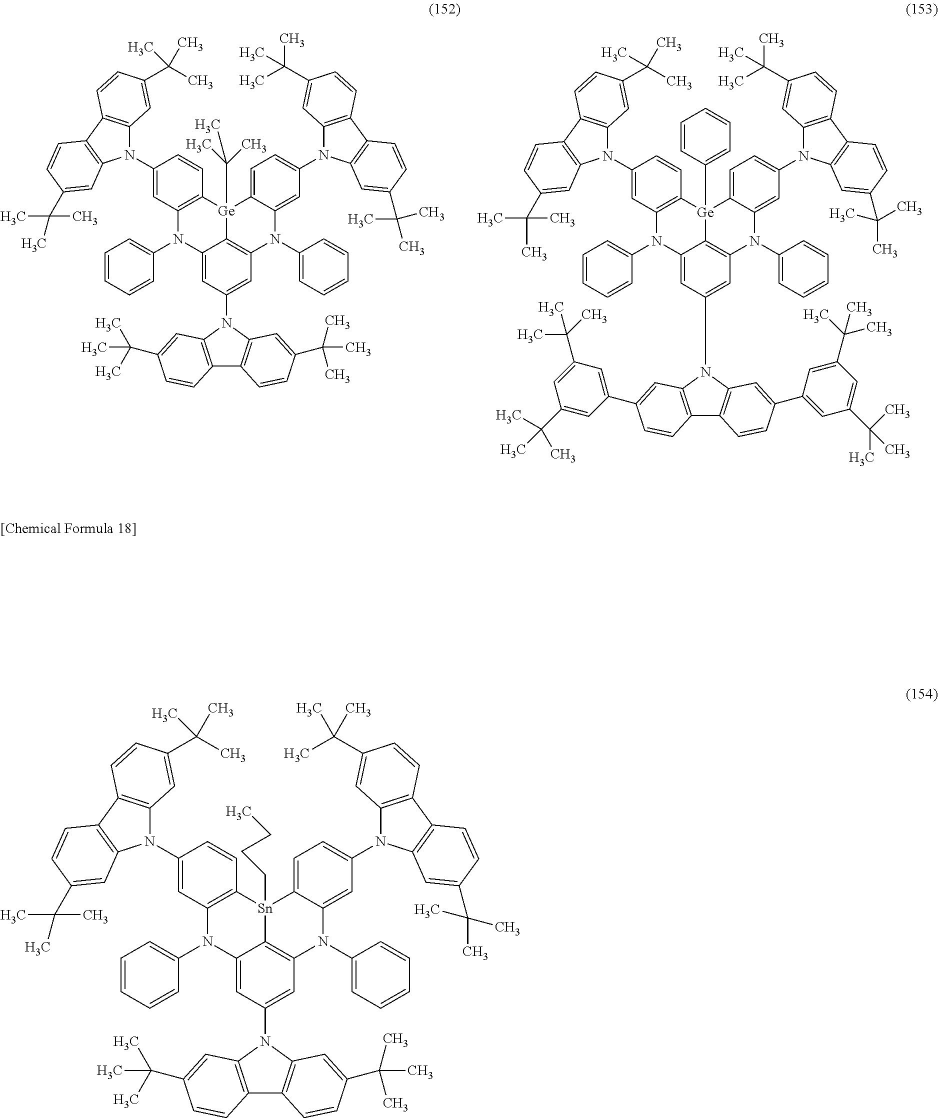

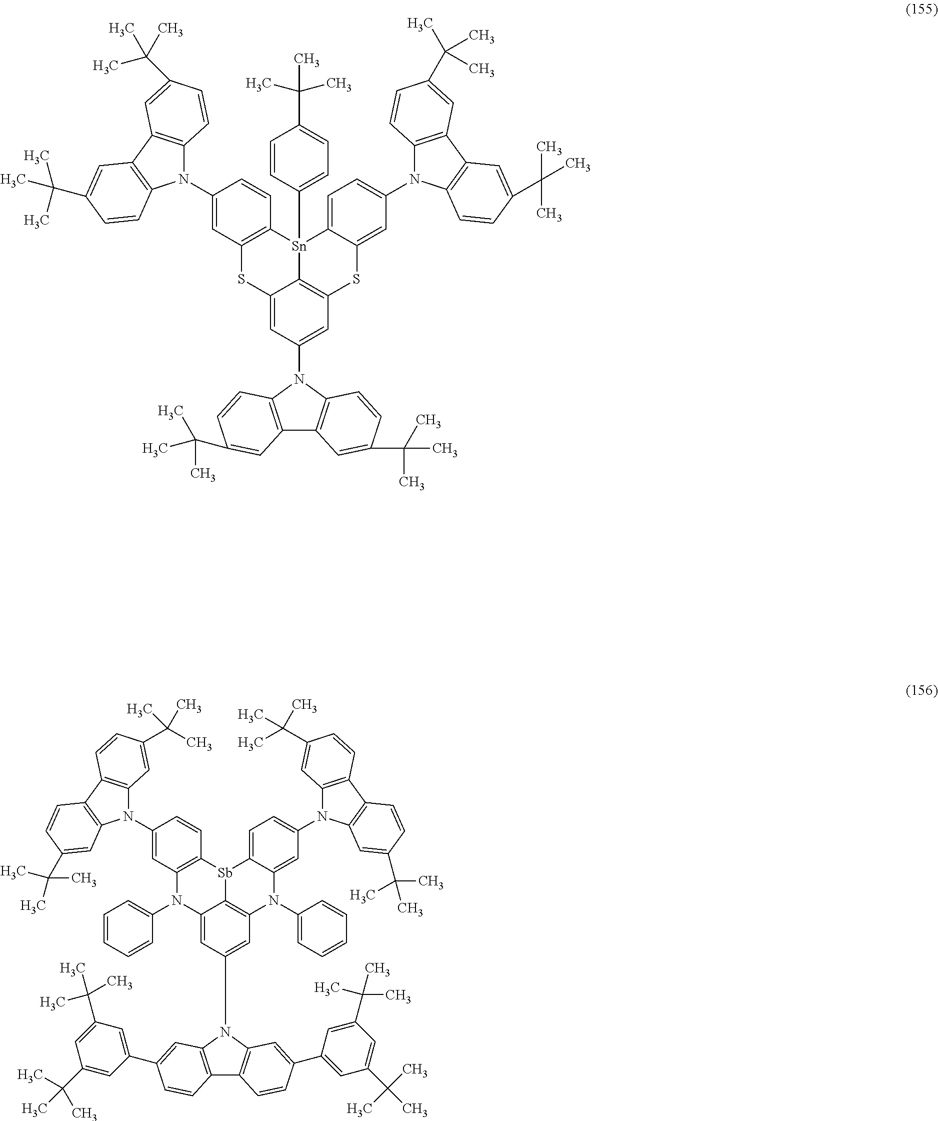

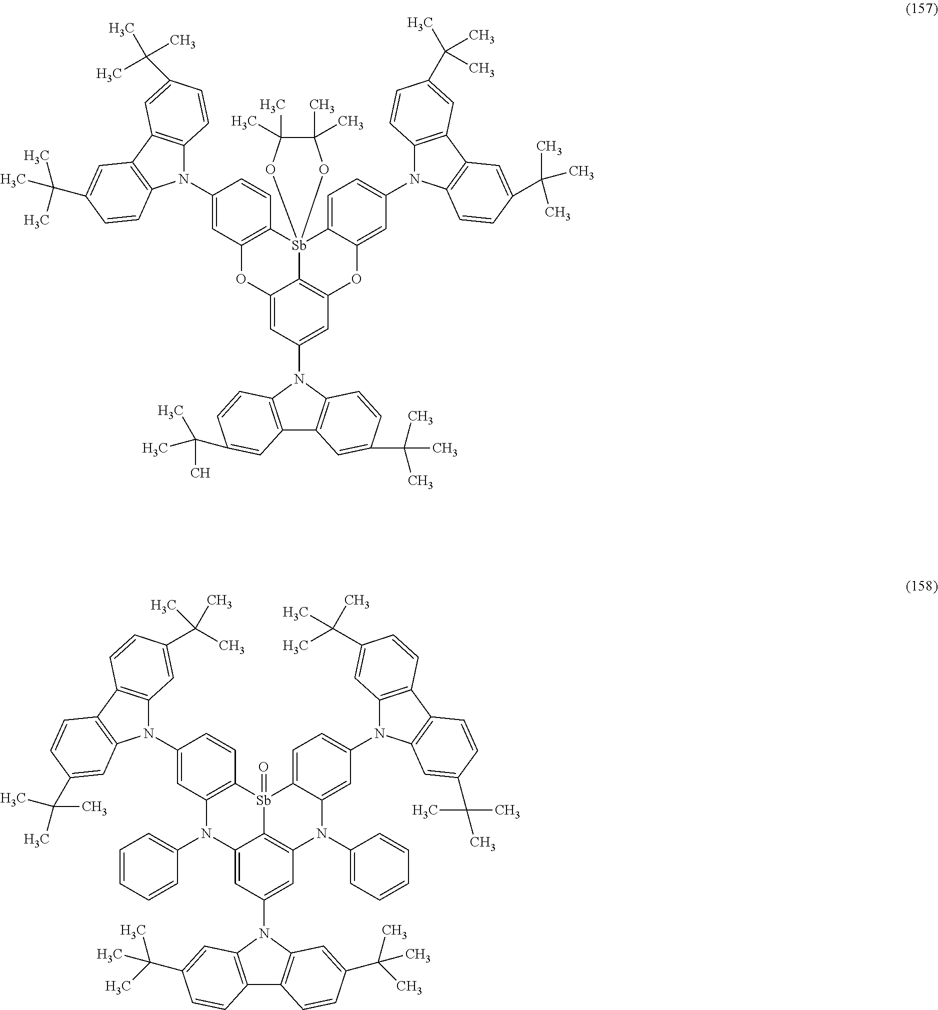

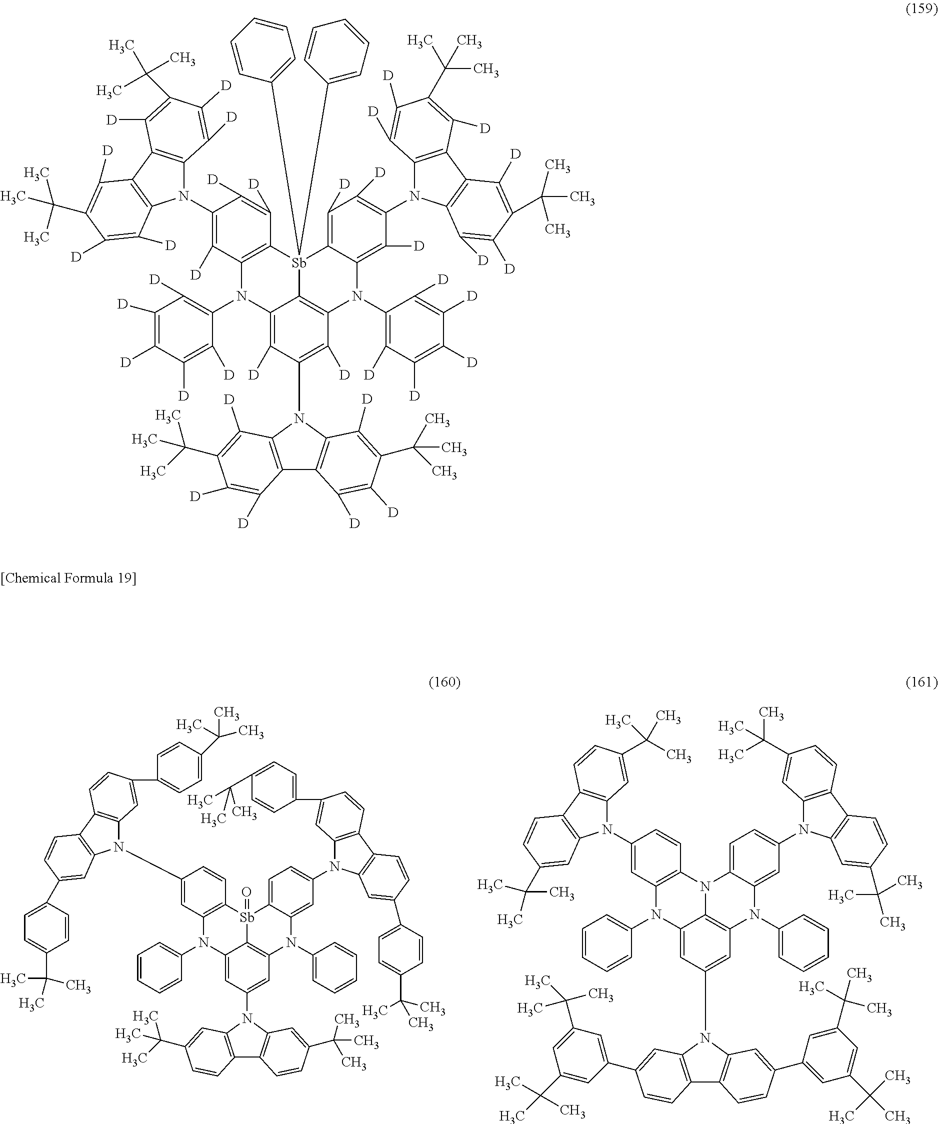

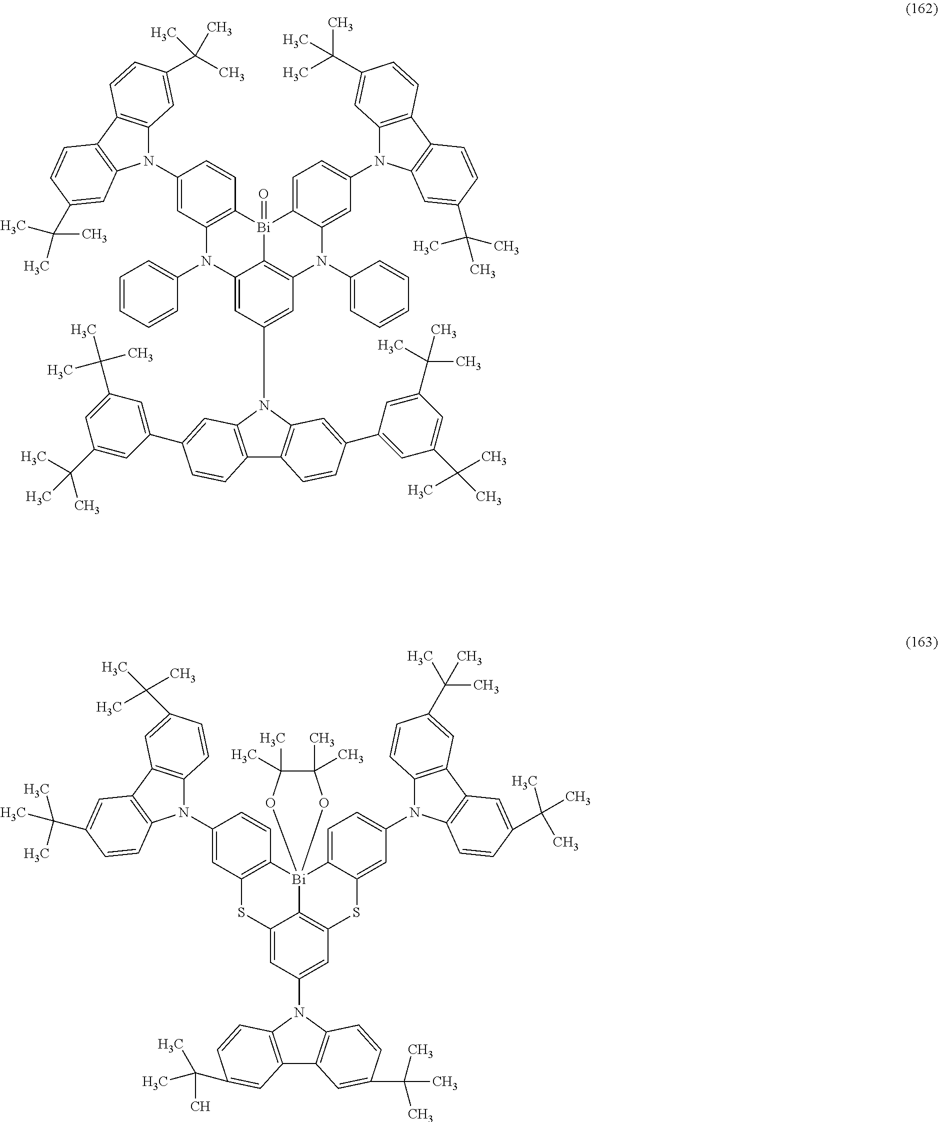

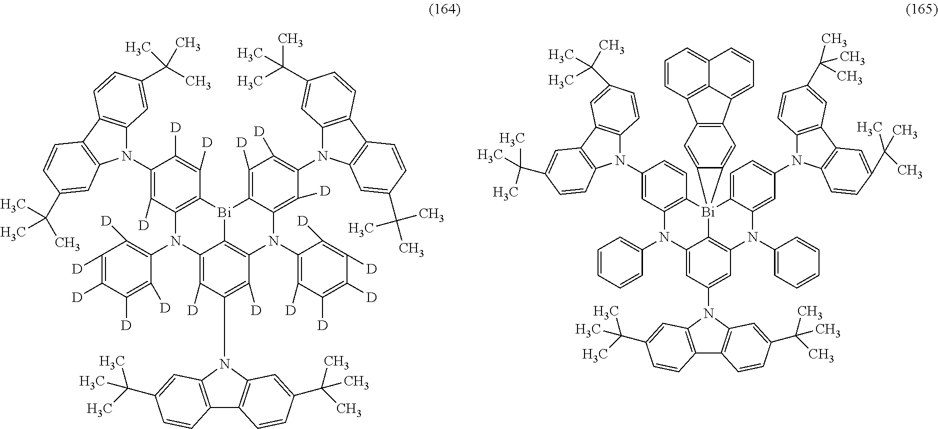

The organic compounds shown above can be synthesized by the following synthesis schemes, for example.

The organic compound (G2) of one embodiment of the present invention can be synthesized according to the following synthesis scheme. That is, as shown in Synthesis Scheme (S—1-1), a 9-phenylcarbazole compound (A1) and an amine compound (A2) are coupled to give an amine compound (A3). Similarly, as shown in Synthesis Scheme (S-1-2), a 9-phenylcarbazole compound (A4) and an amine compound (A5) are coupled to give an amine compound (A6).

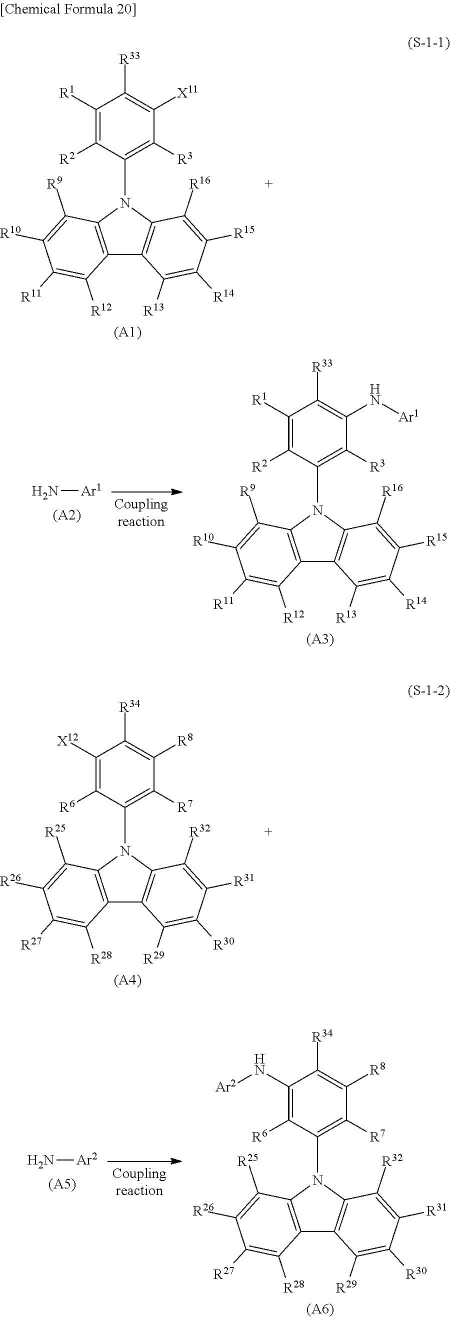

Subsequently, as shown in Synthesis Scheme (S-2-1), a benzene derivative (A7) and the amine compound (A3) obtained in Synthesis Scheme (S-1-1) are coupled, whereby an amine compound (A8) can be obtained.

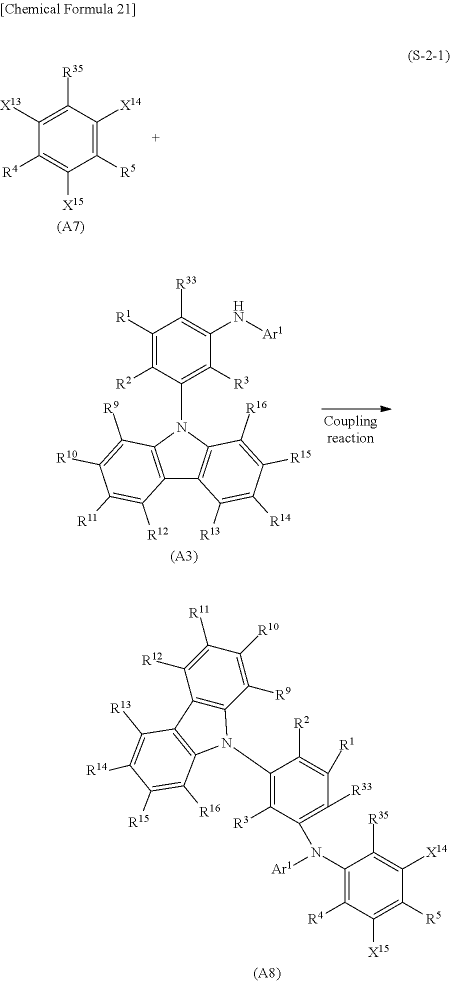

Next, as shown in Synthesis Scheme (S-2-2), the amine compound (A8) obtained in Synthesis Scheme (S-2-1) and the amine compound (A6) obtained in Synthesis Scheme (S-1-2) are coupled, whereby an amine compound (A9) can be obtained.

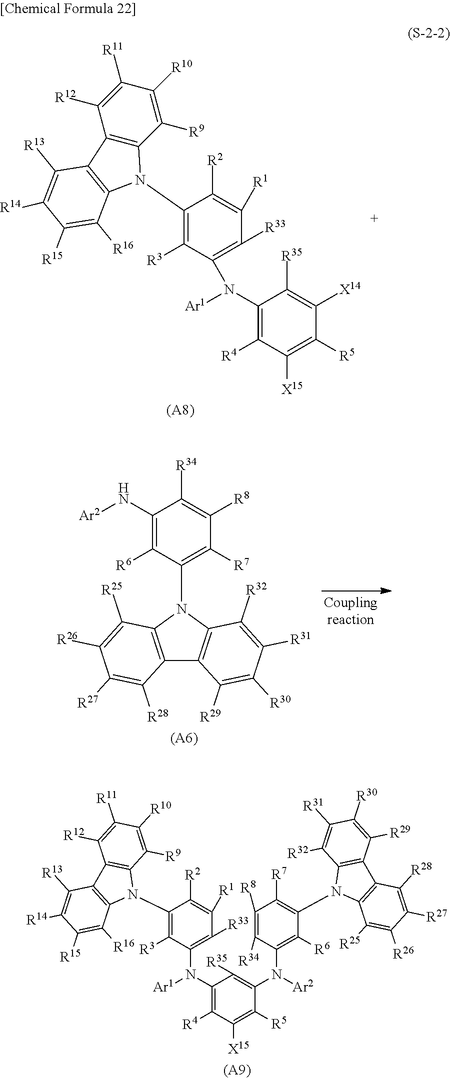

Next, as shown in Synthesis Scheme (S-2-3), the amine compound (A9) obtained in Synthesis Scheme (S-2-2) and a carbazole compound (A10) are coupled, whereby an amine compound (A11) can be obtained. Note that in the case where the amine compound (A3) and the amine compound (A6) have the same molecular structure, the amine compound (A9) can be obtained also by coupling two equivalents of amine compounds (A3) with the benzene derivative (A7) in Synthesis Scheme (S-2-1).

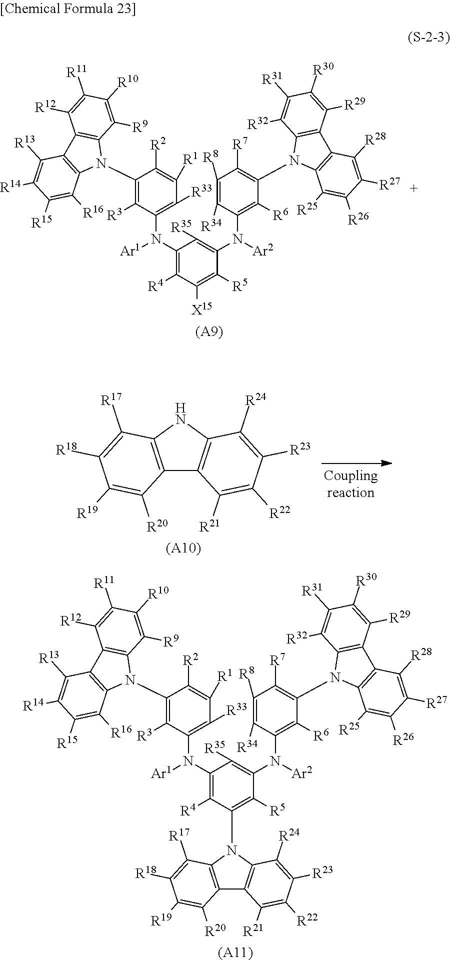

Subsequently, as shown in Synthesis Scheme (S-3), the organic: compound (G2) of one embodiment of the present invention can be obtained by a reaction between the amine compound (A11) and a boron trihalide (A12).

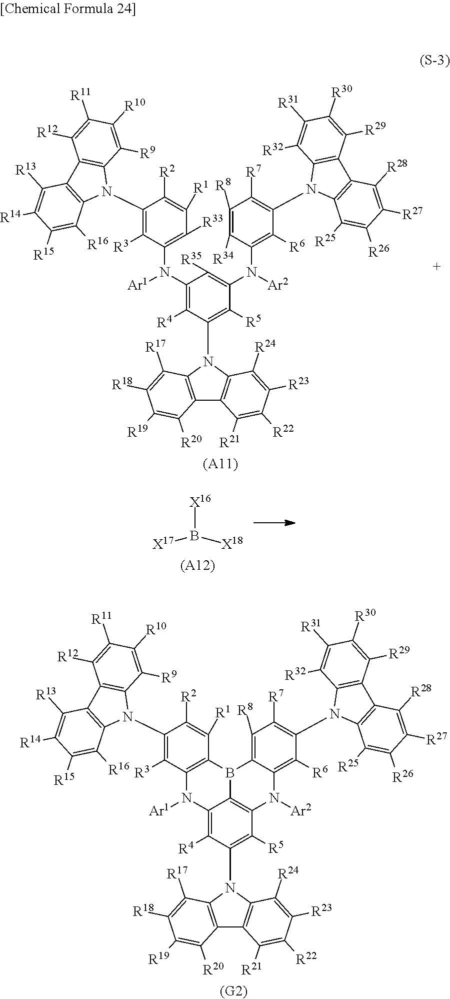

In the Synthesis Schemes (S-1-1) to (S-1-2), (S-2-1) to (S-2-3), and (S-3) above, Ar¹ and Ar² each independently represent any one of a substituted or unsubstituted aryl group having 6 to 25 carbon atoms and a substituted or unsubstituted heteroaryl group having 3 to 30 carbon atoms; in the case where the above Ar¹ and Ar² each include a substituent, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, or a substituted or unsubstituted aryl group having 6 to 25 carbon atoms can be given as the substituent.

In addition, R¹ to R⁸ each independently represent any one of hydrogen and deuterium, and R⁹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms; and R³³ to R³⁵ each independently represent any one of hydrogen, deuterium, and halogen.

Furthermore, X¹¹ to X¹⁸ each independently represent a halogen, a triflate group, an organotin group, a magnesium halide group, or an organozinc group; in the case where X¹¹ to X¹⁸ are each halogen, especially chlorine, bromine, or iodine is preferred.

In the coupling reactions represented by Synthesis Schemes (S-1-1) to (S-1-2), (S-2-1) to (S-2-3), and (S-3) above, in the case where Buchwald-Hartwig reaction using palladium is performed, examples of the palladium catalyst that can be used include bis(dibenzylideneacetone)palladium(0), palladium(II) acetate, tetrakis(triphenylphosphine)palladium(0), and [1,1-bis(diphenylphosphino)ferrocene]palladium(II) dichloride.

Examples of a ligand of the above palladium catalyst include tri(tert-butyl)phosphine, tri(ortho-tolyl)phosphine, triphenylphosphine, tri(n-hexyl)phosphine, di(1-adamantyl)-n-butylphosphine, 2-dicyclohexylphosphino-2′,6′-dimethoxybiphenyl, tri(ortho-tolyl)phosphine, di-tert-butyl(2,2-diphenyl-1-methyl-1-cyclopropyl)phosphine (abbreviation: cBRIDP), and tricyclohexylphosphine.

Examples of a base that can be used in the coupling reactions represented by Synthesis Schemes (S-1-1) and (S-1-2), (S-2-1) to (S-2-3), and (S-3) described above include an organic base such as sodium tert-butoxide and an inorganic base such as potassium carbonate or sodium carbonate.

Examples of a solvent that can be used in the coupling reactions represented by Synthesis Schemes (S-1-1) and (S-1-2), (S-2-1) to (S-2-3), and (S-3) described above include toluene, xylene, mesitylene, benzene, tetrahydrofuran, and dioxane.

The reaction performed in Synthesis Schemes (S-1-1) and (S-1-2), (S-2-1) to (S-2-3), and (S-3) described above is not limited to the Buchwald-Hartwig reaction. A Migita-Kosugi-Stille coupling reaction using an organotin compound, a coupling reaction using a Grignard reagent, an Ullmann reaction using copper or a copper compound, or the like can be used.

In the coupling reactions represented by the above Schemes (S-2-1) to (S-2-3), the reaction between the benzene derivative (A7) and the amine compound is preferably performed in the following manner: the coupling reactions of the amine compounds (A3) and (A6) are performed before the reaction with the carbazole compound (A10), and then the coupling with the carbazole derivative (A10) is performed. The amine compounds (A3) and (A6) are preferred because the rate of the palladium coupling reaction in the Buchwald-Hartwig reaction is higher than that of the carbazole compound (A10), in which case generation of impurities can be suppressed. Furthermore, the amine compounds (A3) and (A6) are preferred because they have higher halogen selectivity in the Buchwald-Hartwig reaction and thus are more easily purified than the carbazole compound (A10).

Examples of the boron trihalide (A12) used in Scheme (S-3) above include boron trichloride, boron tribromide, and boron triiodide.

In the case where any one of R³³, R³⁴, and R³⁵ is halogen in Scheme (S-3) above, halogen and lithium organic may be reacted with each other and then reacted with boron trihalide; in that case, it is expected that the heating time in Synthesis Scheme (S-3) can be shortened or the yield can be increased. Note that as described in this embodiment, General Formula (G2), which is a target substance, can be obtained in high yield or with a high purity, or both in high yield and with a high purity also in a synthesis method in which organic lithium is not used in Synthesis Scheme (S-3).

The organoboron compound of one embodiment of the present invention for a dopant material can be synthesized in the aforementioned manner; however, the synthesis method is not limited to the aforementioned manner.

### <Second Organic Compound>

As a fluoranthene skeleton that is the second organic compound used for the light-emitting layer 113, an organic compound having a fluoranthene ring or a benzofluoranthene ring is preferably used.

The S1 level of the above second organic compound having a fluoranthene skeleton is preferably higher than or equal to 3.0 eV and lower than or equal to 3.6 eV. Note that when the S1 level is higher than or equal to 3.0 eV and lower than or equal to 3.6 eV, the second organic compound can be used as a blue fluorescent host material.

In general, an organic compound having an anthracene skeleton as a basic skeleton of a host material for blue fluorescent light-emitting devices is widely used; however, an anthracene skeleton has a physical property in which oxygen is easily added thereto. A compound in which a substituent is introduced into a fluoranthene skeleton and a compound in which a substituent is introduced into an anthracene skeleton are used to calculate the resistance to oxygen addition of the compounds. The obtained result shows that oxygen is less likely to be added to the organic compound having a fluoranthene skeleton than the organic compound having an anthracene skeleton (hereinafter it is also referred to as resistance to oxygen addition). Details are described below.

### <<Calculation of Resistance to Oxygen Addition>>

By the following method, resistance to oxygen addition of 9-[4-(3-fluoranthenyl)phenyl]-9H-carbazole (abbreviation: CzPFlt) having a fluoranthene skeleton and 9-[4-(10-phenyl-9-anthracenyl)phenyl]-9H-carbazole (abbreviation: CzPA) having an anthracene skeleton are calculated.

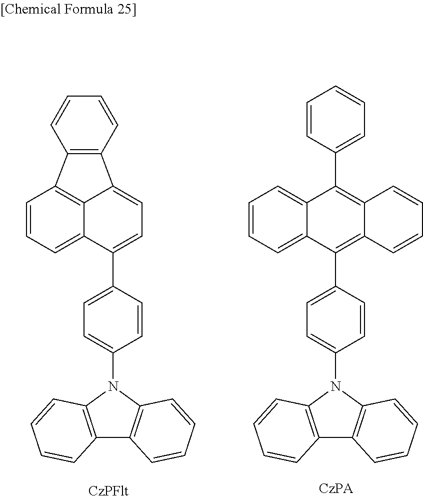 [SMILES: c1ccc2c(c1)-c1cccc3c(-c4ccc(-n5c6ccccc6c6ccccc65)cc4)ccc-2c13 ; c1ccc(-c2c3ccccc3c(-c3ccc(-n4c5ccccc5c5ccccc54)cc3)c3ccccc23)cc1]

Oxygen is added to CzPFlt and CzPA to form an oxygen adduct of CzPFlt and an oxygen adduct of CzPA, and the activation energy of the oxygen addition reaction and the stabilization energy of the oxygen adducts are calculated.

Note that Gaussian 09 is used as a quantum chemistry computational program. A high performance computer (HPE SGI8600) is used for the calculations.

The stable structures in the initial state, the transition state, and the final state for the oxygen addition reaction in the singlet ground state are calculated using density functional theory (DFT). In addition, vibration analysis is performed on the most stable structure in each state.

In the DFT, the total energy is represented as the sum of potential energy, electrostatic energy between electrons, electronic kinetic energy, and exchange-correlation energy including all the complicated interactions between electrons. In the DFT, an exchange-correlation interaction is approximated by a functional (a function of a function) of one electron potential represented in terms of electron density. Here, B3LYP which is a hybrid functional is used to specify the weight of each parameter related to exchange-correlation energy. As a basis function, 6-311G (d,p) is used.

The sum of energy in the most stable state of CzPFlt and energy in the most stable state of an oxygen molecule is set 0 eV, and the activation energy of the oxygen addition reaction and the stabilization energy of the oxygen adduct of CzPFlt are calculated. Furthermore, the sum of energy in the most stable state of CzPA and energy in the most stable state of an oxygen molecule is set 0 eV, and the activation energy of the oxygen addition reaction and the stabilization energy of the oxygen adduct of CzPA are calculated.

As a result, the oxygen adduct of CzPFlt and the oxygen adduct of CzPA, represented by the structures shown below, have the minimum values of both the activation energy of the oxygen addition reaction and the stabilization energy of the oxygen adducts. Thus, it can be inferred that the oxygen adduct of CzPFlt and the oxygen adduct of CzPA represented by the structures shown below tend to be easily formed.

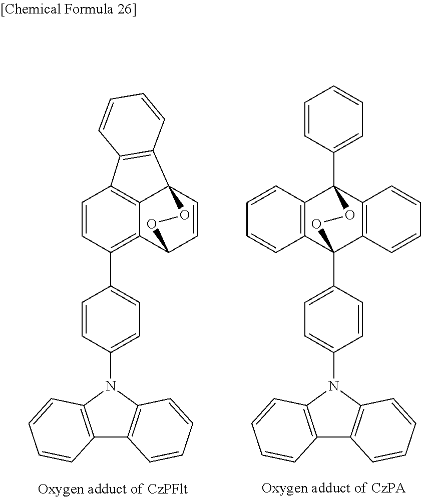 [SMILES: C1=C[C@]23OO[C@H]1c1c(-c4ccc(-n5c6ccccc6c6ccccc65)cc4)ccc(c12)-c1ccccc13 ; c1ccc([C@]23OO[C@](c4ccc(-n5c6ccccc6c6ccccc65)cc4)(c4ccccc42)c2ccccc23)cc1]

The calculation results of the oxygen adduct of CzPFlt and the oxygen adduct of CzPA are shown in the following table.

TABLE 1

| | Activation energy of | Stabilization energy of |
|---|---|---|
| | oxygen addition reaction | oxygen adduct |
| CzPFlt | 1.85 eV | 1.23 eV |
| CzPA | 1.37 eV | 0.45 eV |

The above result shows that the reaction energy of oxygen addition to CzPFlt is higher than the reaction energy of oxygen addition to CzPA, indicating that CzPFlt tends to be less likely to form an oxygen adduct than CzPA. Accordingly, it can be confirmed that CzPFlt has higher resistance to oxygen addition than CzPA. Furthermore, the difference between the stabilization energy of the oxygen adduct and the activation energy of the oxygen addition reaction of CzPA is larger than that of CzPFlt. Accordingly, it can be inferred that in the case where an oxygen adduct of CzPA is formed, the added oxygen is less likely to be removed from the oxygen adduct of CzPA.

From the above, the second organic compound having a fluoranthene skeleton is less likely to form an oxygen adduct than the organic compound having an anthracene skeleton; thus, it can be said that using an organic compound having a fluoranthene skeleton as a host material in a light-emitting layer is effective for inhibiting a decrease in reliability and characteristics of a light-emitting device in fabrication of a light-emitting device including a fabrication process in the presence of oxygen.

The second organic compound may contain a condensed aromatic ring or a condensed heteroaromatic ring in addition to the fluoranthene skeleton. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, a naphthobisbenzofuran skeleton, and the like are given.

Specifically, specific structures of the second organic compound having a fluoranthene skeleton are shown in Structural Formulas (200) to (204).

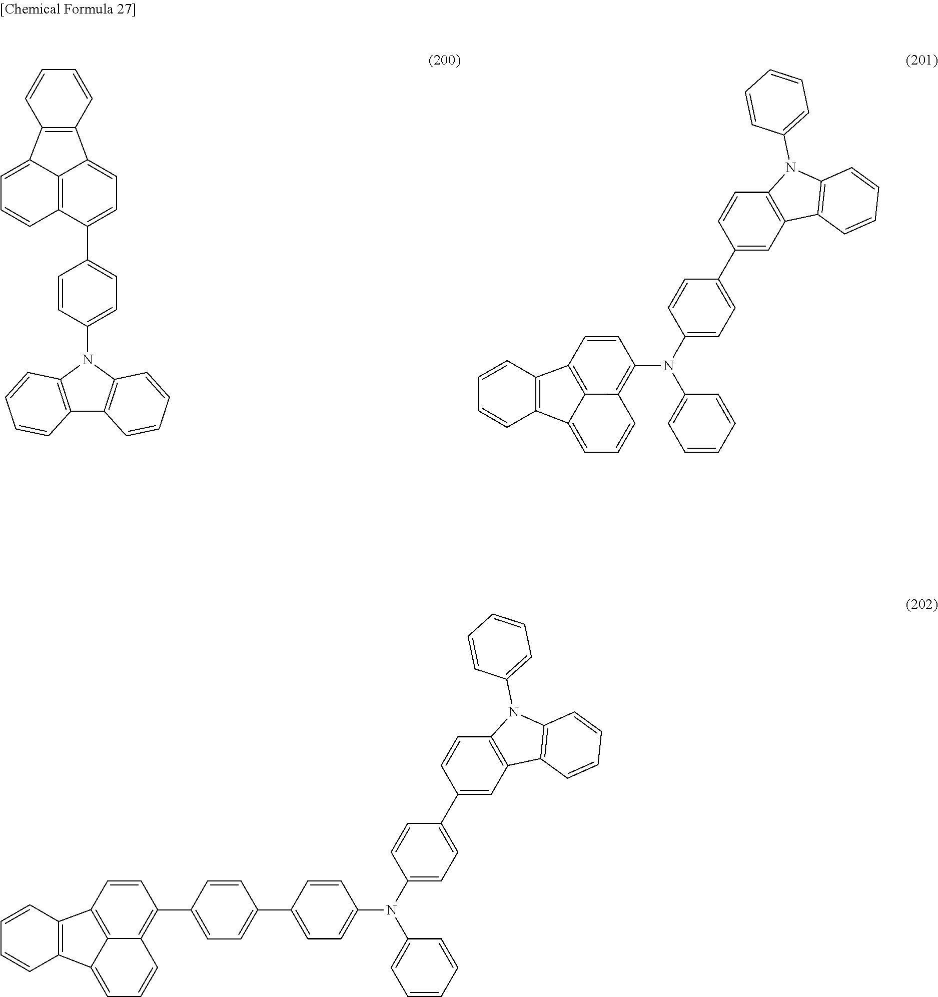 [SMILES: c1ccc2c(c1)-c1cccc3c(-c4ccc(-n5c6ccccc6c6ccccc65)cc4)ccc-2c13 ; c1ccc(N(c2ccc(-c3ccc4c(c3)c3ccccc3n4-c3ccccc3)cc2)c2ccc3c4c(cccc24)-c2ccccc2-3)cc1 ; c1ccc(N(c2ccc(-c3ccc(-c4ccc5c6c(cccc46)-c4ccccc4-5)cc3)cc2)c2ccc(-c3ccc4c(c3)c3ccccc3n4-c3ccccc3)cc2)cc1]

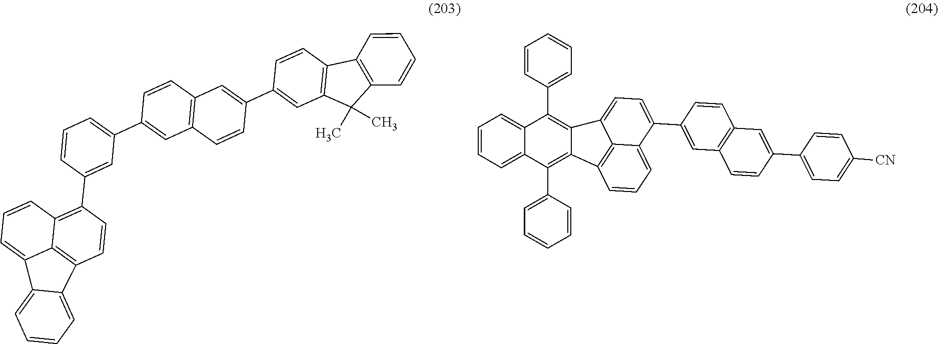

FIGS. 1B and 1C each illustrate an example of a specific structure of the light-emitting device 100 in FIG. 1A. FIG. 1B has a structure in which a hole-injection layer 111, a hole-transport layer 112, a light-emitting layer 113, an electron-transport layer 114, and an electron-injection layer 115 are stacked in this order over the first electrode 101. As illustrated in the cross-sectional view in FIG. 1B, the end portions (or side surfaces) of the hole-injection layer 111, the hole-transport layer 112, the light-emitting layer 113, and the electron-transport layer 114 are positioned inward from the end portion (or side surfaces) of the first electrode 101. In addition, the end portions (or side surfaces) of the hole-injection layer 111, the hole-transport layer 112, the light-emitting layer 113, and the electron-transport layer 114, and part of the top and the end portions (or side surfaces) of the first electrode 101 are in contact with an insulating layer 107.

With the insulating layer 107, the hole-injection layer 111, the end portions (or side surfaces) of the hole-transport layer 112, the end portions (or side surfaces) of the light-emitting layer 113, and the end portions (or side surfaces) of the electron-transport layer 114 can be protected. This can reduce damage to the layers due to a process and prevent an electrical connection caused by contact with another layer.

Although the electron-injection layer 115 is part of the EL layer 103, the shape of the electron-injection layer 115 differs from those of the other layers (the hole-injection layer 111, the hole-transport layer 112, the light-emitting layer 113, and the electron-transport layer 114) of the EL layer 103, as illustrated in FIG. 1B. However, the shape of the electron-injection layer 115 can be the same as that of the second electrode 102. The electron-injection layer 115 and the second electrode 102 can be shared by a plurality of light-emitting devices; hence, the fabrication process of the light-emitting device 100 can be simplified and the throughput can be improved.

The light-emitting device may have a structure illustrated in FIG. 1C. In the structure, the hole-injection layer 111, the hole-transport layer 112, the light-emitting layer 113, the electron-transport layer 114, and the electron-injection layer 115 are sequentially stacked over the first electrode 101 to cover the first electrode 101. In the cross sectional view in FIG. 1C, the end portions of the hole-injection layer 111, the hole-transport layer 112, the light-emitting layer 113, and the electron-transport layer 114 are positioned outward from the end portion (or side surface) of the first electrode 101. The insulating layer 107 is in contact with the end portions of the hole-injection layer 111, the hole-transport layer 112, the light-emitting layer 113, and the electron-transport layer 114.

The insulating layer 107 is in contact with the hole-injection layer 111, the end portions (or side surfaces) of the hole-transport layer 112, the end portions (or side surfaces) of the light-emitting layer 113, and the end portions (or side surfaces) of the electron-transport layer 114. The insulating layer 107 is positioned between a second insulating layer 140 and the hole-injection layer 111, the end portions (or side surfaces) of the hole-transport layer 112, the end portions (or side surfaces) of the light-emitting layer 113, and the end portions (or side surfaces) of the electron-transport layer 114. The electron-injection layer 115 is provided over the second insulating layer 140, the insulating layer 107, and the electron-transport layer 114. The second insulating layer 140 can be formed using an organic compound or an inorganic compound.

In the case where an organic compound is used as the second insulating layer 140, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin may be used. As the photosensitive resin, a positive material or a negative material can be used.

When the second insulating layer 140 is formed using a photosensitive resin, the second insulating layer 140 can be formed only by light exposure and development steps in a manufacturing process; hence, adverse effects of dry etching, wet etching, or the like on another layer can be reduced. A negative photosensitive resin is preferably used, in which case a photomask (light-exposure mask) used in this step can sometimes be used also in a different step.

With the device structures illustrated in FIG. 1B and FIG. 1C, when some layers of the EL layer 103 are patterned to have a desired shape during the fabrication process, the processing surface might be heated or exposed to the air, causing problems such as crystallization of the light-emitting layer 113 or the electron-transport layer, which decreases the reliability and luminance of the light-emitting device in some cases. In contrast, in the light-emitting device 100 described in Embodiment 1, patterning is performed after the electron-transport layer 114 is formed and thus a problem such as crystallization of the light-emitting layer 113 can be inhibited. Note that in this case, only the structure of the electron-injection layer 115 is different from those of the other layers (the hole-injection layer 111, the hole-transport layer 112, the light-emitting layer 113, and the electron-transport layer 114) of the EL layer 103 because the electron-injection layer 115 of part of the EL layer 103 is formed after the formation of the electron-transport layer.

Note that the light-emitting devices 100 having the shapes illustrated in FIG. 1B and FIG. 1C are examples of device structures that can be subjected to patterning in such a fabrication method, but the shape of the light-emitting device of one embodiment of the present invention is not limited to the shapes. With the device structure of one embodiment of the present invention, reductions in efficiency and reliability in the light-emitting device can be inhibited.

The insulating layer 107 illustrated in each of FIG. 1B and FIG. 1C may not be provided if not needed. For example, when electrical continuity between the electron-injection layer 115 and the hole-injection-layer 111 and hole-transport layer 112 is sufficiently low, the light-emitting device 100 does not necessarily include the insulating layer 107.

As the materials that can be used for the first electrode 101, the second electrode 102, the hole-injection layer 111, the hole-transport layer 112, the light-emitting layer 113, the electron-injection layer 115, and the insulating layer 107, materials that will be described later in an embodiment below can be used.

The structures described in this embodiment can be used in an appropriate combination with the structures described in the other embodiments.

### Embodiment 2

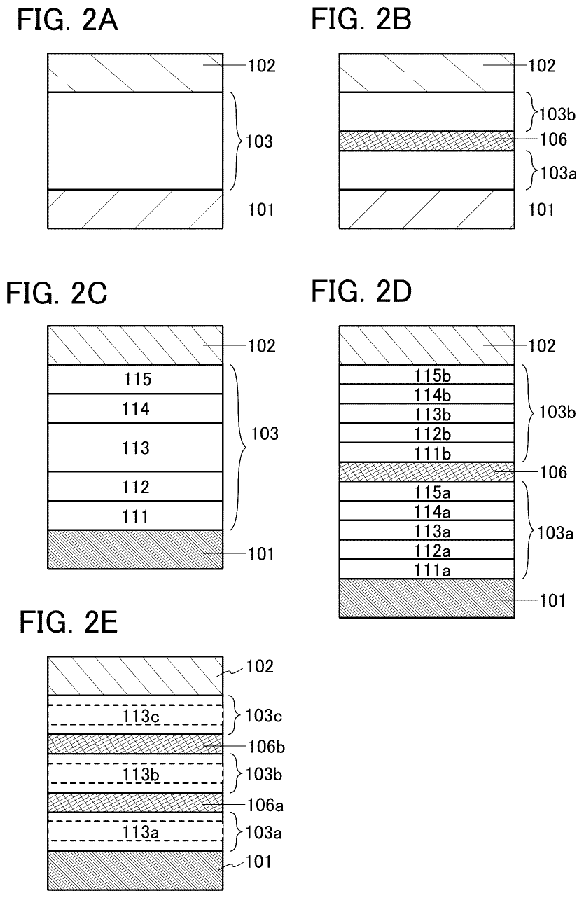

In this embodiment, another structure of the light-emitting device described in Embodiment 1 is described with reference to FIG. 2A to FIG. 2E.

### <<Basic Structure of Light-Emitting Device>>

A basic structure of a light-emitting device is described. FIG. 2A illustrates a light-emitting device in which an EL layer including a light-emitting layer is provided between a pair of electrodes. Specifically, the light-emitting device has a structure in which an EL layer 103 is sandwiched between the first electrode 101 and the second electrode 102.

FIG. 2B illustrates a light-emitting device with a stacked-layer structure (a tandem structure) in which a plurality of EL layers (103a and 103b) (two layers in FIG. 2B) are provided between a pair of electrodes and a charge-generation layer 106 is provided between the EL layers. With a light-emitting device having a tandem structure, a light-emitting apparatus with high efficiency can be achieved without changing the current amount.

The charge-generation layer 106 has a function of injecting electrons to one of the EL layers (103a or 103b) and injecting holes to the other of the EL layers (103b or 103a) when a potential difference is generated between the first electrode 101 and the second electrode 102. Thus, when voltage is applied such that the potential of the first electrode 101 is higher than that of the second electrode 102 in FIG. 2B, electrons are injected to the EL layer 103a and holes are injected to the EL layer 103b from the charge-generation layer 106.

Note that in terms of light extraction efficiency, itis preferable that the charge-generation layer 106 have a light-transmitting property with respect to visible light (specifically, the visible light transmittance with respect to the charge-generation layer 106 is preferably 40% or higher). Furthermore, the charge-generation layer 106 functions even when having lower conductivity than the first electrode 101 and the second electrode 102.

FIG. 2C illustrates a stacked-layer structure of the EL layer 103 in the light-emitting device of one embodiment of the present invention. Note that in this case, the first electrode 101 functions as an anode and the second electrode 102 functions as a cathode. The EL layer 103 has a structure in which the hole-injection layer 111, the hole-transport layer 112, a light-emitting layer 113, the electron-transport layer 114, and the electron-injection layer 115 are stacked sequentially over the first electrode 101. Note that the light-emitting layer 113 may have a stacked-layer structure of a plurality of light-emitting layers that emit light of different colors. For example, a light-emitting layer containing a light-emitting substance that emits red light, a light-emitting layer containing a light-emitting substance that emits green light, and a light-emitting layer containing a light-emitting substance that emits blue light may be stacked with or without a layer containing a carrier-transport material therebetween. Alternatively, a light-emitting layer containing a light-emitting substance that emits yellow light and a light-emitting layer containing a light-emitting substance that emits blue light may be used in combination. Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer containing a light-emitting substance that emits blue light and a second light-emitting layer containing a light-emitting substance that emits blue light may be stacked with or without a layer containing a carrier-transport material therebetween. The structure in which a plurality of light-emitting layers that emit light of the same color are stacked can achieve higher reliability than a single-layer structure in some cases. Even in the case where a plurality of EL layers are provided as in the tandem structure illustrated in FIG. 2B, the EL layers are sequentially stacked from the anode side as described above. When the first electrode 101 is a cathode and the second electrode 102 is an anode, the stacking order in the EL layer 103 is reversed. Specifically, the layer 111 over the first electrode 101 serving as the cathode represents an electron-injection layer; the layer 112, an electron-transport layer; the layer 113, a light-emitting layer; the layer 114, a hole-transport layer; and the layer 115, a hole-injection layer.

The light-emitting layers 113 included in the EL layers (103, 103a, and 103b) each contain an appropriate combination of a light-emitting substance and a plurality of substances, so that fluorescent light or phosphorescent light of a desired emission color can be obtained. Furthermore, the light-emitting layer 113 may have a stacked-layer structure having different emission colors. In that case, light-emitting substances and other substances may be different between the stacked light-emitting layers. Furthermore, a structure in which different emission colors can be obtained from the plurality of EL layers (103a and 103b) illustrated in FIG. 2B may be employed. Also in that case, light-emitting substances and other substances may be different between the stacked light-emitting layers.

In addition, the light-emitting device of one embodiment of the present invention can have an optical micro resonator (microcavity) structure with the first electrode 101 being a reflective electrode and the second electrode 102 being a transflective electrode in FIG. 2C, for example, and light emission obtained from the light-emitting layer 113 in the EL layer 103 can be resonated between the electrodes and light emitted through the second electrode 102 can be intensified.

Note that when the first electrode 101 of the light-emitting device is a reflective electrode having a stacked-layer structure of a reflective conductive material and a light-transmitting conductive material (a transparent conductive film), optical adjustment can be performed by adjusting the thickness of the transparent conductive film. Specifically, when the wavelength of light obtained from the light-emitting layer 113 is λ, the optical path length (the product of the film thickness and the refractive index) between the first electrode 101 and the second electrode 102 is preferably adjusted to mλ/2 (m is an integer of 1 or larger) or the vicinity thereof.

To amplify desired light (wavelength: λ) obtained from the light-emitting layer 113, the optical path length from the first electrode 101 to a region where the desired light is obtained in the light-emitting layer 113 (a light-emitting region) and the optical path length from the second electrode 102 to the region where the desired light is obtained in the light-emitting layer 113 (the light-emitting region) are each preferably adjusted to (2m′+1)λ/4 (m′ is an integer of 1 or larger) or the vicinity thereof. Here, the light-emitting region refers to a region where holes and electrons are recombined in the light-emitting layer 113.

By performing such optical adjustment, the spectrum of specific monochromatic light obtained from the light-emitting layer 113 can be narrowed and light emission with high color purity can be obtained.

Note that in the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained with given positions in the first electrode 101 and the second electrode 102 being supposed to be reflective regions. Furthermore, the optical path length between the first electrode 101 and the light-emitting layer from which the desired light is obtained is, to be exact, the optical path length between the reflective region in the first electrode 101 and the light-emitting region in the light-emitting layer from which the desired light is obtained. However, it is difficult to precisely determine the reflective region in the first electrode 101 and the light-emitting region in the light-emitting layer from which the desired light is obtained; thus, it is assumed that the above effect can be sufficiently obtained with a given position in the first electrode 101 being supposed to be the reflective region and a given position in the light-emitting layer from which the desired light is obtained being supposed to be the light-emitting region.

The light-emitting device illustrated in FIG. 2D is a light-emitting device having a tandem structure. Owing to a microcavity structure of the light-emitting device, light (monochromatic light) with different wavelengths from the EL layers (103a and 103b) can be extracted. Thus, side-by-side patterning for obtaining different emission colors (e.g., RGB) is not necessary. Therefore, higher definition can be easily achieved. In addition, a combination with coloring layers (color filters) is also possible. Furthermore, the emission intensity of light with a specific wavelength in the front direction can be increased, whereby power consumption can be reduced.

A light-emitting device illustrated in FIG. 2E is an example of the light-emitting device with the tandem structure illustrated in FIG. 2B, and includes three EL layers (103a, 103b, and 103c) stacked with charge-generation layers (106a and 106b) therebetween, as illustrated in the drawing. Note that the three EL layers (103a, 103b, and 103c) include respective light-emitting layers (113a, 113b, and 113c) and the emission colors of the light-emitting layers can be combined freely. For example, the light-emitting layer 113a can emit blue light, the light-emitting layer 113b can emit red, green, or yellow light, and the light-emitting layer 113c can emit blue light; for another example, the light-emitting layer 113a can emit red light, the light-emitting layer 113b can emit blue, green, or yellow light, and the light-emitting layer 113c can emit red light.

In the above light-emitting device of one embodiment of the present invention, at least one of the first electrode 101 and the second electrode 102 is a light-transmitting electrode (a transparent electrode, a transflective electrode, or the like). In the case where the light-transmitting electrode is a transparent electrode, the visible light transmittance of the transparent electrode is 40% or higher. In the case where the light-transmitting electrode is a transflective electrode, the visible light reflectance of the transflective electrode is higher than or equal to 20% and lower than or equal to 80%, preferably higher than or equal to 40% and lower than or equal to 70%. The resistivity of these electrodes is preferably 1×10⁻² Ωcm or lower.

In the case where one of the first electrode 101 and the second electrode 102 is an electrode having a reflecting property (a reflective electrode) in the above light-emitting device of one embodiment of the present invention, the visible light reflectance of the electrode having a reflecting property is higher than or equal to 40% and lower than or equal to 100%, preferably higher than or equal to 70% and lower than or equal to 100%. The resistivity of this electrode is preferably 1×10⁻² Ωcm or lower.

### <<Specific Structure of Light-Emitting Device>>

Next, a specific structure of the light-emitting device of one embodiment of the present invention will be described. Here, description is made using FIG. 2D illustrating the tandem structure. Note that the structure of the EL layer applies also to the light-emitting devices having single structures in FIG. 2A and FIG. 2C. In the case where the light-emitting device illustrated in FIG. 2D has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the EL layer 103b, with the use of a material selected as appropriate.

### <First Electrode and Second Electrode>

As materials for forming the first electrode 101 and the second electrode 102, any of the following materials can be used in an appropriate combination as long as the functions of the both electrodes described above can be fulfilled. For example, a metal, an alloy, an electrically conductive compound, and a mixture of these can be used as appropriate. Specifically, an In—Sn oxide (also referred to as ITO), an In—Si—Sn oxide (also referred to as ITSO), an In—Zn oxide, and an In—W—Zn oxide are given. In addition, it is also possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 in the periodic table, which is not listed above as an example (for example, lithium (Li), cesium (Cs), calcium (Ca), or strontium (Sr)), a rare earth metal such as europium (Eu) or ytterbium (Yb), an alloy containing an appropriate combination of any of these elements, graphene, or the like.

In the light-emitting device illustrated in FIG. 2D, when the first electrode 101 is an anode, a hole-injection layer 111a and a hole-transport layer 112a of the EL layer 103a are sequentially stacked over the first electrode 101 by a vacuum evaporation method. After the EL layer 103a and the charge-generation layer 106 are formed, a hole-injection layer 111b and a hole-transport layer 112b of the EL layer 103b are sequentially stacked over the charge-generation layer 106 in a similar manner.

### <Hole-Injection Layer>

The hole-injection layers (111, 111a, and 111b) are layers that inject holes from the first electrode 101 which is an anode and from the charge-generation layers (106, 106a, and 106b) to the EL layers (103, 103a, and 103b) and each contain an organic acceptor material and a material with a high hole-injection property.

The organic acceptor material is a material that allows holes to be generated in another organic compound whose HOMO level value is close to the LUMO level value of the organic acceptor material when charge separation is caused between the organic acceptor material and the organic compound. Thus, as the organic acceptor material, a compound having an electron-withdrawing group (a halogen group or a cyano group), such as a quinodimethane derivative, a chloranil derivative, or a hexaazatriphenylene derivative, can be used. For example, it is possible to use 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. Note that among organic acceptor materials, a compound in which electron-withdrawing groups are bonded to condensed aromatic rings each having a plurality of heteroatoms, such as HAT-CN, is particularly preferred because it has a high acceptor property and stable film quality against heat. Alternatively, a [3]radialene derivative having an electron-withdrawing group (in particular, a cyano group or a halogen group such as a fluoro group) has a very high electron-accepting property and thus is preferable. Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentatluorobenzeneacetonitrile], or the like can be used.

As the material having a high hole-injection property, an oxide of a metal belonging to Group 4 to Group 8 in the periodic table (e.g., a transition metal oxide such as a molybdenum oxide, a vanadium oxide, a ruthenium oxide, a tungsten oxide, or a manganese oxide) can be used. As specific examples, a molybdenum oxide, a vanadium oxide, a niobium oxide, a tantalum oxide, a chromium oxide, a tungsten oxide, a manganese oxide, and a rhenium oxide are given. In particular, a molybdenum oxide is preferable because it is stable in the air, has a low hygroscopic property, and is easily handled. It is also possible to use phthalocyanine (abbreviation: H₂Pc), a phthalocyanine-based compound such as copper phthalocyanine (abbreviation: CuPc), or the like.

In addition to the above materials, it is also possible to use an aromatic amine compound, which is a low molecular compound, such as 4,4′,4″-tris(N,N-diphenylamino)triphenylamine (abbreviation: TDATA), 4,4′,4″-tris[V-(3-methylphenyl)-V-phenylamino]triphenylamine (abbreviation: MTDATA), 4,4′-bis[N-(4-diphenylaminophenyl)-N-phenylamino]biphenyl (abbreviation: DPAB), AN-bis{4-[bis(3-methylphenyl)amino]phenyl}-N,N-diphenyl-(1,1-biphenyl)-4,4′-diamine (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), or 3-[N-(l-naphthyl)-N-(9-phenylcarbazol-3-yl)amino]-9-phenylcarbazole (abbreviation: PCzPCN1).

It is also possible to use a high molecular compound (an oligomer, a dendrimer, a polymer, or the like) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide] (abbreviation: PTPDMA), or poly[N,N′-bis(4-butylphenyl)-N,N′-bis(phenyl)benzidine] (abbreviation: Poly-TPD). It is also possible to use a high molecular compound to which acid such as poly(3,4-ethylenedioxythiophene)/polystyrenesulfonic acid (abbreviation: PEDOT/PSS) or polyaniline/polystyrenesulfonic acid (abbreviation: PAni/PSS) is added.

As the material with a high hole-injection property, a mixed material containing a hole-transport material and the above-described organic acceptor material (an electron-accepting material) can be used. In that case, the organic acceptor material extracts electrons from the hole-transport material, so that holes are generated in the hole-injection layer 111 and the holes are injected into the light-emitting layer 113 through the hole-transport layer 112. Note that the hole-injection layer 111 may be formed as a single layer of a mixed material containing the hole-transport material and the organic acceptor material (an electron-accepting material), or may be formed by stacking a layer containing the hole-transport material and a layer containing the organic acceptor material (the electron-accepting material).

The hole-transport material is preferably a substance having a hole mobility higher than or equal to 1×10⁻⁶ cm²/Vs in the case where the square root of the electric field strength [V/cm] is 600. Note that other substances can be used as long as they have a property of transporting more holes than electrons.

As the hole-transport material, a material having a high hole-transport property such as a compound having a π-electron rich heteroaromatic ring (e.g., a carbazole derivative, a furan derivative, or a thiophene derivative) or an aromatic amine (an organic compound having an aromatic amine skeleton), is preferable.

Examples of the above carbazole derivative (an organic compound having a carbazole ring) include a bicarbazole derivative (e.g., a 3,3′-bicarbazole derivative) and an aromatic amine having a carbazolyl group.

Specific examples of the above bicarbazole derivative (e.g., a 3,3′-bicarbazole derivative) include 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(1,1′-biphenyl-3-yl)-3,3′-bi-9H-carbazole (abbreviation: BismBPCz), 9-(1,1′-biphenyl-3-yl)-9′-(1,1′-biphenyl-4-yl)-9N,9′H-3,3′-bicarbazole (abbreviation: mBPCCBP), and 9-(2-naphthyl)-9′-phenyl-9H,9′H-3,3′-bicarbazole (abbreviation: PNCCP).

Specific examples of the above aromatic amine having a carbazolyl group include 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]-bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(91H-fluoren)-4-amine, N-[4-(9-phenyl-9H-carbazol-3-yl)phenyl]-N-(1.1′:3′,1″-terphenyl-4-yl)-9,9-dimethyl-9H-fluoren-2-amine, N-[4-(9-phenyl-9H-carbazol-3-yl)phenyl]-N-(1,1′4′,1″-terphenyl-4-yl)-9,9-dimethyl-9H-fluoren-2-amine, N-[4-(9-phenyl-9H-carbazol-3-yl)phenyl]-N-[1,1′:3′,1″-terphenyl-4-yl]-9,9-dimethyl-9H-fluoren-4-amine, N-[4-(9-phenyl-9H-carbazol-3-yl)phenyl]-N-[1,1′:4′,1″-terphenyl-4-yl]-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N-bis(9-phenylcarbazol-3-yl)-N,N′-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]spiro-9,9′-bifluoren-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

In addition to the above, other examples of the carbazole derivative include 3-[4-(9-phenanthryl)-phenyl]-9-phenyl-9H-carbazole (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the above furan derivative (an organic compound having a furan ring) include 4,4′,4″-(benzene-1,3,5-triyl)tri(dibenzofuran) (abbreviation: DBF3P-II), and 4-{3-[3-(9-phenyl-9H-fluoren-9-yl)phenyl]phenyl}dibenzofuran (abbreviation: mmDBFFLBi-II).

Specific examples of the above thiophene derivative (an organic compound having a thiophene ring) include organic compounds each having a thiophene ring such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Specific examples of the above aromatic amine include 4,4′-bis[N-(1-naphthyl)-V-phenylamino]biphenyl (abbreviation: NPB or α-NPD), N,N-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), A-(9,9-dimethyl-9H-fluoren-2-yl)-N-{9,9-dimethyl-2-[N-phenyl-N′-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]-spiro-9,9′-bifluorene (abbreviation: DPA2SF), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), DNTPD, 1,3,5-tris[A-(4-diphenylaminophenyl)-N-phenylamino]benzene (abbreviation: DPA3B), N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-AN-phenyl-4-biphenylamine (abbreviation: ThBA1BP), 4-(2-naphthyl)-4′,4″-diphenyltriphenylamine (abbreviation: BBApβNB), 4-[4-(2-naphthyl)phenyl]-4′,4″-diphenyltriphenylamine (abbreviation: BBAβNBi), 4,4′-diphenyl-4″-(6; 1′-binaphthyl-2-yl)triphenylamine (abbreviation: BBAαNβNB), 4,4′-diphenyl-4″-(7; 1′-binaphthyl-2-yl)triphenylamine (abbreviation: BBAαNβNB-03), 4,4′-diphenyl-4″-(7-phenyl)naphthyl-2-yl)triphenylamine (abbreviation: BBAPβNB-03), 4,4′-diphenyl-4″-(6; 2′-binaphthyl-2-yl)triphenylamine (abbreviation: BBA(βN2)B), 4,4′-diphenyl-4″-(7; 2′-binaphthyl-2-yl)triphenylamine (abbreviation: BBA(βN2)B-03), 4,4′-diphenyl-4″-(4; 2′-binaphthyl-1-yl)triphenylamine (abbreviation: BBAβNαNB), 4,4′-diphenyl-4″-(5; 2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβDNBi), 4-phenyl-4′-(1-naphthyl)-triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis([1,1′-biphenyl]-4-yl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[91H-fluoren]-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Alternatively, it is also possible to use, as the hole-transport material, a high molecular compound (e.g., an oligomer, a dendrimer, or a polymer) such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), poly[N,N-bis(4-butylphenyl)-N,N-bis(phenyl)benzidine] (abbreviation: Poly-TPD), or the like. Alternatively, it is also possible to use a high molecular compound to which acid such as poly(3,4-ethylenedioxythiophene)/polystyrenesulfonic acid (abbreviation: PEDOT/PSS), and polyaniline/polystyrenesulfonic acid (abbreviation: PAni/PSS) is added, or the like.

Note that the hole-transport material is not limited to the above, and one of or a combination of various known materials may be used as the hole-transport material.

Note that the hole-injection layers (111, 111a, and 111b) can be formed by any of various known deposition methods, and can be formed by a vacuum evaporation method, for example.

### <Hole-Transport Layer>

The hole-transport layers (112, 112a, and 112b) are each a layer that transports the holes, which are injected from the first electrode 101 by the hole-injection layers (111, 111a, and 111b), to the light-emitting layers (113, 113a, and 113b). Note that the hole-transport layers (112, 112a, and 112b) are each a layer containing a hole-transport material. Thus, for the hole-transport layers (112, 112a, and 112b), a hole-transport material that can be used for the hole-injection layers (111, 111a, and 111b) can be used.

Note that in the light-emitting device of one embodiment of the present invention, the organic compound used for the hole-transport layers (112, 112a, and 112b) can also be used for the light-emitting layers (113, 113a, and 113b). The use of the same organic compound for the hole-transport layers (112, 112a, and 112b) and the light-emitting layers (113, 113a, and 113b) is preferable, in which case holes can be efficiently transported from the hole-transport layers (112, 112a, and 112b) to the light-emitting layers (113, 113a, and 113b).

### <Light-Emitting Layer>

The light-emitting layers (113, 113a, and 113b) are each a layer containing a light-emitting substance. Note that as the light-emitting substance that can be used for the light-emitting layers (113, 113a, and 113b), a substance that exhibits an emission color of blue, violet, bluish violet, green, yellowish green, yellow, orange, red, or the like can be used as appropriate. In the case where a plurality of light-emitting layers are provided, different light-emitting substances are used for the light-emitting layers; thus, different emission colors can be exhibited (for example, complementary emission colors are combined to obtain white light emission). Furthermore, one light-emitting layer may have a stacked-layer structure containing different light-emitting substances.

The light-emitting layers (113, 113a, and 113b) may each contain one or more kinds of organic compounds (a host material and the like) in addition to a light-emitting substance (a guest material).

In the case where a plurality of host materials are used in the light-emitting layers (113, 113a, and 113b), a second host material that is additionally used is preferably a substance having a larger energy gap than those of a known guest material and a first host material. Preferably, the lowest singlet excitation energy level (S1 level) of the second host material is higher than the S1 level of the first host material, and the lowest triplet excitation energy level (T1 level) of the second host material is higher than the T1 level of the guest material. Furthermore, the lowest triplet excitation energy level (T1 level) of the second host material is preferably higher than the T1 level of the first host material. With such a structure, an exciplex can be formed by the two kinds of host materials. To form an exciplex efficiently, it is particularly preferable to combine a compound that easily accepts holes (a hole-transport material) and a compound that easily accepts electrons (an electron-transport material). With this structure, high efficiency, low voltage, and a long lifetime can be achieved at the same time.

As an organic compound used as the above host material (including the first host material and the second host material), organic compounds such as the hole-transport materials that can be used for the hole-transport layers (112, 112a, and 112b) described above and electron-transport materials that can be used for electron-transport layers (114, 114a, and 114b) described later can be used as long as they satisfy requirements for the host material used in the light-emitting layer. Another example is an exciplex formed by a plurality of kinds of organic compounds (the first host material and the second host material). An exciplex (also referred to as Exciplex) whose excited state is formed by a plurality of kinds of organic compounds has an extremely small difference between the S1 level and the T1 level and has a function of a TADF material capable of converting triplet excitation energy into singlet excitation energy. As a combination of the plurality of kinds of organic compounds forming an exciplex, for example, it is preferable that one have a π-electron deficient heteroaromatic ring and the other have a π-electron rich heteroaromatic ring. A phosphorescent substance such as an iridium-, rhodium-, or platinum-based organometallic complex or metal complex may be used as one of the combination forming an exciplex.

The light-emitting substance that can be used in the light-emitting layers (113, 113a, and 113b) is not particularly limited, and a light-emitting substance that converts singlet excitation energy into light emission in the visible light range or a light-emitting substance that converts triplet excitation energy into light emission in the visible light range can be used.

<<Light-Emitting Substance that Converts Singlet Excitation Energy into Light>>

The following substances emitting fluorescent light (fluorescent substances) are given as the light-emitting substance that can be used for the light-emitting layers (113, 113a, and 113b) and convert singlet excitation energy into light emission. The examples include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N-bis(3-methylphenyl)-N,N′-bis[3-(9-phenyl-9H-fluoren-9-yl)phenyl]pyrene-1,6-diamine (abbreviation: 1,6mMemFLPAPrn), N,N′-diphenyl-N,N′-bis[4-(9-phenyl-91H-fluoren-9-yl)phenyl]pyrene-1,6-diamine (abbreviation: 1,6FLPAPrn), N,N′-bis(dibenzofuran-2-yl)-N,N-diphenylpyrene-1,6-diamine (abbreviation: 1,6FrAPrn), N,N′-bis(dibenzothiophen-2-yl)-N,N′-diphenylpyrene-1,6-diamine (abbreviation: 1,6ThAPrn), N,N-(pyrene-1,6-diyl)bis[(N,N′-phenylbenzo[b]naphtho[1,2-d]furan)-6-amine] (abbreviation: 1,6BnfAPrn), N,N-(pyrene-1,6-diyl)bis[(N-phenylbenzo[b]naphtho[1,2-d]furan)-8-amine] (abbreviation: 1,6BnfAPrn-02), and N,N-(pyrene-1,6-diyl)bis[(6,N-diphenylbenzo[b]naphtho[1,2-d]furan)-8-amine] (abbreviation: 1,6BnfAPrn-03).

In addition, it is possible to use 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N″-(2-tert-butylanthracene-9,10-diyldi-4,1-phenylene)bis[N,N′,N″-triphenyl-1,4-phenylenediamine] (abbreviation: DPABPA), N,9-diphenyl-N—[4-(9,10-diphenyl-2-anthryl)phenyl]-9H-carbazol-3-amine (abbreviation: 2PCAPPA), N-[4-(9,10-diphenyl-2-anthryl)phenyl]-N,N′N′-triphenyl-1,4-phenylenediamine (abbreviation: 2DPAPPA), or the like.

It is also possible to use, for example, N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), 1,6BnfAPrn-03, 3,10-bis[N-(9-phenyl-9H-carbazol-2-yl)-N-phenylamino]naphtho[2,3-b; 6,7-b′]bisbenzofuran (abbreviation: 3,10PCA2Nbf(IV)-02), and 3,10-bis[N-(dibenzofuran-3-yl)-N-phenylamino]naphtho[2,3-b; 6,7-b′]bisbenzofuran (abbreviation: 3,10FrA2Nbf(IV)-02). In particular, a pyrenediamine compound such as 1,6FLPAPrn, 1,6mMemFLPAPrn, or 1,6BnfAPrn-03 can be used, for example.

<<Light-Emitting Substance that Converts Triplet Excitation Energy into Light Emission>>

Next, as examples of the light-emitting substance that converts triplet excitation energy into light emission and can be used for the light-emitting layer 113, a substance that emits phosphorescent light (a phosphorescent substance) and a thermally activated delayed fluorescent (TADF) material that exhibits thermally activated delayed fluorescence are given.

A phosphorescent substance refers to a compound that exhibits phosphorescence but does not exhibit fluorescence at a temperature higher than or equal to low temperatures (e.g., 77 K) and lower than or equal to room temperature (i.e., higher than or equal to 77 K and lower than or equal to 313 K). The phosphorescent substance preferably contains a metal element with large spin-orbit interaction, and can be an organometallic complex, a metal complex (a platinum complex), a rare earth metal complex, or the like. Specifically, a transition metal element is preferable and it is particularly preferable that a platinum group element (ruthenium (Ru), rhodium (Rh), palladium (Pd), osmium (Os), iridium (Ir), or platinum (Pt)), especially iridium, be contained, in which case the transition probability relating to direct transition between the singlet ground state and the triplet excited state can be increased.

<<Phosphorescent Substance (from 450 nm to 570 nm: Blue or Green)>>

As a phosphorescent substance that exhibits blue or green and whose emission spectrum has a peak wavelength at greater than or equal to 450 nm and less than or equal to 570 nm, the following substances are given.

The examples include: organometallic complexes having a 4H-triazole ring, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr5btz)₃]); organometallic complexes having a 1H-triazole ring, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic complexes having an imidazole ring, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); and organometallic complexes in which a ligand is a phenylpyridine derivative having an electron-withdrawing group such as bis[2-(4′,6′-difluorophenyl)pyridinato-N,C^{2′}]iridium(III) tetrakis(I-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)).

<<Phosphorescent Substance (from 495 nm to 590 nm: Green or Yellow)>>

As a phosphorescent substance that exhibits green or yellow and whose emission spectrum has a peak wavelength at greater than or equal to 495 nm and less than or equal to 590 nm, the following substances are given.

The examples include: organometallic iridium complexes having a pyrimidine ring, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine ring, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine ring, such as tris(2-phenylpyridinato-N,C^{2′})iridium(III) (abbreviation: [Ir(ppy)₃]), bis(2-phenylpyridinato-N,C²)iridium(III) acetylacetonate (abbreviation: [Ir(ppy)₂(acac)]), bis(benzo[f,h]quinolinato)iridium(III) acetylacetonate (abbreviation: [Ir(bzq)₂(acac)]), tris(benzo[f,h]quinolinato)iridium(III) (abbreviation: [Ir(bzq)₃]), tris(2-phenylquinolinato-N,C^{2′})iridium(I) (abbreviation: [Ir(pq)₃]), bis(2-phenylquinolinato-N,C^{2′})iridium(I) acetylacetonate (abbreviation: [Ir(pq)₂(acac)]), bis[2-(2-pyridinyl-κN)phenyl-KC][2-(4-phenyl-2-pyridinyl-κN)phenyl-κC]iridium(III) (abbreviation: [Ir(ppy)₂(4dppy)]), bis[2-(2-pyridinyl-κN)phenyl-κC][2-(4-methyl-5-phenyl-2-pyridinyl-κA)phenyl-κC], [2-d3-methyl-8-(2-pyridinyl-κN)benzofuro[2,3-b]pyridine-κC]bis[2-(5-d3-methyl-2-pyridinyl-κN2)phenyl-κC]iridium(III) (abbreviation: Ir(5mppy-d3)₂(mbfpypy-d3)), [2-(methyl-d3)-8-[4-(1-methylethyl-1-d)-2-pyridinyl-κN]benzofuro[2,3-b]pyridine-7-yl-κC]bis[5-(methyl-d3)-2-[5-(methyl-d3)-2-pyridinyl-κN]phenyl-κC]iridium(III) (abbreviation: Ir(5mtpy-d6)₂(mbfpypy-iPr-d4)), [2-d3-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d3)), and [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); organometallic complexes such as bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C^{2′}}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and rare earth metal complexes such as tris(acetylacetonato)(monophenanthroline)terbium(III) (abbreviation: [Tb(acac)₃(Phen)]).

<<Phosphorescent Substance (from 570 nm to 750 nm: Yellow or Red)>>

As a phosphorescent material that exhibits yellow or red and whose emission spectrum has a peak wavelength at greater than or equal to 570 nm and less than or equal to 750 nm, the following substances are given.

The examples include organometallic complexes having a pyrimidine ring, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(d1npm)₂(dpm)]); organometallic complexes having a pyrazine ring, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-κN]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), bis[2-(5-(2,6-dimethylphenyl)-3-(3,5-dimethylphenyl)-2-pyrazinyl-κN)-4,6-dimethylphenyl-κC](2,2′,6,6′-tetramethyl-3,5-heptadionato-κ²O,O′)iridium(III) (abbreviation: [Ir(dmdppr-dmp)₂(dpm)]), (acetylacetonato)bis[2-methyl-3-phenylquinoxalinato-N,C^{2′}]iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine ring, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), and bis[4,6-dimethyl-2-(2-quinolinyl-κN)phenyl-κC](2,4-pentanedionato-κ²O,O′)iridium(III) (abbreviation: [Ir(dmpqn)₂(acac)]); platinum complexes such as 2,3,7,8,12,13,17,18-octaethyl-21H,23H-porphyrinplatinum(II) (abbreviation: [PtOEP]); and rare earth metal complexes such as tris(1,3-diphenyl-1,3-propanedionato)(monophenanthroline)europium(II) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]).

### <<TADF Material>>

Any of materials shown below can be used as the TADF material. The TADF material refers to a material that has a small difference (preferably, less than or equal to 0.2 eV) between the S1 level and the T1 level, can up-convert a triplet excited state into a singlet excited state (reverse intersystem crossing) using a little thermal energy, and efficiently exhibits light emission (fluorescence) from the singlet excited state. The thermally activated delayed fluorescence is efficiently obtained under the condition where the difference in energy between the triplet excited energy level and the singlet excited energy level is greater than or equal to 0 eV and less than or equal to 0.2 eV, preferably greater than or equal to 0 eV and less than or equal to 0.1 eV. Delayed fluorescence by the TADF material refers to light emission having a spectrum similar to that of normal fluorescence and an extremely long lifetime. The lifetime is 1×10⁻⁶ seconds or longer, preferably 1×10⁻³ seconds or longer.

Examples of the TADF material include fullerene, a derivative thereof, an acridine derivative such as proflavine, and eosin. Other examples include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4 Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

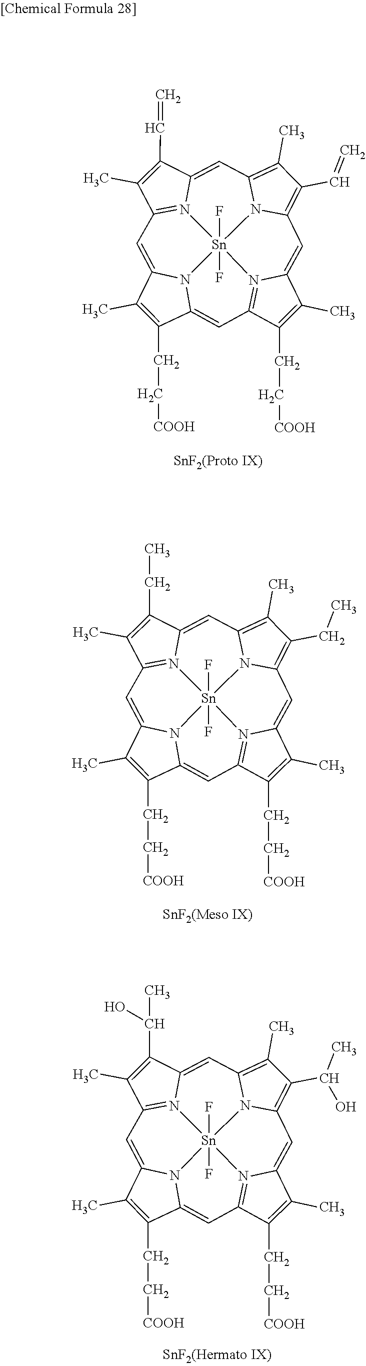

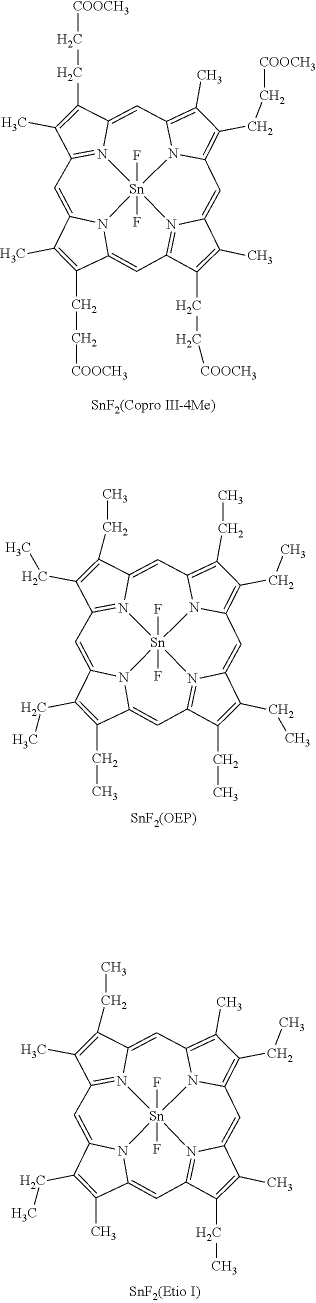

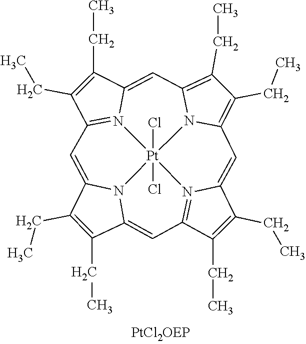

Alternatively, any of heteroaromatic compounds having a π-electron rich heteroaromatic compound and a π-electron deficient heteroaromatic compound, such as 2-(biphenyl-4-yl)-4,6-bis(12-phenylindolo[2,3-a]carbazol-11-yl)-1,3,5-triazine (abbreviation: PIC-TRZ), 2-{4-[3-(N phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbazol-9-yl)benzofuro[3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), and 9-[3-(4,6-diphenyl-1,3,5-triazin-2-yl)phenyl]-9′-phenyl-2,3′-bi-9H-carbazole (abbreviation: mPCCzPTzn-02), may be used.

Note that a substance in which a π-electron rich heteroaromatic compound is directly bonded to a π-electron deficient heteroaromatic compound is particularly preferable because both the donor property of the π-electron rich heteroaromatic compound and the acceptor property of the π-electron deficient heteroaromatic compound become strong and the energy difference between the singlet excited state and the triplet excited state becomes small. As the TADF material, a TADF material (TADF 100) in which a singlet excited state and a triplet excited state is in a thermal equilibrium state may be used. Since such a TADF material enables a short emission lifetime (excitation lifetime), a decrease in efficiency of a light-emitting device in a high-luminance region can be inhibited.

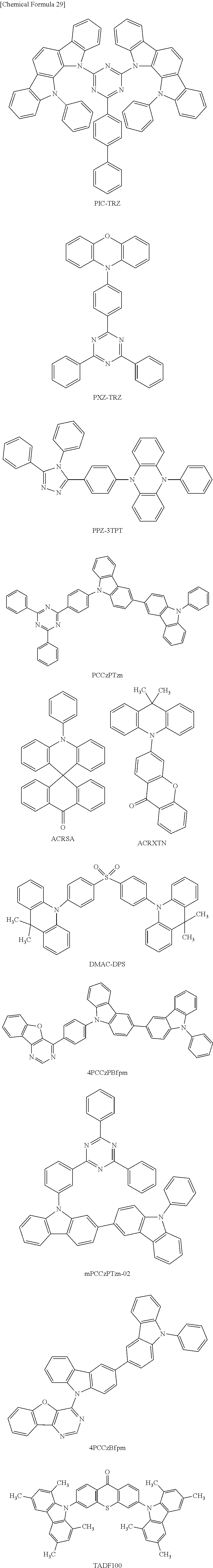

As the material having a function of converting triplet excitation energy into light emission, a nanostructure of a transition metal compound having a perovskite structure is also given in addition to the above. In particular, a nanostructure of a metal-halide perovskite material is preferable. The nanostructure is preferably a nanoparticle or a nanorod.

As the organic compounds (the host material and the like) used in combination with the above-described light-emitting substance (the guest material) in the light-emitting layers (113, 113a, 113b, and 113c), one or more kinds of substances having a larger energy gap than the light-emitting substance (the guest material) may be selected to be used.

### <<Host Material for Fluorescent Light Emission>>

In the case where the light-emitting substance used in the light-emitting layers (113, 113a, 113b, and 113c) is a fluorescent substance, an organic compound (a host material) used in combination with the light-emitting substance is preferably an organic compound that has a high energy level in a singlet excited state and has a low energy level in a triplet excited state or an organic compound having a high fluorescence quantum yield. Therefore, the hole-transport material (described above) and the electron-transport material (described below) in this embodiment, for example, can be used as long as it is an organic compound that satisfies such a condition. The first organic compound and the second organic compound described in Embodiment 1 can also be used.

In terms of a preferable combination with the light-emitting substance (the fluorescent substance), examples of the organic compound (the host material) include condensed polycyclic aromatic compounds such as an anthracene derivative, a tetracene derivative, a phenanthrene derivative, a pyrene derivative, a chrysene derivative, and a dibenzo[g,p]chrysene derivative, although some of them overlap with the above specific examples.

Note that specific examples of the organic compound (the host material) preferably used in combination with the fluorescent substance include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), 3-[4-(1-naphthyl)-phenyl]-9-phenyl-9H-carbazole (abbreviation: PCPN), 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)-biphenyl-4′-yl}-anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9-(1-naphthyl)-10-(2-naphthyl)anthracene (abbreviation: α,βADN), 2-(10-phenylanthracen-9-yl)dibenzofuran, 2-(10-phenyl-9-anthracenyl)-benzo[b]naphtho[2,3-d]furan (abbreviation: Bnf(II)PhA), 9-(1-naphthyl)-10-[4-(2-naphthyl)phenyl]anthracene (abbreviation: αN-PNPAnth), 2,9-di(1-naphthyl)-10-phenylanthracene (abbreviation: 2αN-αNPhA), 9-(1-naphthyl)-10-[3-(1-naphthyl)phenyl]anthracene (abbreviation: αN-mαNPAnth), 9-(2-naphthyl)-10-[3-(1-naphthyl)phenyl]anthracene (abbreviation: βN-mαNPAnth), 9-(1-naphthyl)-10-[4-(1-naphthyl)phenyl]anthracene (abbreviation: αN-αNPAnth), 9-(2-naphthyl)-10-[4-(2-naphthyl)phenyl]anthracene (abbreviation: βN-βrNPAnth), 2-(1-naphthyl)-9-(2-naphthyl)-10-phenylanthracene (abbreviation: 2αN-βNPhA), 9-(2-naphthyl)-10-[3-(2-naphthyl)phenyl]anthracene (abbreviation: βN-mβNPAnth), 1-[4-(10-[1,1′-biphenyl]-4-yl-9-anthracenyl)phenyl]-2-ethyl-1H-benzimidazole (abbreviation: EtBImPBPhA), 9,9′-bianthryl (abbreviation: BANT). 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(I-pyrenyl)benzene (abbreviation: TPB3), 5,12-diphenyltetracene, 5,12-bis(biphenyl-2-yl)tetracene, and the like.

### <<Host Material for Phosphorescent Light>>

In the case where the light-emitting substance used for the light-emitting layers (113, 113a, 113b, and 113c) is a phosphorescent substance, an organic compound having triplet excitation energy (energy difference between a ground state and a triplet excited state) which is higher than that of the light-emitting substance is preferably selected as the organic compound (the host material) used in combination with the light-emitting substance. Note that in the case where a plurality of organic compounds (e.g., a first host material and a second host material (or an assist material)) are used in combination with a light-emitting substance in order to form an exciplex, the plurality of organic compounds are preferably mixed with a phosphorescent substance.

Such a structure makes it possible to efficiently obtain light emission utilizing ExTET (Exciplex-Triplet Energy Transfer), which is energy transfer from an exciplex to a light-emitting substance. Note that a combination of the plurality of organic compounds that easily forms an exciplex is preferably employed, and it is particularly preferable to combine a compound that easily accepts holes (a hole-transport material) and a compound that easily accepts electrons (an electron-transport material).

In terms of a preferable combination with the light-emitting substance (phosphorescent substance), examples of the organic compounds (the host material and the assist material) include an aromatic amine (an organic compound having an aromatic amine skeleton), a carbazole derivative (an organic compound having a carbazole ring), a dibenzothiophene derivative (an organic compound having a dibenzothiophene ring), a dibenzofuran derivative (an organic compound having a dibenzofuran ring), an oxadiazole derivative (an organic compound having an oxadiazole ring), a triazole derivative (an organic compound having a triazole ring), a benzimidazole derivative (an organic compound having a benzimidazole ring), a quinoxaline (an organic compound having a quinoxaline ring) derivative, a dibenzoquinoxaline derivative (an organic compound having a dibenzoquinoxaline ring), a pyrimidine derivative (an organic compound having a pyrimidine ring), a triazine derivative (an organic compound having a triazine ring), a pyridine derivative (an organic compound having a pyridine ring), a bipyridine derivative (an organic compound having a bipyridine ring), a phenanthroline derivative (an organic compound having a phenanthroline ring), a furodiazine derivative (an organic compound having a furodiazine ring), and zinc- or aluminum-based metal complexes, although some of them overlap with the above specific examples.

Among the above organic compounds, specific examples of the aromatic amine and the carbazole derivative, which are organic compounds having a high hole-transport property, are the same as the specific examples of the hole-transport materials described above. Any of these is preferable as the host material.

Among the above organic compounds, specific examples of the dibenzothiophene derivative and the dibenzofuran derivative, which are organic compounds having a high hole-transport property, include 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri(dibenzofuran) (abbreviation: DBF3P-II), DBT3P-II, 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), and 4-[3-(triphenylen-2-yl)phenyl]dibenzothiophene (abbreviation: mDBTPTp-II). Any of these examples is preferred as the host material.

In addition, a metal complex having an oxazole-based or thiazole-based ligand, such as bis[2-(2-benzoxazolyl)phenolato]zinc(II) (abbreviation: ZnPBO) or bis[2-(2-benzothiazolyl)phenolato]zinc(II) (abbreviation: ZnBTZ), or the like is given as a preferred example of the host material.

Among the above organic compounds, specific examples of the oxadiazole derivative, the triazole derivative, the benzimidazole derivative, the quinoxaline derivative, the dibenzoquinoxaline derivative, the quinazoline derivative, the phenanthroline derivative, and the like, which are organic compounds having a high electron-transport property, include an organic compound including a heteroaromatic ring having a polyazole ring such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs); an organic compound including a heteroaromatic ring having a pyridine ring such as bathophenanthroline (abbreviation: Bphen), bathocuproine (abbreviation: BCP), and 2,9-di(naphthalen-2-yl)-4,7-diphenyl-1,10-phenanthroline (abbreviation: NBphen); 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-{4-[9,10-di(2-naphthyl)-2-anthryl]phenyl}-1-phenyl-1H-benzimidazole (abbreviation: ZADN), and 2-[4′-(9-phenyl-9H-carbazol-3-yl)-3,1′-biphenyl-1-yl]dibenzo[f,h]quinoxaline (abbreviation: 2mpPCBPDBq). Any of these examples is preferred as the host material.

Among the above organic compounds, specific examples of the pyridine derivative, the diazine derivative (including the pyrimidine derivative, the pyrazine derivative, and the pyridazine derivative), the triazine derivative, the furodiazine derivative, which are organic compounds having a high electron-transport property, include an organic compound including a heteroaromatic ring having a diazine ring such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(V-phenyl-91-carbazol-3-yl)-91-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 9,9′-[pyrimidine-4,6-diylbis(biphenyl-3,3′-diyl)]bis(9H-carbazole) (abbreviation: 4,6mCzBP2Pm), 2-[3′-(9,9-dimethyl-9H-fluoren-2-yl)-1,1′-biphenyl-3-yl]-4,6-diphenyl-1,3,5-triazine (abbreviation: mFBPTzn), 8-(1,1′-biphenyl-4-yl)-4-[3-(dibenzothiophen-4-yl)phenyl]-[1]benzofuro[3,2-d]pyrindine (abbreviation: 8BP-4nDBtPBfpnm), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 11-[3′-(dibenzothiophen-4-yl)biphenyl-3-yl]phenanthro[9′,10′:4,5]furo[2,3-b]pyrazine (abbreviation: 1IrnDBtBPPnfpr), 11-[3′-dibenzothiophen-4-yl)biphenyl-4-yl]phenanthro[9′,10′:4,5]furo[2,3-b]pyrazine, 11-[(3′-(9H-carbazol-9-yl)-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[(3′-9-phenyl-9H-carbazol-3-yl)biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9_H carbazol-9-yl)naphtho[1′,2′:4,5]furo[2,3-b]pyrazine (abbreviation: 10PCCzNfpr), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl)biphenyl-3-yl]naphtho[1′,2′:4,5]furo[2,3-b]pyrazine (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-{(3′-[2,8-diphenyldibenzothiophen-4-yl)biphenyl-3-yl}naphtho[1′,2′:4,5]furo[2,3-b]pyrazine, 11-{(3′-[2,8-diphenyldibenzothiophen-4-yl)biphenyl-3-yl]phenanthro[9′,10′:4,5]furo[2,3-b]pyrazine, 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)-1,1′-biphenyl-3-yl]-4,6-diphenyl-1,3,5-triazine (abbreviation: mTpBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn), 6-(1,1′-biphenyl-3-yl)-4-[3,5-bis(9H-carbazol-9-yl)phenyl]-2-phenylpyrimidine (abbreviation: 6mBP-4Cz2PPm), and 4-[3,5-bis(9H-carbazol-9-yl)phenyl]-2-phenyl-6-(1,1′-biphenyl-4-yl)pyrimidine (abbreviation: 6BP-4Cz2PPm). Any of these examples is preferred as the host material.

Among the above organic compounds, specific examples of the metal complexes, which are organic compounds having a high electron-transport property, include zinc- and aluminum-based metal complexes, such as tris(8-quinolinolato)aluminum(III) (abbreviation: Alq), tris(4-methyl-8-quinolinolato)aluminum(III) (abbreviation: Almq₃), bis(10-hydroxybenzo[f,h]quinolinato)beryllium(II) (abbreviation: BeBq₂), bis(2-methyl-8-quinolinolato)(4-phenylphenolato)aluminum(III) (abbreviation: BAlq), and bis(8-quinolinolato)zinc(II) (abbreviation: Znq), and metal complexes having a quinoline ring or a benzoquinoline ring. Any of these examples is preferred as the host material.

In addition, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) or the like is also preferred as the host material.

Furthermore, an organic compound having a bipolar property, i.e., both a high hole-transport property and a high electron-transport property, and including a diazine ring, such as 9-phenyl-9′-(4-phenyl-2-quinazolinyl)-3,3′-bi-9H-carbazole (abbreviation: PCCzQz), 2-[4′-(9-phenyl-9H-carbazol-3-yl)-3,1′-biphenyl-1-yl]dibenzo[f,h]quinoxaline (abbreviation: 2mpPCBPDBq), 5-[3-(4,6-diphenyl-1,3,5-triazin-2-yl)phenyl]-7,7-dimethyl-5H,7H-indeno[2,1-b]carbazole (abbreviation: mINc(II)PTzn), 11-(4-[1,1′-biphenyl)-4-yl)-6-phenyl-1,3,5-triazin-2-yl]-11,12-dihydro-12-phenyl-indolo[2,3-a]carbazole (abbreviation: BP-Icz(II)Tzn), or 7-[4-(9-phenyl-9H-carbazol-2-yl)quinazolin-2-yl]-7H-dibenzo[c,g]carbazole (abbreviation: PC-cgDBCzQz), can be used as the host material.

### <Electron-Transport Layer>

The electron-transport layers (114, 114a, and 114b) are each a layer that transports the electrons, which are injected from the second electrode 102 and charge-generation layers (106, 106a, and 106b) by the electron-injection layers (115, 115a, and 115b) to be described later, to the light-emitting layers (113, 113a, and 113b). Note that the heat resistance of the light-emitting device of one embodiment of the present invention can be improved by including a stacked-layer structure in the electron-transport layer. It is preferable that the electron-transport materials used in the electron-transport layers (114, 114a, and 114b) be substances with an electron mobility higher than or equal to 1×10⁻⁶ cm²/Vs in the case where the square root of the electric field strength [V/cm] is 600. Note that other substances can also be used as long as they have an electron-transport property higher than a hole-transport property. Each of the electron-transport layers (114, 114a, and 114b) function even in the form of a single layer but may have a stacked-layer structure of two or more layers. Note that since the above-described mixed material has heat resistance, performing a photolithography step over the electron-transport layer including such a material can inhibit the influence of a thermal process on the device characteristics.

### <<Electron-Transport Material>>

As the electron-transport material that can be used for the electron-transport layers (114, 114a, and 114b), an organic compound with a high electron-transport property can be used; for example, a heteroaromatic compound can be used. The heteroaromatic compound refers to a cyclic compound containing at least two different kinds of elements in a ring. Examples of cyclic structures include a three-membered ring, a four-membered ring, a five-membered ring, a six-membered ring, and the like, among which a five-membered ring and a six-membered ring are particularly preferable; the elements contained in the heteroaromatic compound are preferably one or more of nitrogen, oxygen, sulfur, and the like, as well as carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and π-electron deficient heteroaromatic compound including the nitrogen-containing heteroaromatic compound, is preferably used. Note that the electron-transport material is preferably different from the materials used in the light-emitting layer. Not all excitons formed by recombination of carriers in the light-emitting layer can contribute to light emission and some excitons are diffused into a layer in contact with the light-emitting layer or a layer in the vicinity of the light-emitting layer. In order to avoid this phenomenon, the energy level (the lowest singlet excitation energy level or the lowest triplet excitation energy level) of a material used for the layer in contact with the light-emitting layer or the layer in the vicinity of the light-emitting layer is preferably higher than that of a material used for the light-emitting layer. Thus, in order to obtain a highly efficient device, the electron-transport material is preferably different from the materials used in the light-emitting layer.

The heteroaromatic compound is an organic compound including at least one heteroaromatic ring.

Note that the heteroaromatic ring includes any one of a pyridine ring, a diazine ring, a triazine ring, a polyazole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having a polyazole ring includes a heteroaromatic ring having an imidazole ring, a triazole ring, or an oxadiazole ring.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of a heteroaromatic compound including carbon and one or more of nitrogen, oxygen, sulfur, and the like and having a five-membered ring structure include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of a heteroaromatic compound including carbon and one or more of nitrogen, oxygen, sulfur, and the like and having a six-membered ring structure include a heteroaromatic compound having a heteroaromatic ring such as a pyridine ring, a diazine ring (a pyrimidine ring, a pyrazine ring, a pyridazine ring, or the like), a triazine ring, or a polyazole ring. Other examples include a heteroaromatic compound having a bipyridine structure and a heteroaromatic compound having a terpyridine structure, which are included in heteroaromatic compounds in which pyridine rings are connected.

Examples of the heteroaromatic compound having a fused ring structure including the above six-membered ring structure as a part include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to the furan ring of a furodiazine ring), or a benzimidazole ring.

Specific examples of the above-described heteroaromatic compound having a five-membered ring structure (e.g., a polyazole ring (including an imidazole ring, a triazole ring, an oxadiazole ring), an oxazole ring, a thiazole ring, or a benzimidazole ring) include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs).

Specific examples of the above-described heteroaromatic compound having a six-membered ring structure (including a heteroaromatic ring having a pyridine ring, a diazine ring, a triazine ring, or the like) include a heteroaromatic compound including a heteroaromatic ring having a pyridine ring, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB), a heteroaromatic compound including a heteroaromatic ring having a triazine ring, such as 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)-1,1′-biphenyl-3-yl]-4,6-diphenyl-1,3,5-triazine (abbreviation: mTpBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn), 2-{3-[3-(dibenzothiophen-4-yl)phenyl]phenyl}-4,6-diphenyl-1,3,5-triazine (abbreviation: mDBtBPTzn), or mFBPTzn, and a heteroaromatic compound including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 4,6mCzBP2Pm, 6-(1,1′-biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(1,1′-biphenyl-4-yl)pyrimidine (abbreviation: 6BP-4Cz2PPm), 4-[3-(dibenzothiophen-4-yl)phenyl]-8-(naphthalen-2-yl)-[1]benzofuro[3,2-d]pyrimidine (abbreviation: 8PN-4mDBtPBfpm), 8BP-4mDBtPBfpm, 9mDBtBPNfpr, 9pmDBtBPNfpr, 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(1,1′-biphenyl-3-yl)]naphtho[1′,2′:4,5]furo[3,2-d]pyrimidine (abbreviation: 8mDBtBPNfpm), or 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm). Note that the above aromatic compounds including a heteroaromatic ring include a heteroaromatic compound having a fused heteroaromatic ring.

Other examples include a heteroaromatic compound including a heteroaromatic ring having a diazine (pyrimidine) ring, such as 2,2′-(pyridine-2,6-diyl)bis(4-phenylbenzo[f,h]quinazoline) (abbreviation: 2,6(P-Bqn)2Py), 2,2′-(2,2′-bipyridine-6,6′-diyl)bis(4-phenylbenzo[f,h]quinazoline) (abbreviation: 6,6′(P-Bqn)2BPy), 2,2′-(pyridine-2,6-diyl)bis{4-[4-(2-naphthyl)phenyl]-6-phenylpyrimidine} (abbreviation: 2,6(NP—PPm)2Py), or 6-(1,1′-biphenyl-3-yl)-4-[3,5-bis(9H-carbazol-9-yl)phenyl]-2-phenylpyrimidine (abbreviation: 6mBP-4Cz2PPm), and a heteroaromatic compound including a heteroaromatic ring having a triazine ring, such as 2,4,6-tris[3′-(pyridin-3-yl)biphenyl-3-yl]-1,3,5-triazine (abbreviation: TmPPPyTz), 2,4,6-tris(2-pyridyl)-1,3,5-triazine (abbreviation: 2Py3Tz), or 2-[3-(2,6-dimethyl-3-pyridyl)-5-(9-phenanthryl)phenyl]-4,6-diphenyl-1,3,5-triazine (abbreviation: mPn-mDMePyPTzn).

Specific examples of the above-described heteroaromatic compound having a fused ring structure including the six-membered ring structure as a part (a heteroaromatic compound having a fused ring structure) include a heteroaromatic compound having a quinoxaline ring, such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(pyridine-2,6-diyl)bis(4-phenylbenzo[f,h]quinazoline) (abbreviation: 2,6(P-Bqn)2Py), 2-[3-(dibenzothiophen-4-yl)phenyl]dibenzo[f,h]quinoxaline (abbreviation: 2mDBTPDBq-1U), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-91-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-IJ), or 2mpPCBPDBq.

For the electron-transport layers (114, 114a, and 114b), any of the metal complexes given below as well as the heteroaromatic compounds given above can be used. Examples of the metal complexes include a metal complex having a quinoline ring or a benzoquinoline ring, such as tris(8-quinolinolato)aluminum(III) (abbreviation: Alq₃), Almq₃, 8-(quinolinolato)lithium (abbreviation: Liq), BeBq₂, bis(2-methyl-8-quinolinolato)(4-phenylphenolato)aluminum(III) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO) or bis[2-(2-benzothiazolyl)phenolato]zinc(II) (abbreviation: ZnBTZ).

A high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can also be used as an electron-transport material.

The electron-transport layer (114, 114a, or 114b) is not limited to a single layer, and may be a stack of two or more layers made of the above substances.

### <Electron-Injection Layer>

The electron-injection layers (115, 115a, and 115b) are each a layer containing a substance having a high electron-injection property. The electron-injection layers (115, 115a, and 115b) are each a layer for increasing the efficiency of electron injection from the second electrode 102 and are each preferably formed using a material whose LUMO level value has a small difference (0.5 eV or less) from the work function value of the material used for the second electrode 102. Thus, the electron-injection layer 115 can be formed using an alkali metal, an alkaline earth metal, or a compound thereof, such as lithium, cesium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. A rare earth metal or a rare earth metal compound such as erbium fluoride (ErF₃) or ytterbium (Yb) can also be used. Note that to form the electron-injection layers (115, 115a, and 115b), a plurality of kinds of the above-described materials may be mixed or a plurality of kinds of the above-described materials may be stacked. Electride may also be used for the electron-injection layers (115, 115a, and 115b). Examples of the electride include a substance in which electrons are added at high concentration to a mixed oxide of calcium and aluminum. Note that any of the substances used in the electron-transport layers (114, 114a, and 114b), which are given above, can also be used.

A mixed material in which an organic compound and an electron donor (donor) are mixed may also be used in the electron-injection layers (115, 115a, and 115b). Such a mixed material is excellent in an electron-injection property and an electron-transport property because electrons are generated in the organic compound by the electron donor. In this case, the organic compound is preferably a material excellent in transporting the generated electrons; specifically, the above-mentioned electron-transport materials (metal complexes, heteroaromatic compounds, and the like) used in the electron-transport layers (114, 114a, and 114b) can be used, for example. Any substance showing an electron-donating property with respect to the organic compound can serve as an electron donor. Specifically, an alkali metal, an alkaline earth metal, and a rare earth metal are preferable, and lithium, cesium, magnesium, calcium, erbium, ytterbium, and the like are given. In addition, an alkali metal oxide and an alkaline earth metal oxide are preferable, and lithium oxide, calcium oxide, barium oxide, and the like are given. A Lewis base such as magnesium oxide can also be used. An organic compound such as tetrathiafulvalene (abbreviation: TTF) can also be used. Alternatively, a stack of these materials may be used.

Moreover, a mixed material in which an organic compound and a metal are mixed may also be used in the electron-injection layers (115, 115a, and 115b). The organic compound used here preferably has a LUMO (lowest unoccupied molecular orbital) level higher than or equal to −3.6 eV and lower than or equal to −2.3 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferred examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, and the like), a triazine ring, a bipyridine ring, or a terpyridine ring), and a heteroaromatic compound having a fused ring structure including a six-membered ring structure as a part (e.g., a quinoline ring, a benzoquinoline ring, a quinoxaline ring, a dibenzoquinoxaline ring, or a phenanthroline ring). Since the materials are specifically described above, description thereof is omitted here.

As the metal used for the above mixed material, a transition metal that belongs to Group 5, Group 7, Group 9, or Group 11 in the periodic table or a material that belongs to Group 13 is preferably used, and Ag, Cu, Al, In, and the like can be given as examples. In this case, the organic compound forms a singly occupied molecular orbital (SOMO) with the transition metal.

To amplify light obtained from the light-emitting layer 113b, for example, the optical path length between the second electrode 102 and the light-emitting layer 113b is preferably less than one fourth of the wavelength λ of light emitted from the light-emitting layer 113b. In that case, the optical path length can be adjusted by changing the thickness of the electron-transport layer 114b or the electron-injection layer 115b.

When the charge-generation layer 106 is provided between the two EL layers (103a and 103b) as in the light-emitting device in FIG. 2D, a structure in which a plurality of EL layers are stacked between a pair of electrodes (the structure is also referred to as a tandem structure) can be obtained.

### <Charge-Generation Layer>

The charge-generation layer 106 has a function of injecting electrons into the EL layer 103a and injecting holes into the EL layer 103b when a voltage is applied between the first electrode (anode) 101 and the second electrode (cathode) 102. The charge-generation layer 106 may have a structure in which an electron acceptor (acceptor) is added to a hole-transport material) or a structure in which an electron donor (donor) is added to an electron-transport material. Alternatively, both of these structures may be stacked. Note that forming the charge-generation layer 106 with the use of any of the above materials can inhibit an increase in driving voltage caused by the stack of the EL layers.

In the case where the charge-generation layer 106 has a structure in which an electron acceptor is added to a hole-transport material that is an organic compound, any of the materials described in this embodiment can be used as the hole-transport material. As examples of the electron acceptor, 7,7,8,8-tetracyano-2,3,5,6-tetrafluoroquinodimethane (abbreviation: F₄-TCNQ), chloranil, and the like can be given. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide.

In the case where the charge-generation layer 106 has a structure in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide, cesium carbonate, or the like is preferably used. An organic compound such as tetrathianaphthacene may be used as the electron donor.

Although FIG. 2D illustrates the structure in which two EL layers 103 are stacked, three or more EL layers may be stacked with charge-generation layers each provided between different EL layers.

### <Substrate>

The light-emitting device described in this embodiment can be formed over a variety of substrates. Note that the type of substrate is not limited to a particular type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, and paper or a base material film including a fibrous material.

Examples of the glass substrate include barium borosilicate glass, aluminoborosilicate glass, and soda lime glass. Examples of the flexible substrate, the attachment film, and the base material film include plastics typified by polyethylene terephthalate (PET), polyethylene naphthalate (PEN), and polyether sulfone (PES), a synthetic resin such as acrylic resin, polypropylene, polyester, polyvinyl fluoride, polyvinyl chloride, polyamide, polyimide, aramid, epoxy resin, an inorganic vapor deposition film, and paper.

For fabrication of the light-emitting device described in this embodiment, a vapor phase method such as an evaporation method or a liquid phase method such as a spin coating method and an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, layers having a variety of functions (the hole-injection layer 111, the hole-transport layer 112, the light-emitting layer 113, the electron-transport layer 114, and the electron-injection layer 115) included in the EL layer of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

In the case where a film formation method such as the coating method or the printing method is employed, a high molecular compound (e.g., an oligomer, a dendrimer, or a polymer), a middle molecular compound (a compound between a low molecular compound and a high molecular compound with a molecular weight of greater than or equal to 400 and less than or equal to 4,000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the EL layer 103 of the light-emitting device described in this embodiment are not limited to the materials described in this embodiment, and other materials can be used in combination as long as the functions of the layers are fulfilled.

Note that in this specification and the like, the term “layer” and the term “film” can be interchanged with each other as appropriate.

The structures described in this embodiment can be used in an appropriate combination with any of the structures described in the other embodiments.

### Embodiment 3

In this embodiment, specific structure examples and an example of a manufacturing method of a light-emitting and light-receiving apparatus of one embodiment of the present invention are described.

### <Structure Example of Light-Emitting and Light-Receiving Apparatus 700>

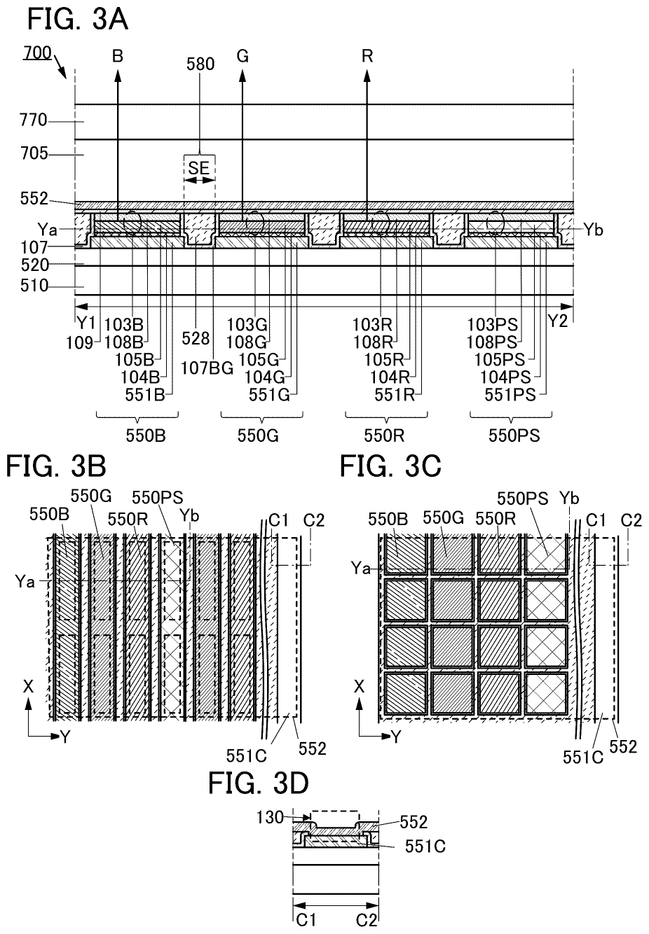

A light-emitting and light-receiving apparatus 700 illustrated in FIG. 3A includes a light-emitting device 550B, a light-emitting device 550G, a light-emitting device 550R, and a light-receiving device 550PS. The light-emitting device 550B, the light-emitting device 550G, the light-emitting device 550R, and the light-receiving device 550PS are formed over a functional layer 520 provided over a first substrate 510. The functional layer 520 includes circuits such as driver circuit that are composed of a plurality of transistors and wirings that electrically connect the driver circuits. Note that the driver circuits are electrically connected to the light-emitting device 550B, the light-emitting device 550G, the light-emitting device 550R, and the light-receiving device 550PS, for example, and can drive them. The light-emitting and light-receiving apparatus 700 includes an insulating layer 705 over the functional layer 520 and the devices (the light-emitting devices and the light-receiving device), and the insulating layer 705 has a function of bonding a second substrate 770 and the functional layer 520.

Note that the light-emitting device 550B, the light-emitting device 550G, the light-emitting device 550R, and the light-receiving device 550PS each have the device structure described in FIG. 1 or FIG. 2. Note that this embodiment describes a case where separation formation can be performed not only between a light-emitting device and a light-receiving device, but also between the devices (a plurality of light-emitting devices and a light-receiving device).

In this specification and the like, a structure in which light-emitting layers in light-emitting devices of different colors (e.g., blue (B), green (G), and red (R)) and light-receiving layers in light-receiving devices are separately formed or separately patterned may be referred to as an SBS (Side By Side) structure. Note that in the light-emitting and light-receiving apparatus 700 illustrated in FIG. 3A, the light-emitting device 550B, the light-emitting device 550G, the light-emitting device 550R, and the light-receiving device 550PS are arranged in this order; however, one embodiment of the present invention is not limited to the structure. For example, in the light-emitting and light-receiving apparatus 700, the light-emitting device 550R, the light-emitting device 550G, the light-emitting device 550B, and the light-receiving device 550PS may be arranged in this order.

As illustrated in FIG. 3A, the light-emitting device 550B includes an electrode 551B, an electrode 552, and the EL layer 103B. The light-emitting device 550G includes an electrode 551G, the electrode 552, and an EL layer 103G. The light-emitting device 550R includes an electrode 551R, the electrode 552, and an EL layer 103R. The light-receiving device 550PS includes an electrode 551PS, the electrode 552, and a light-receiving layer 103PS. Note that a specific structure of each layer of the devices is as described in Embodiment 1. A specific structure of each layer of the devices is as described in Embodiment 2. The EL layer 103B, the EL layer 103G, and the EL layer 103R each have a stacked-layer structure of layers having different functions including light-emitting layers (105B, 105G, and 105R). The light-receiving layer 103PS has a stacked-layer structure of layers having different functions including an active layer 105PS. FIG. 3A illustrates a case where the EL layer 103B includes a hole-injection/transport layer 104B, the light-emitting layer 105B, an electron-transport layer 108B, and an electron-injection layer 109; the EL layer 103G includes a hole-injection/transport layer 104G, the light-emitting layer 105G, an electron-transport layer 108G, and the electron-injection layer 109; the EL layer 103R includes a hole-injection/transport layer 104R, the light-emitting layer 105R, an electron-transport layer 108R, and the electron-injection layer 109; and the light-receiving layer 103PS includes a first transport layer 104PS, the active layer 105PS, a second transport layer 108PS, and the electron-injection layer 109. However, the present invention is not limited to the case. Note that the hole-injection/transport layers (104B, 104G, and 104R) represent the layer having the functions of the hole-injection layer and the hole-transport layer described in Embodiment 2 and may have a stacked-layer structure.

Note that the electron-transport layers (108B, 108G, and 108R) and the second transport layer 108PS may have a function of blocking holes moving from the anode side to the cathode side through the light-emitting layers (103B, 103G, and 103R). The electron-injection layer 109 may have a stacked-layer structure in which some or all of layers are formed using different materials.

As illustrated in FIG. 3A, an insulating layer 107 may be formed on side surfaces (or end portions) of the hole-injection/transport layers (104B, 104G, and 104R), the light-emitting layers (105B, 105G, and 105R), and the electron-transport layers (108B, 108G, and 108R) included in the EL layers (103B, 103G, and 103R), and side surfaces (or end portions) of the first transport layer 104PS, the active layer 105PS, and the second transport layer 108PS included in the light-receiving layer 103PS. The insulating layer 107 is formed in contact with the side surfaces (or the end portions) of the EL layers (103B, 103G, and 103R) and the light-receiving layer 103PS. This can inhibit entry of oxygen, moisture, or constituent elements thereof into the inside through the side surfaces of the EL layers (103B, 103G, and 103R) and the light-receiving layer 103PS. For the insulating layer 107, aluminum oxide, magnesium oxide, hafnium oxide, gallium oxide, indium gallium zinc oxide, silicon nitride, silicon nitride oxide, or the like can be used, for example. Some of the above-described materials may be stacked to form the insulating layer 107. The insulating layer 107 can be formed by a sputtering method, a CVD method, an MBE method, a PLD method, an ALD method, or the like and is formed preferably by an ALD method, which enables favorable coverage. Note that the insulating layer 107 continuously covers the side surfaces (or the end portions) of parts of the EL layers (103B, 103G, and 103R) of adjacent light-emitting devices and part of the light-receiving layer 103PS of the light-receiving device. For example, in FIG. 3A, the side surfaces of part of the EL layer 103B of the light-emitting device 550B and part of the EL layer 103G of the light-emitting device 550G are covered with an insulating layer 107BG. In a region covered with the insulating layer 107BG, a partition wall 528 formed using an insulating material is preferably formed, as illustrated in FIG. 3A.

In addition, the electron-injection layer 109 is formed over the electron-transport layers (108B, 108G, and 108R) that are parts of the EL layers (103B, 103G, and 103R) and the insulating layers 107. Note that the electron-injection layer 109 may have a stacked-layer structure of two or more layers (for example, stacked layers having different electric resistances).

The electrode 552 is formed over the electron-injection layer 109. Note that the electrodes (551B, 551G, and 551R) and the electrode 552 have overlapping regions. The light-emitting layer 105B is provided between the electrode 551B and the electrode 552, the light-emitting layer 105G is provided between the electrode 551G and the electrode 552, the light-emitting layer 105R is provided between the electrode 551R and the electrode 552, and the light-receiving layer 103PS is provided between the electrode 551PS and the electrode 552.

The EL layers (103B, 103G, and 103R) illustrated in FIG. 3A each have a structure similar to that of the EL layer 103 described in Embodiment 2. The light-emitting layer 105B can emit blue light, the light-emitting layer 105G can emit green light, and the light-emitting layer 105R can emit red light, for example.

The partition walls 528 are provided between the electrodes (551B, 551G, 551R, and 551PS), parts of the EL layers (103B, 103G, and 103R), and part of the light-receiving layer 103PS. As illustrated in FIG. 3A, the partition walls 528 are in contact with the side surfaces (or the end portions) of the electrodes (551n, 551G, 551R, and 551PS) and parts of the EL layers (103B, 103G, and 103R) and part of the light-receiving layer 103PS of the devices through the insulating layer 107.

In each of the EL layers and the light-receiving layer, particularly the hole-injection layer, which is included in the hole-transport region between the anode and the light-emitting layer and the hole-transport region between the anode and the active layer, often has high conductivity; therefore, a hole-injection layer formed as a layer shared by adjacent devices might cause crosstalk. Thus, as described in this structure example, the partition walls 528 formed of an insulating material are provided between the EL layers and between the EL layer and the light-receiving layer, which can inhibit occurrence of crosstalk between adjacent devices (between the light-receiving device and the light-emitting device, between the light-emitting device and the light-emitting device, or between the light-receiving device and the light-receiving device).

In the manufacturing method described in this embodiment, side surfaces (or end portions) of the EL layer and the light-receiving layer are exposed in the patterning step. This may promote deterioration of the EL layer and the light-receiving layer by allowing the entry of oxygen, water, or the like through the side surfaces (or the end portions) of the EL layer and the light-receiving layer. Therefore, providing the partition wall 528 can inhibit the deterioration of the EL layer and the light-receiving layer in the manufacturing process.

Providing the partition wall 528 can flatten a depressed portion formed between adjacent devices (between the light-receiving device and the light-emitting device, between the light-emitting device and the light-emitting device, or between the light-receiving device and the light-receiving device). When the depressed portion is reduced, disconnection of the electrode 552 formed over the EL layers and the light-receiving layer can be inhibited. As an insulating material used for forming the partition wall 528, an organic material such as an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used, for example. An organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin can also be used. A photosensitive resin such as a photoresist can also be used. Note that as the photosensitive resin, a positive material or a negative material can be used.

With the photosensitive resin, the partition wall 528 can be fabricated only by light exposure and development steps. The partition wall 528 may be formed using a negative photosensitive resin (e.g., a resist material). In the case where an insulating layer containing an organic material is used as the partition wall 528, a material absorbing visible light is suitably used. When a material that absorbs visible light is used for the partition wall 528, light emitted from the EL layer can be absorbed by the partition wall 528, so that light that might leak to the adjacent EL layer and the adjacent light-receiving layer (stray light) can be inhibited. Thus, a display panel having high display quality can be provided.

For example, the difference between the top-surface level of the partition wall 528 and the top-surface level of any of the EL layer 103B, the EL layer 103G, the EL layer 103R, and the light-receiving layer 103PS is preferably 0.5 times or less, further preferably 0.3 times or less the thickness of the partition wall 528. The partition wall 528 may be provided such that the top-surface level of any of the EL layer 103B, the EL layer 103G, the EL layer 103R, and the light-receiving layer 103PS is higher than the top-surface level of the partition wall 528, for example. Alternatively, the partition wall 528 may be provided such that the top-surface level of the partition wall 528 is higher than the top-surface level of each of the EL layer 103B, the EL layer 103G, the EL layer 103R, and the light-receiving layer 103PS, for example.

When electrical continuity is established between the EL layer 103B, the EL layer 103G, the EL layer 103R, and the light-receiving layer 103PS in a light-emitting and light-receiving apparatus (display panel) with a high definition more than 1,000 ppi, a crosstalk phenomenon occurs, resulting in a narrower color gamut of the light-emitting and light-receiving apparatus. Providing the partition wall 528 in a high-definition display panel with more than 1,000 ppi, preferably more than 2,000 ppi, or further preferably in an ultrahigh-definition display panel with more than 5,000 ppi allows the display panel to express vivid colors.

FIG. 3B and FIG. 3C are each a schematic top view of the light-emitting and light-receiving apparatus 700 taken along the dashed-dotted line Ya-Yb in the cross-sectional view of FIG. 3A. The light-emitting devices 550B, the light-emitting devices 550G, and the light-emitting devices 550R are arranged in a matrix. FIG. 3B illustrates what is called stripe arrangement, in which the light-emitting devices of the same color are arranged in X-direction. FIG. 3C illustrates a structure in which the light-emitting devices of the same color are arranged in the X-direction and separated by patterning for each pixel. Note that the arrangement method of the light-emitting devices is not limited thereto; another arrangement method such as delta arrangement, zigzag arrangement, PenTile arrangement, or diamond arrangement may also be used.

Each of the EL layers (the EL layer 103B, the EL layer103G, and the EL layer 103R) and the light-receiving layer 103PS are processed to be separated by patterning using a photolithography method; hence, a high-definition light-emitting and light-receiving apparatus (display panel) can be fabricated. End portions (side surfaces) of the EL layer processed by patterning using a photolithography method have substantially the same surface (or are positioned on substantially the same plane). In this case, the width (SE) of the space 580 between the EL layers and between the EL layer and the light-receiving layer is preferably 5 μm or less, further preferably 1 μm or less.

In the EL layer, particularly the hole-injection layer, which is included in the hole-transport region between the anode and the light-emitting layer, often has high conductivity; therefore, a hole-injection layer formed as a layer shared by adjacent light-emitting devices might cause crosstalk. Therefore, processing the EL layers to be separated by patterning using a photolithography method as shown in this structure example can suppress occurrence of crosstalk between adjacent light-emitting devices.

FIG. 3D is a schematic cross-sectional view taken along the dashed-dotted line C1-C2 in FIG. 3B and FIG. 3C. FIG. 3D illustrates a connection portion 130 where the connection electrode 551C and the electrode 552 are electrically connected. In the connection portion 130, the electrode 552 is provided over and in contact with the connection electrode 551C. In addition, the partition wall 528 is provided to cover the end portion of the connection electrode 551C.

### <Manufacturing Method Example of Light-Emitting and Light-Receiving Apparatus>

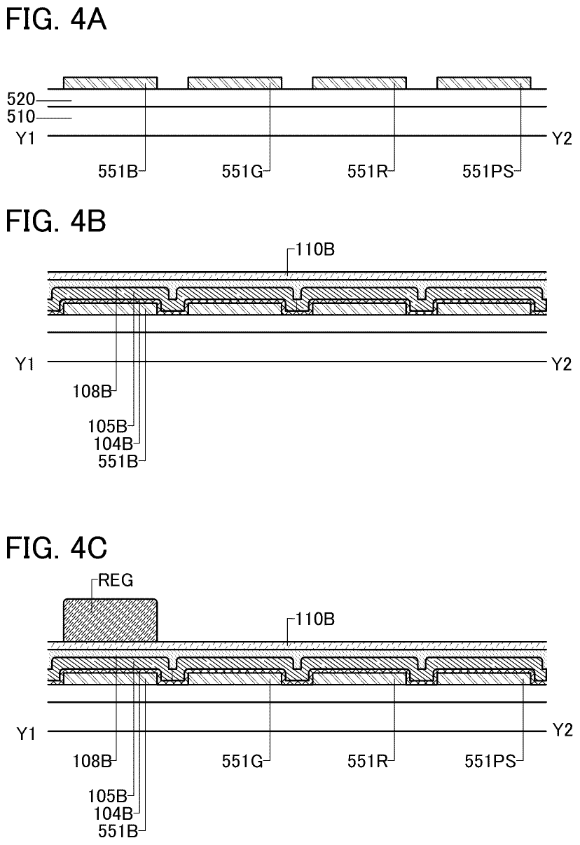

The electrode 551B, the electrode 551G, the electrode 551R, and the electrode 551PS are formed as illustrated in FIG. 4A. For example, a conductive film is formed over the functional layer 520 over the first substrate 510 and processed into predetermined shapes by a photolithography method.

The conductive film can be formed by a sputtering method, a chemical vapor deposition (CVD) method, a molecular beam epitaxy (MBE) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

The conductive film may be processed by a nanoimprinting method, a sandblasting method, a lift-off method, or the like as well as a photolithography method described above. Alternatively, island-shaped thin films may be directly formed by a film formation method using a shielding mask such as a metal mask.

There are two typical processing methods using a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development. The former method involves heat treatment steps such as heating after resist application (PAB: Pre Applied Bake) and heating after light exposure (PEB: Post Exposure Bake). In one embodiment of the present invention, a lithography method is used not only for processing of a conductive film but also for processing of a thin film used for formation of an EL layer (a film made of an organic compound or a film partly including an organic compound).

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. Light exposure may be performed by liquid immersion light exposure technique. As the light for light exposure, extreme ultraviolet (EUV) light or X-rays may also be used. Instead of the light for light exposure, an electron beam can be used. It is preferable to use extreme ultraviolet light, X-rays, or an electron beam, in which case extremely minute processing can be performed. Note that a photomask is not needed when light exposure is performed by scanning with a beam such as an electron beam.

For etching of a thin film using a resist mask, a dry etching method, a wet etching method, a sandblast method, or the like can be used.

Subsequently, as illustrated in FIG. 4B, the hole-injection/transport layer 104B, the light-emitting layer 105B, and the electron-transport layer 108B are formed over the electrode 551B, the electrode 551G, the electrode 551R, and the electrode 551PS. Note that the hole-injection/transport layer 104B, the light-emitting layer 105B, and the electron-transport layer 108B can be formed using a vacuum evaporation method, for example. Furthermore, a sacrificial layer 110B is formed over the electron-transport layer 108B. For the formation of the hole-injection/transport layer 104B, the light-emitting layer 105B, and the electron-transport layer 108B, any of the materials described in Embodiment 2 can be used.

For the sacrificial layer 110B, it is preferable to use a film highly resistant to etching treatment performed on the hole-injection/transport layer 104B, the light-emitting layer 105B, and the electron-transport layer 108B, i.e., a film having high etching selectivity. The sacrificial layer 110B preferably has a stacked-layer structure of a first sacrificial layer and a second sacrificial layer which have different etching selectivities. Moreover, for the sacrificial layer 110B, it is possible to use a film that can be removed by a wet etching method less likely to cause damage to the EL layer 103B. In wet etching, oxalic acid or the like can be used as an etchant.

The sacrificial layer 110B can be formed using an inorganic film such as a metal film, an alloy film, a metal oxide film, a semiconductor film, or an inorganic insulating film, for example. The sacrificial layer 110B can be formed by any of a variety of film formation methods such as a sputtering method, an evaporation method, a CVD method, and an ALD method.

For the sacrificial layer 110B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver.

The sacrificial layer 110B can be formed using a metal oxide such as indium gallium zinc oxide (In—Ga—Zn oxide, also referred to as IGZO). It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon can also be used, for example.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. In particular, A is preferably one or more kinds selected from gallium, aluminum, and yttrium.

For the sacrificial layer 110B, an inorganic insulating material such as aluminum oxide, hafnium oxide, or silicon oxide can be used.

The sacrificial layer 110B is preferably formed using a material that can be dissolved in a solvent chemically stable with respect to the electron-transport layer 108B, which is at least the uppermost layer. In particular, a material that will be dissolved in water or alcohol can be suitably used for the sacrificial layer 110B. In formation of the sacrificial layer 110B, it is preferable that application of such a material dissolved in a solvent such as water or alcohol be performed by a wet film formation method and followed by heat treatment for evaporating the solvent. At this time, the heat treatment is preferably performed in a reduced-pressure atmosphere, in which case the solvent can be removed at a low temperature in a short time and thermal damage to the hole-injection/transport layer 104B, the light-emitting layer 105B, and the electron-transport layer 108B can be reduced accordingly.

In the case where the sacrificial layer 110B having a stacked-layer structure is formed, the stacked-layer structure can include the first sacrificial layer formed using any of the above-described materials and the second sacrificial layer thereunder.

The second sacrificial layer in that case is a film used as a hard mask for etching of the first sacrificial layer. In processing the second sacrificial layer, the first sacrificial layer is exposed. Thus, a combination of films having high etching selectivity therebetween is selected for the first sacrificial layer and the second sacrificial layer. Thus, a film that can be used for the second sacrificial layer can be selected in accordance with the etching conditions of the first sacrificial layer and the etching conditions of the second sacrificial layer.

For example, in the case where dry etching using a gas containing fluorine (also referred to as a fluorine-based gas) is performed for the etching of the second sacrificial layer, silicon, silicon nitride, silicon oxide, tungsten, titanium, molybdenum, tantalum, tantalum nitride, an alloy containing molybdenum and niobium, an alloy containing molybdenum and tungsten, or the like can be used for the second sacrificial layer. Here, a metal oxide film of IGZO, ITO, or the like is given as an example of a film having high etching selectivity (that is, enabling low etching rate) in dry etching using the fluorine-based gas, and such a film can be used as the first sacrificial layer.

Note that the material for the second sacrificial layer is not limited to the above and can be selected from a variety of materials in accordance with the etching conditions of the first sacrificial layer and the etching conditions of the second sacrificial layer. For example, any of the films that can be used for the first sacrificial layer can be selected.

As the second sacrificial layer, a nitride film can be used, for example. Specifically, it is possible to use a nitride such as silicon nitride, aluminum nitride, hafnium nitride, titanium nitride, tantalum nitride, tungsten nitride, gallium nitride, or germanium nitride.

Alternatively, an oxide film can be used as the second sacrificial layer. Typically, a film of an oxide or an oxynitride such as silicon oxide, silicon oxynitride, aluminum oxide, aluminum oxynitride, hafnium oxide, or hafnium oxynitride can be used.

Next, as illustrated in FIG. 4C, a resist is applied onto the sacrificial layer 110B, and the resist having a desired shape (a resist mask: REG) is formed by a photolithography method. Such a method involves heat treatment steps such as heating after resist application (PAB: Pre Applied Bake) and heating after light exposure (PEB: Post Exposure Bake). The PAB temperature reaches approximately 100° C. and the PEB temperature reaches approximately 120° C., for example. Therefore, the light-emitting device needs to be resistant to such treatment temperatures.

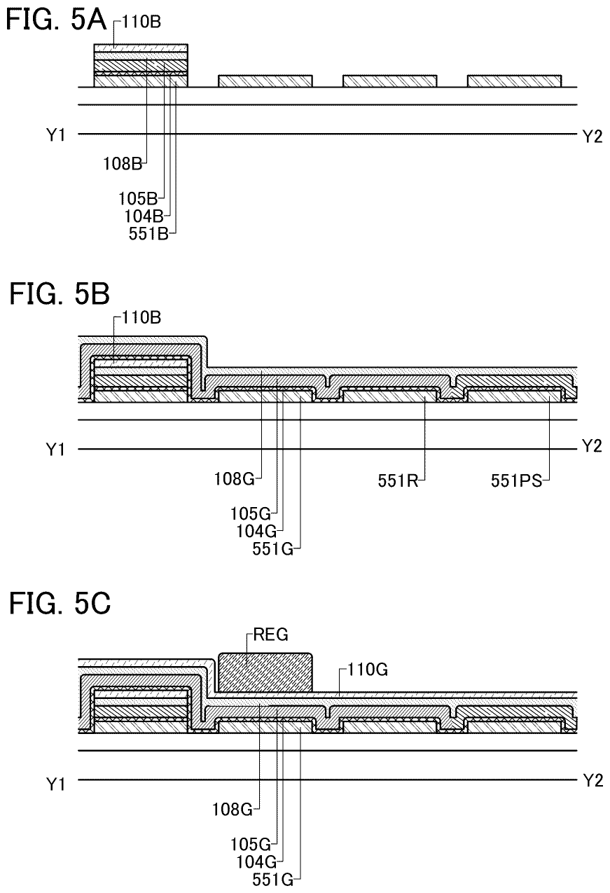

Next, part of the sacrificial layer 110B that is not covered with the resist mask REG is removed by etching using the obtained resist mask REG, the resist mask REG is removed, and then the hole-injection/transport layer 104B, the light-emitting layer 105B, and the electron-transport layer 108B that are not covered with the sacrificial layer are removed by etching, so that the hole-injection/transport layer 104B, the light-emitting layer 105B, and the electron-transport layer 108B are processed to have side surfaces (or have their side surfaces exposed) over the electrode 551B or have belt-like shapes extending in the direction intersecting with the sheet. Note that dry etching is preferably employed for the etching. In the case where the sacrificial layer 110B has the aforementioned stacked-layer structure of the first sacrificial layer and the second sacrificial layer, the hole-injection/transport layer 104B, the light-emitting layer 105B, and the electron-transport layer 108B may be processed into predetermined shapes in the following manner: part of the second sacrificial layer is etched with use of the resist mask REG, the resist mask REG is then removed, and part of the first sacrificial layer is etched with use of the second sacrificial layer as a mask. The shape illustrated in FIG. 5A is obtained through these etching treatment.

Subsequently, as illustrated in FIG. 5B, the hole-injection/transport layer 104G, the light-emitting layer 105G, and the electron-transport layer 108G are formed over the sacrificial layer 110B, the electrode 551G, the electrode 551R, and the electrode 551PS. As the materials for forming the hole-injection/transport layer 104G, the light-emitting layer 105G, and the electron-transport layer 108G, any of the materials described in Embodiment 2 can be used. Note that the hole-injection/transport layer 104G, the light-emitting layer 105G, and the electron-transport layer 108G can be formed by a vacuum evaporation method, for example.

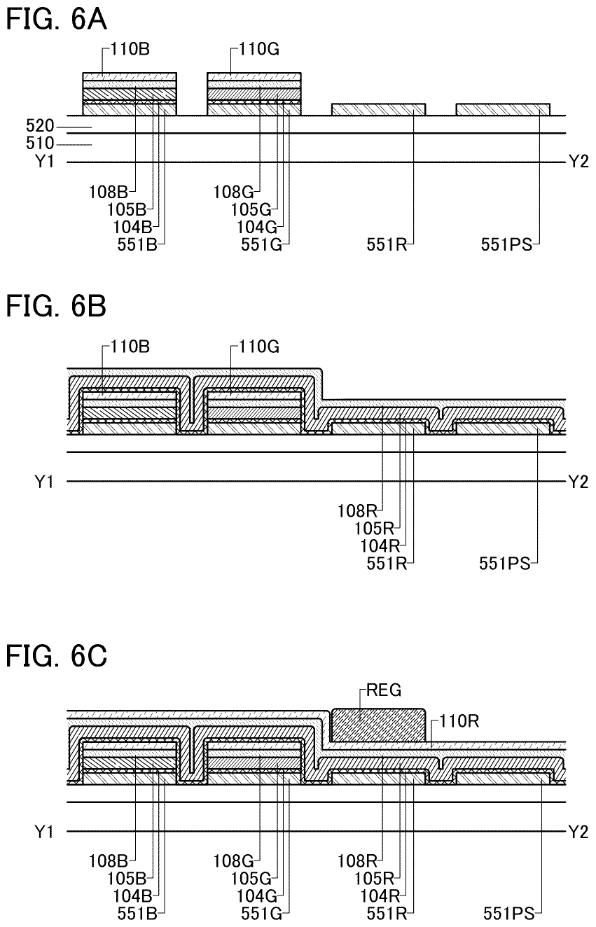

Next, as illustrated in FIG. 5C, the sacrificial layer 110G is formed over the electron-transport layer 108G, a resist is applied onto the sacrificial layer 110G, and the resist having a desired shape (the resist mask: REG) is formed by a photolithography method. The sacrificial layer 110G that is not covered with the obtained resist mask is removed by etching, the resist mask is then removed, and then the hole-injection/transport layer 104G, the light-emitting layer 105G, and the electron-transport layer 108G that are not covered with the sacrificial layer are removed by etching. Thus, the hole-injection/transport layer 104G, the light-emitting layer 105G, and the electron-transport layer 108G are processed to have side surfaces (or have their side surfaces exposed) over the electrode 551G or have belt-like shapes extending in the direction intersecting with the sheet. Note that dry etching is preferably employed for the etching. The sacrificial layer 110G can be formed using a material similar to that for the sacrificial layer 110B. In the case where the sacrificial layer 110G has the aforementioned stacked-layer structure of the first sacrificial layer and the second sacrificial layer, the hole-injection/transport layer 104G, the light-emitting layer 105G, and the electron-transport layer 108G may be processed into predetermined shapes in the following manner: part of the second sacrificial layer is etched with use of the resist mask, the resist mask is then removed, and then part of the first sacrificial layer is etched with use of the second sacrificial layer as a mask. The shape illustrated in FIG. 6A is obtained through these etching treatment.

Next, as illustrated in FIG. 6B, the hole-injection/transport layer 104R, the light-emitting layer 105R, and the electron-transport layer 108R are formed over the sacrificial layer 110B, the sacrificial layer 110G, the electrode 551R, and the electrode 551PS. For the formation of the hole-injection/transport layer 104R, the light-emitting layer 105R, and the electron-transport layer 108R, any of the materials described in Embodiment 2 can be used. Note that the hole-injection/transport layer 104R, the light-emitting layer 105R, and the electron-transport layer 108R can be formed by a vacuum evaporation method, for example.

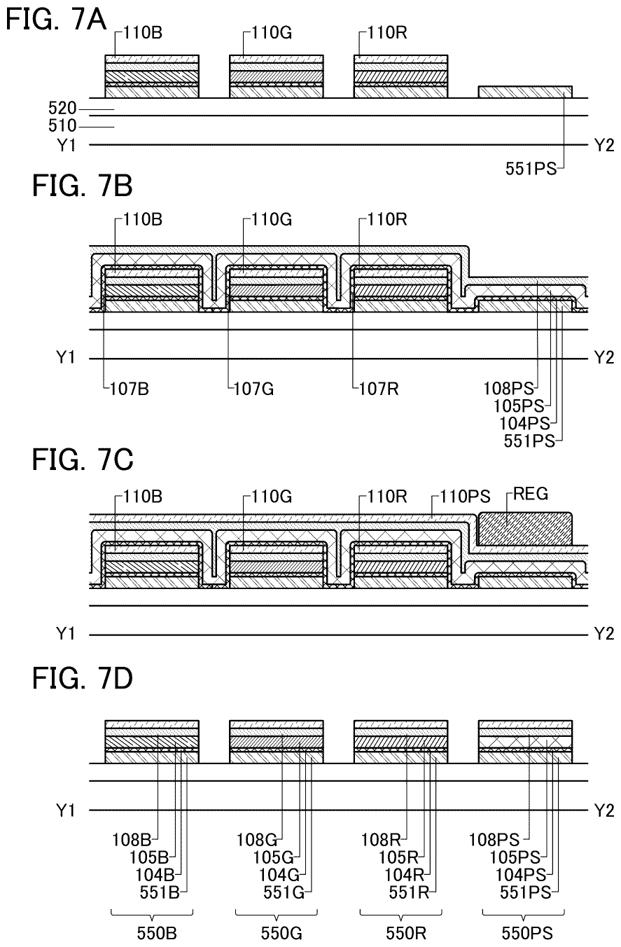

Next, as illustrated in FIG. 6C, the sacrificial layer 110R is formed over the electron-transport layer 108R, a resist is applied onto the sacrificial layer 110R, and the resist having a desired shape (the resist mask: REG) is formed by a photolithography method. Part of the sacrificial layer 110R that is not covered with the obtained resist mask is removed by etching, the resist mask is then removed, and then the hole-injection/transport layer 104R, the light-emitting layer 105R, and the electron-transport layer 108R that are not covered with the sacrificial layer 110R are partly removed by etching. Thus, the hole-injection/transport layer 104R, the light-emitting layer 105R, and the electron-transport layer 108R are processed to have side surfaces (or have their side surfaces exposed) over the electrode 551R or have belt-like shapes extending in the direction intersecting with the sheet. Note that dry etching is preferably employed for the etching. The sacrificial layer 110R can be formed using a material similar to that for the sacrificial layer 110B. In the case where the sacrificial layer 110R has the aforementioned stacked-layer structure of the first sacrificial layer and the second sacrificial layer, the hole-injection/transport layer 104R, the light-emitting layer 105R, and the electron-transport layer 108R may be processed into a predetermined shape in the following manner: part of the second sacrificial layer is etched with use of the resist mask, the resist mask is then removed, and part of the first sacrificial layer is etched with use of the second sacrificial layer as a mask. The shape illustrated in FIG. 7A is obtained through these etching treatment.

Next, as illustrated in FIG. 7B, the first transport layer 104PS, the active layer 105PS, and the second transport layer 108PS are formed over the sacrificial layer 110B, the sacrificial layer 110G, the sacrificial layer 110R, and the electrode 551PS. The first transport layer 104PS, the active layer 105PS, and the second transport layer 108PS can be formed using any of the materials described in Embodiment 1. Note that the first transport layer 104PS, the active layer 105PS, and the second transport layer 108PS can be formed by a vacuum evaporation method, for example.

Next, as illustrated in FIG. 7C, the sacrificial layer 110PS is formed over the second transport layer 108PS, a resist is applied onto the sacrificial layer 110PS, and the resist having a desired shape (the resist mask: REG) is formed by a photolithography method. Part of the sacrificial layer 110PS that is not covered with the obtained resist mask is removed by etching, the resist mask is then removed, and the first transport layer 104PS, the active layer 105PS, and the second transport layer 108PS that are not covered with the sacrificial layer 110PS are partly removed by etching. Thus, the first transport layer 104PS, the active layer 105PS, and the second transport layer 108PS are processed to have side surfaces (or have their side surfaces exposed) over the electrode 551PS or have belt-like shapes extending in the direction intersecting with the sheet. Note that dry etching is preferably employed for the etching. The sacrificial layer 110PS can be formed using a material similar to that for the sacrificial layer 110B. In the case where the sacrificial layer 110PS has the aforementioned stacked-layer structure of the first sacrificial layer and the second sacrificial layer, the first transport layer 104PS, the active layer 105PS, and the second transport layer 108PS may be processed into a predetermined shape in the following manner: part of the second sacrificial layer is etched using the resist mask, the resist mask is then removed, and part of the first sacrificial layer is etched using the second sacrificial layer as a mask. The shape illustrated in FIG. 7D is obtained through these etching treatment.

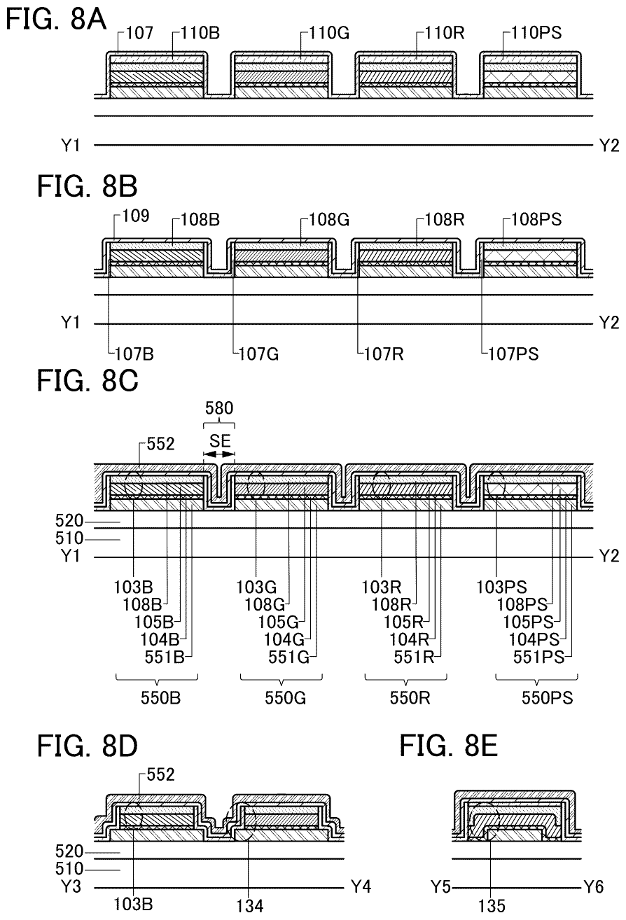

Next, as illustrated in FIG. 8A, the insulating layer 107 is formed over the sacrificial layer 110B, the sacrificial layer 110G, the sacrificial layer 110R, and the sacrificial layer 110PS.

For formation of the insulating layer 107, an ALD method can be used, for example. In this case, as illustrated in FIG. 8A, the insulating layer 107 is formed to be in contact with the side surfaces (end portions) of the hole-injection/transport layers (104B, 104G, and 104R), the light-emitting layers (105B, 105G, and 105R), and the electron-transport layers (108B, 108G, and 108R) of the light-emitting devices and the first transport layer 104PS, the active layer 105PS, and the second transport layer 108PS of the light-receiving device. This can inhibit entry of oxygen, moisture, or constituent elements thereof into the inside through the side surfaces. As a material used for the insulating layer 107, aluminum oxide, magnesium oxide, hafnium oxide, gallium oxide, indium gallium zinc oxide, silicon nitride, silicon nitride oxide, or the like can be used, for example.

Next, as illustrated in FIG. 8B, the sacrificial layers (110B, 110G, 110R, and 110PS) are removed, and then, the electron-injection layer 109 is formed over the insulating layers (107B, 107G, 107R, and 107PS), the electron-transport layers (108B, 108G, and 108R), and the second transport layer 108PS. Note that parts of the insulating layers 107 are removed at the same time when the sacrificial layers (110B, 110G, 110R, and 110PS) are removed, whereby the insulating layers (107B, 107G, 107R, and 107PS) are formed. The electron-injection layer 109 can be formed using any of the materials described in Embodiment 2. The electron-injection layer 109 is formed by a vacuum evaporation method, for example. Note that the electron-injection layer 109 is formed over the electron-transport layers (108B, 108G, and 108R) and the second transport layer 108PS. Note that the electron-injection layer 109 is in contact with the side surfaces (end portions) of the hole-injection/transport layers (104B, 104G, and 104R), the light-emitting layers (105B, 105G, and 105R), and the electron-transport layers (108B, 108G, and 108R) of the light-emitting devices and the first transport layer 104PS, the active layer 105PS, and the second transport layer 108PS of the light-receiving device through the insulating layers (107B, 107G, 107R, and 107PS).

Next, as illustrated in FIG. 8C, the electrode 552 is formed. The electrode 552 is formed by a vacuum evaporation method, for example. The electrode 552 is formed over the electron-injection layer 109. Note that the electrode 552 is in contact with the side surfaces (end portions) of the hole-injection/transport layers (104B, 104G, and 104R), the light-emitting layers (105B, 105G, and 105R), and the electron-transport layers (108B, 108G, and 108R) of the light-emitting devices and the first transport layer 104PS, the active layer 105PS, and the second transport layer 108PS of the light-receiving device through the electron-injection layer 109 and the insulating layer (107B, 107G, and 107R). This can prevent electrical short circuits between the electrode 552 and each of the following layers: the hole-injection/transport layers (104B, 104G, and 104R), the light-emitting layers (105B, 105G, and 105R), and the electron-transport layers (108B, 108G, and 108R) of the light-emitting devices and the first transport layer 104PS, the active layer 105PS, and the second transport layer 108PS of the light-receiving device.

Through the above steps, the EL layer 103B, the EL layer 103G, the EL layer 103R, and the light-receiving layer 103PS in the light-emitting device 550B, the light-emitting device 550G, the light-emitting device 550R, and the light-receiving device 550PS can be processed to be separated from each other.

The EL layers (the EL layer 103B, the EL layer 103G, and the EL layer 103R) and the light-receiving layer 103PS are processed to be separated by patterning using a photolithography method; hence, a high-definition light-emitting and light-receiving apparatus (display panel) can be fabricated. End portions (side surfaces) of layers of the EL layer processed by patterning using a photolithography method have substantially the same surface (or are positioned on substantially the same plane).

The hole-injection/transport layers (104B, 104G, and 104R) of the EL layers and the first transport layer 104PS of the light-receiving layer often have high conductivity, and thus might cause crosstalk when formed as layers shared by adjacent devices. Therefore, processing the EL layers to be separated by patterning using a photolithography method as shown in this structure example can suppress occurrence of crosstalk between adjacent light-emitting and light-receiving devices.

In this structure, the hole-injection/transport layers (104B, 104G, and 104R), the light-emitting layers (105B, 105G, and 105R), and the electron-transport layers (108B, 108G, and 108R) of the EL layers (the EL layer 103B, the EL layer 103G, and the EL layer 103R) included in the light-emitting devices and the first transport layer 104PS, the active layer 105PS, and the second transport layer 108PS of the light-receiving layer 103PS included in the light-receiving device are processed to be separated by patterning using a photolithography method; thus, the side surfaces (end portions) of the processed EL layers have substantially the same surface (or are positioned on substantially the same plane).

In addition, the hole-injection/transport layers (104B, 104G, and 104R), the light-emitting layers (105B 105G, and 105R), and the electron-transport layers (108B, 108G, and 108R) of the EL layers (the EL layer 103B, the EL layer 103G, and the EL layer 103R) included in the light-emitting devices and the first transport layer 104PS, the active layer 105PS, and the second transport layer 108PS of the light-receiving layer 103PS included in the light-receiving device are processed to be separated by patterning using a photolithography method. Thus, the space 580 is provided between the processed end portions (side surfaces) of adjacent devices. In FIG. 8C, when the space 580 is denoted by a distance SE between the EL layers of the adjacent devices, the aperture ratio can be increased and the definition can be increased as the distance SE decreases. By contrast, as the distance SE increases, the effect of the difference in the fabrication process between the adjacent devices becomes permissible, which leads to an increase in manufacturing yield. Since the light-emitting device fabricated according to this specification is suitable for a miniaturization process, the distance SE between the EL layers or between the EL layer and the light-receiving layer of the adjacent devices can be longer than or equal to 0.5 μm and shorter than or equal to 5 μm, preferably longer than or equal to 1 μm and shorter than or equal to 3 μm, further preferably longer than or equal to 1 μm and shorter than or equal to 2.5 μm, and still further preferably longer than or equal to 1 μm and shorter than or equal to 2 μm. Typically, the distance SE is preferably longer than or equal to 1 μm and shorter than or equal to 2 μm (e.g., 1.5 μm or a neighborhood thereof).

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure. Since a light-emitting and light-receiving apparatus having the MML structure is manufactured without using a metal mask, the pixel arrangement, the pixel shape, and the like can be designed more flexibly in the light-emitting and light-receiving apparatus having the MML structure than in a light-emitting and light-receiving apparatus having the FMM structure or the MM structure.

Note that an island-shaped EL layer of a light-emitting and light-receiving apparatus having an MML structure is formed not by patterning with use of a metal mask but by processing after formation of an EL layer. Accordingly, a light-emitting and light-receiving apparatus with a higher definition or a higher aperture ratio than a conventional one can be achieved. Moreover, EL layers can be formed separately for the respective colors, enabling the light-emitting and light-receiving apparatus to perform extremely clear display with high contrast and high display quality. Moreover, providing the sacrificial layer over the EL layer can reduce damage to the EL layer in the manufacturing process, resulting in an increase in the reliability of the light-emitting device.

In FIG. 8(C), the widths of the EL layers (103B, 103G, and 103R) are substantially equal to the widths of the electrodes (551B, 551G, and 551R) in the light-emitting device 550B, the light-emitting device 550G, and the light-emitting device 550R, and the width of the light-receiving layer 103PS is substantially equal to the width of the electrode 551PS in the light-receiving device 550PS; however, one embodiment of the present invention is not limited thereto.

In the light-emitting device 550B, the light-emitting device 550G, and the light-emitting device 550R, the widths of the EL layers (103B, 103G, and 103R) may be smaller than the widths of the electrodes (551B, 551G, and 551R). In the light-receiving device 550PS, the width of the light-receiving layer 103PS may be smaller than the width of the electrode 551PS. FIG. 8D illustrates an example in which the widths of the EL layers (103B and 103G) are smaller than the widths of the electrodes (551B and 551G) in the light-emitting device 550B and the light-emitting device 550G (see the region 134).

In the light-emitting device 550B, the light-emitting device 550G, and the light-emitting device 550R, the widths of the EL layers (103B, 103G, and 103R) may be larger than the widths of the electrodes (551B, 551G, and 551R). In the light-receiving device 550PS, the width of the light-receiving layer 103PS may be larger than the width of the electrode 551PS. FIG. 8E illustrates an example in which the width of the EL layer 103R is smaller than the width of the electrode 551R in the light-emitting device 550R (see the region 135).

The structures described in this embodiment can be used in an appropriate combination with any of the structures described in the other embodiments.

### Embodiment 4

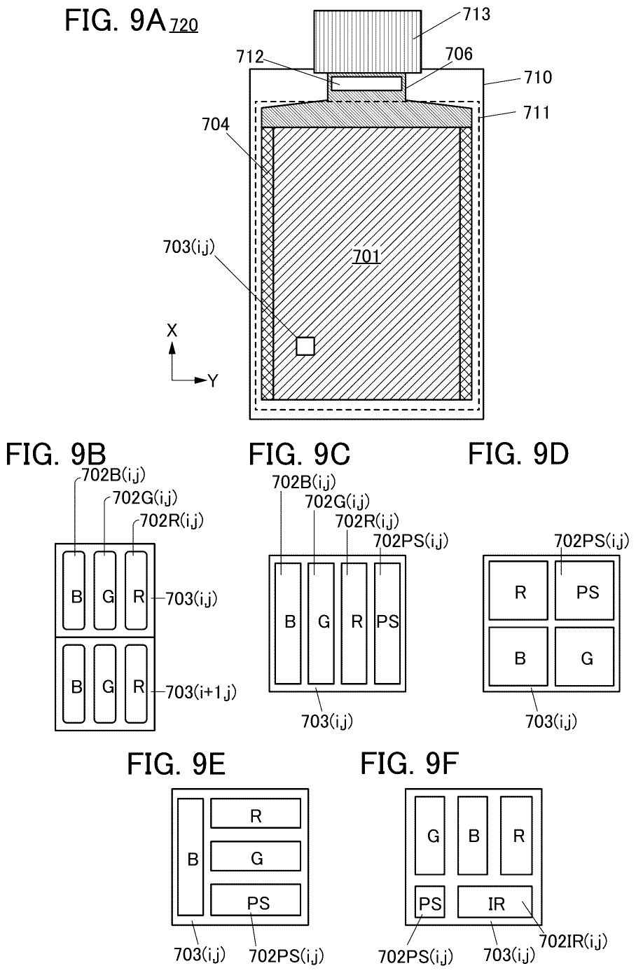

In this embodiment, an apparatus 720 will be described with reference to FIG. 9 to FIG. 11. The apparatus 720 illustrated in FIG. 9 to FIG. 11 includes any of the light-emitting devices described in Embodiment 1 and Embodiment 2, and thus is a light-emitting apparatus. Furthermore, the apparatus 720 described in this embodiment can be used in a display portion of an electronic apparatus or the like and thus can also be referred to as a display panel or a display apparatus. Moreover, when the apparatus includes the light-emitting device as a light source and a light-receiving device that can receive light from the light-emitting device, the apparatus can also be referred to as a light-emitting and light-receiving apparatus. Note that the light-emitting apparatus, the display panel, the display apparatus, and the light-emitting and light-receiving apparatus each include at least a light-emitting device.

Furthermore, the light-emitting apparatus, the display panel, the display apparatus, and the light-emitting and light-receiving apparatus of this embodiment can each have a high resolution or a large size. Accordingly, the light-emitting apparatus, the display panel, the display apparatus, and the light-emitting and light-receiving apparatus in this embodiment can be used for display portions of electronic apparatuses such as a digital camera, a digital video camera, a digital photo frame, a mobile phone, a portable game console, a smartphone, a wristwatch terminal, a tablet terminal, a portable information terminal, and an audio reproducing device, in addition to display portions of electronic apparatuses with a relatively large screen, such as a television device, a desktop or notebook personal computer, a monitor of a computer or the like, digital signage, and a large game machine such as a pachinko machine.

FIG. 9A is a top view of the apparatus 720 (including the light-emitting apparatus, the display panel, the display apparatus, and the light-emitting and light-receiving apparatus).

In FIG. 9A, the apparatus 720 has a structure in which a substrate 710 and a substrate 711 are bonded to each other. In addition, the apparatus 720 includes a display region 701, a circuit 704, a wiring 706, and the like. Note that the display region 701 includes a plurality of pixels. As illustrated in FIG. 9B, a pixel 703(i, j) illustrated in FIG. 9A has a pixel 703(i+1, j) adjacent to the pixel 703(i,j).

Furthermore, as illustrated in the example of FIG. 9A, the substrate 710 is provided with an IC (integrated circuit) 712 by a COG (Chip On Glass) method, a COF (Chip On Film) method, or the like in the apparatus 720. As the IC 712, an IC including a scan line driver circuit, a signal line driver circuit, or the like can be used, for example. FIG. 9A illustrates a structure where an IC including a signal line driver circuit is used as the IC 712, and a scan line driver circuit is used as the circuit 704.

The wiring 706 has a function of supplying signals and power to the display region 701 and the circuit 704. The signals and power are input to the wiring 706 from the outside through an FPC (Flexible Printed Circuit) 713 or to the wiring 706 from the IC 712. Note that the apparatus 720 is not necessarily provided with the IC. The IC may be mounted on the FPC by a COF method or the like.

FIG. 9B illustrates the pixel 703(i, j) and the pixel 703(i+1, j) of the display region 701. The pixel 703(i, j) can have a plurality of kinds of subpixels including light-emitting devices that emit light of different colors. In addition to the above, a plurality of subpixels including light-emitting devices that emit light of the same color may be included. A pixel can include three kinds of subpixels, for example. The three subpixels can be of three colors of red (R), green (G), and blue (B) or of three colors of yellow (Y), cyan (C), and magenta (M), for example. Alternatively, the pixel can include four kinds of subpixels. As the four subpixels, subpixels of four colors of R, G, B, and white (W), subpixels of four colors of R, G, B, and Y, and the like can be given. Specifically, the pixel 703(i, j) can be composed of a subpixel 702G(i, j) displaying blue, a subpixel 702B(i, j) displaying green, and a subpixel 702R(i, j) displaying red.

A subpixel including a light-receiving device may be provided in addition to a subpixel including alight-emitting device. In the case where the subpixel includes a light-receiving device, the apparatus 720 is also referred to as a light-emitting and light-receiving apparatus.

FIG. 9C to FIG. 9F illustrate various layout examples of the pixel 703(i,j) including a subpixel 702PS(i, j) including a light-receiving device. The pixel arrangement illustrated in FIG. 9C is stripe arrangement, and the pixel arrangement illustrated in FIG. 9D is matrix arrangement. In the pixel arrangement illustrated in FIG. 9E, three subpixels (the subpixel R, the subpixel G, and the subpixel PS) are vertically arranged next to one subpixel (the subpixel B). In the pixel arrangement illustrated in FIG. 9F, the three vertically long subpixel G, subpixel B, and subpixel R are arranged laterally, and the subpixel PS and the horizontally long subpixel IR are arranged laterally below the three subpixels. Note that the wavelength of light detected by the subpixel 702PS(i, j) is not particularly limited; however, the light-receiving device included in the subpixel 702PS(i, j) preferably has sensitivity to light emitted by the light-emitting device included in the subpixel 702R(i, j), the subpixel 702G(i, j), the subpixel 702B(i, j), or the subpixel 702IR(i, j). The light-receiving device preferably detects one or more of light in blue, violet, bluish violet, green, yellowish green, yellow, orange, red, and infrared wavelength ranges, for example.

Furthermore, as illustrated in FIG. 9F, a subpixel 7021R(i, j) that emits infrared rays may be added to any of the above-described sets of subpixels to form the pixel 703(i, j). Specifically, the subpixel that emits light including light with a wavelength greater than or equal to 650 nm and less than or equal to 1,000 nm may be used in the pixel 703(i, j).

Note that the arrangement of subpixels is not limited to the structures illustrated in FIG. 9B to FIG. 9F and a variety of arrangement methods can be employed. The arrangement of subpixels may be stripe arrangement, S stripe arrangement, matrix arrangement, delta arrangement, Bayer arrangement, or PenTile arrangement, for example.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to a top surface shape of a light-emitting region of the light-emitting device.

In the case where a pixel includes a light-receiving device in addition to a light-emitting device, the pixel has a light-receiving function; thus, a touch or an approach of an object can be detected while an image is being displayed. For example, all the subpixels included in the light-emitting apparatus can display an image; alternatively, some of the subpixels can emit light as a light source, and the rest of the subpixels can display an image.

Note that the light-receiving area of the subpixel 702PS(i, j) is preferably smaller than the light-emitting areas of the other subpixels. A smaller light-receiving area leads to a narrower image-capturing range, inhibits a blur in a capturing result, and improves the resolution. Thus, by using the subpixel 702PS(i, j), high-definition or high-resolution image capturing is possible. For example, image capturing for personal authentication with the use of a fingerprint, a palm print, the iris, the shape of a blood vessel (including the shape of a vein and the shape of an artery), a face, or the like is possible by using the subpixel 702PS(i, j).

Moreover, the subpixel 702PS(i, j) can be used in a touch sensor (also referred to as a direct touch sensor), a near touch sensor (also referred to as a hover sensor, a hover touch sensor, a contactless sensor, or a touchless sensor), or the like. For example, the subpixel 702PS(i, j) preferably detects infrared light. Thus, a touch can be detected even in a dark place.

Here, the touch sensor or the near touch sensor can detect the approach or contact of an object (e.g., a finger, a hand, or a pen). The touch sensor can detect the object when the light-emitting and light-receiving apparatus and the object come in direct contact with each other. Furthermore, the near touch sensor can detect the object even when the object is not in contact with the light-emitting and light-receiving apparatus. For example, the display apparatus is preferably capable of detecting an object positioned in the range of 0.1 mm to 300 mm inclusive, further preferably 3 mm to 50 mm inclusive from the light-emitting and light-receiving apparatus. This structure enables the light-emitting and light-receiving apparatus to be operated without direct contact of an object, that is, enables the light-emitting and light-receiving apparatus to be operated in a contactless (touchless) manner. With the above-described structure, the light-emitting and light-receiving apparatus can be operated with a reduced risk of being dirty or damaged or without direct contact between an object and a dirt (e.g., dust, bacteria, or a virus) attached to the light-emitting and light-receiving apparatus.

For high-definition image capturing, the subpixels 702PS(i, j) are preferably provided in all pixels included in the light-emitting and light-receiving apparatus. Meanwhile, in the case where the subpixel 702PS(i, j) is used in a touch sensor, a near touch sensor, or the like, high accuracy is not required as compared to the case of capturing an image of a fingerprint or the like; accordingly, the subpixel 702PS(i, j) may be provided in some pixels in the light-emitting and light-receiving apparatus. When the number of the subpixels 702PS(i, j) included in the light-emitting and light-receiving apparatus is smaller than the number of the subpixels 702R(i, j) or the like, higher detection speed can be achieved.

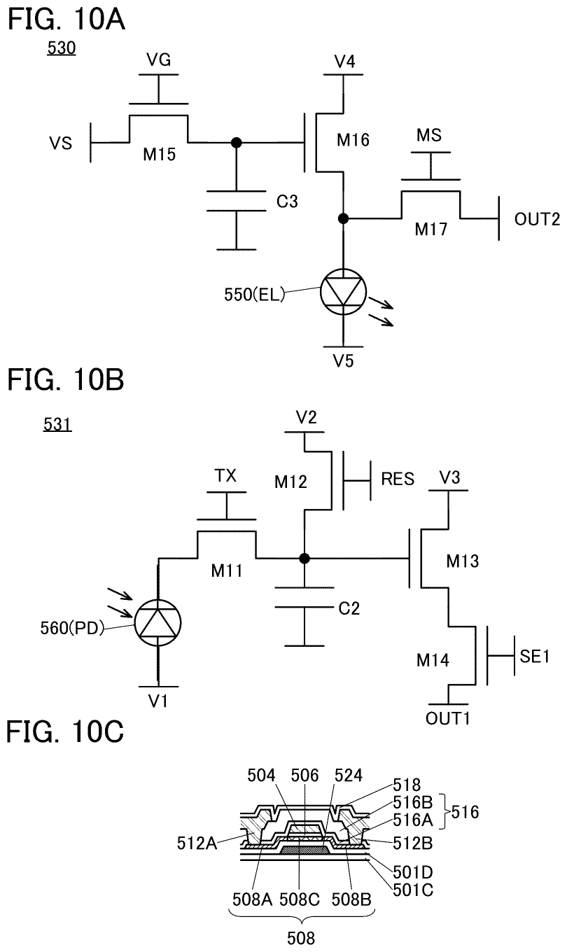

Next, an example of a pixel circuit of a subpixel including the light-emitting device is described with reference to FIG. 10A. A pixel circuit 530 illustrated in FIG. 10A includes a light-emitting device (EL) 550, a transistor M15, a transistor M16, a transistor M7, and a capacitor C3. Note that a light-emitting diode can be used as the light-emitting device 550. In particular, any of the light-emitting devices described in Embodiment 1 and Embodiment 2 is preferably used as the light-emitting device 550.

In the transistor M15 illustrated in FIG. 10A, a gate is electrically connected to a wiring VG, one of a source and a drain is electrically connected to a wiring VS, and the other of the source and the drain is electrically connected to one electrode of the capacitor C3 and a gate of the transistor M16. One of a source and a drain of the transistor M16 is electrically connected to a wiring V4, and the other of the source and the drain of the transistor M16 is electrically connected to an anode of the light-emitting device 550 and one of a source and a drain of the transistor M17. A gate of the transistor M17 is electrically connected to a wiring MS, and the other of the source and the drain of the transistor M17 is electrically connected to a wiring OUT2. A cathode of the light-emitting device 550 is electrically connected to a wiring V5.

A constant potential is supplied to the wiring V4 and the wiring V5. In the light-emitting device 550, the anode side can have a high potential and the cathode side can have a lower potential than the anode side. The transistor M15 is controlled by a signal supplied to the wiring VG and functions as a selection transistor for controlling a selection state of the pixel circuit 530. The transistor M16 functions as a driving transistor that controls a current flowing through the light-emitting device 550 in accordance with a potential supplied to the gate of the transistor M16. When the transistor M15 is in a conduction state, a potential supplied to the wiring VS is supplied to the gate of the transistor M16, and the luminance of the light-emitting device 550 can be controlled in accordance with the potential. The transistor M17 is controlled by a signal supplied to the wiring MS and has a function of outputting a potential between the transistor M16 and the light-emitting device 550 to the outside through the wiring OUT2.

Here, transistors in which a metal oxide (an oxide semiconductor) is used in a semiconductor layer where a channel is formed are preferably used as the transistor M15, the transistor M16, the transistor M17 included in the pixel circuit 530 illustrated in FIG. 10A, and a transistor M11, a transistor M12, a transistor M13, and a transistor M14 included in the pixel circuit 531 illustrated in FIG. 10B.

A transistor using a metal oxide having a wider band gap and a lower carrier density than silicon achieves an extremely low off-state current. Therefore, owing to the low off-state current, charge accumulated in a capacitor that is connected in series with the transistor can be retained for a long time. Accordingly, it is particularly preferable to use transistors containing an oxide semiconductor as the transistor M1I, the transistor M12, and the transistor M15 each of which is connected in series with a capacitor C2 or the capacitor C3. When the other transistors also include an oxide semiconductor, the manufacturing cost can be reduced.

Alternatively, transistors using silicon for a semiconductor in which a channel is formed can be used as the transistor M11 to the transistor M17. It is particularly preferable to use silicon with high crystallinity, such as single crystal silicon or polycrystalline silicon, because high field-effect mobility can be achieved and higher-speed operation can be performed.

Alternatively, transistors using an oxide semiconductor may be used as one or more of the transistor M11 to the transistor M17, and transistors using silicon may be used as the other transistors.

Next, an example of a pixel circuit of a subpixel including a light-receiving device is described with reference to FIG. 10B. A pixel circuit 531 illustrated in FIG. 10B includes a light-receiving device (PD) 560, the transistor M11, the transistor M12, the transistor M13, the transistor M14, and the capacitor C2. Here, an example in which a photodiode is used as the light-receiving device (PD) 560 is illustrated.

In the light-receiving device (PD) 560 illustrated in FIG. 10B, an anode is electrically connected to a wiring V1, and a cathode is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RES, and the other of the source and the drain of the transistor M12 is electrically connected to a wiring V2. One of a source and a drain of the transistor M13 is electrically connected to a wiring V3, and the other of the source and the drain of the transistor M13 is electrically connected to one of a source and a drain of the transistor M14. A gate of the transistor M14 is electrically connected to a wiring SE1, and the other of the source and the drain of the transistor M14 is electrically connected to a wiring OUT1.

A constant potential is supplied to each of the wiring V1, the wiring V2, and the wiring V3. When the light-receiving device (PD) 560 is driven with a reverse bias, the wiring V2 is supplied with a potential higher than the potential of the wiring V1. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with a current flowing through the light-receiving device (PD) 560. The transistor M13 functions as an amplifier transistor for performing output corresponding to the potential of the node. The transistor M14 is controlled by a signal supplied to the wiring SE and functions as a selection transistor for making an external circuit connected to the wiring OUT1 read the output corresponding to the potential of the node.

Although n-channel transistors are shown as the transistors in FIG. 10A and FIG. 10B, p-channel transistors can alternatively be used.

The transistors included in the pixel circuit 530 and the transistors included in the pixel circuit 531 are preferably formed to be arranged over the same substrate. It is particularly preferable that the transistors included in the pixel circuit 530 and the transistors included in the pixel circuit 531 be periodically arranged in one region.

One or more layers including the transistor and/or the capacitor are preferably provided to overlap with the light-receiving device (PD) 560 or the light-emitting device (EL) 550. Thus, the effective area occupied by each pixel circuit can be reduced, and a high-definition light-receiving portion or display portion can be achieved.

FIG. 10C illustrates an example of a specific structure of a transistor that can be used in the pixel circuit described with reference to FIG. 10A and FIG. 10B. As the transistor, a bottom-gate transistor, a top-gate transistor, or the like can be used as appropriate.

The transistor illustrated in FIG. 10C includes a semiconductor film 508, a conductive film 504, an insulating film 506, a conductive film 512A, and a conductive film 512B. The transistor is formed over an insulating film 501C, for example. The transistor also includes an insulating film 516 (an insulating film 516A and an insulating film 516B) and an insulating film 518.

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C and has a function of a gate electrode.

The insulating film 506 includes a region positioned between the semiconductor film 508 and the conductive film 504. The insulating film 506 has a function of a first gate insulating film.

The conductive film 512A has one of a source electrode function and a drain electrode function, and the conductive film 512B has the other of the source electrode function and the drain electrode function.

A conductive film 524 can be used in the transistor. The conductive film 524 includes a region where the semiconductor film 508 is positioned between the conductive film 504 and the conductive film 524. The conductive film 524 has a function of a second gate electrode. An insulating film 501D is positioned between the semiconductor film 508 and the conductive film 524 and has a function of a second gate insulating film.

The insulating film 516 functions as, for example, a protective film covering the semiconductor film 508. Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 516, for example.

For example, a material having a function of inhibiting diffusion of oxygen, hydrogen, water, an alkali metal, an alkaline earth metal, and the like is preferably used for the insulating film 518. Specifically, the insulating film 518 can be formed using silicon nitride, silicon oxynitride, aluminum nitride, or aluminum oxynitride, for example. In each of silicon oxynitride and aluminum oxynitride, the number of nitrogen atoms contained is preferably larger than the number of oxygen atoms contained.

Note that in a step of forming the semiconductor film used in the transistor of the pixel circuit, the semiconductor film used in the transistor of the driver circuit can be formed. A semiconductor film with the same composition as the semiconductor film used in the transistor of the pixel circuit can be used in the driver circuit, for example.

The semiconductor film 508 preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor film 508. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

In the case where the semiconductor film is an In-M-Zn oxide, the atomic proportion of In is preferably greater than or equal to the atomic proportion of M in the In—I—Zn oxide. Examples of the atomic ratio of the metal elements in such an In-A1-Zn oxide include In:M:Zn=1:1:1 or a composition in the neighborhood thereof, In:M:Zn=1:1:1.2 or a composition in the neighborhood thereof, In:A:Zn=1:3:2 or a composition in the neighborhood thereof, In:M:Zn=1:3:4 or a composition in the neighborhood thereof, In:M:Zn=2:1:3 or a composition in the neighborhood thereof, In:A:Zn=3:1:2 or a composition in the neighborhood thereof, In:M:Zn=4:2:3 or a composition in the neighborhood thereof, In:M:Zn=4:2:4.1 or a composition in the neighborhood thereof, In:A:Zn=5:1:3 or a composition in the neighborhood thereof, In:M:Zn=5:1:6 or a composition in the neighborhood thereof, In:M:Zn=5:1:7 or a composition in the neighborhood thereof, In:A:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of 30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn 1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

The semiconductor layer of the transistor preferably includes a metal oxide (also referred to as an oxide semiconductor). As the oxide semiconductor having crystallinity, a CAAC (c-axis aligned crystalline)-OS, an nc (nanocrystalline)-OS, and the like are given.

Alternatively, a transistor using silicon in a channel formation region (a Si transistor) may be used. Examples of silicon include single crystal silicon (single crystal Si), polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistor such as an LTPS transistor, a circuit required to be driven at a high frequency (e.g., a source driver circuit) can be formed on the same substrate as the display portion. This allows simplification of an external circuit mounted on the light-emitting apparatus and a reduction in component cost and mounting cost.

An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, the power consumption of the light-emitting apparatus can be reduced with the OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, with use of an OS transistor as a driving transistor, current can be made flow stably to the light-emitting device, for example, even when a variation in current-voltage characteristics of the light-emitting device occurs. In other words, when the OS transistor operates in the saturation region, the source-drain current hardly changes with an increase in the source-drain voltage; hence, the emission luminance of the light-emitting device can be stable.

As described above, with use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

The semiconductor film used in the transistor of the driver circuit can be formed in the same step as the semiconductor film used in the transistor of the pixel circuit. The driver circuit can be formed over a substrate where the pixel circuit is formed. The number of components of an electronic apparatus can be reduced.

Silicon may be used for the semiconductor film 508. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of a transistor containing silicon, such as an LTPS transistor, a circuit required to be driven at a high frequency (e.g., a source driver circuit) can be formed on the same substrate as the display portion. This allows simplification of an external circuit mounted on the light-emitting apparatus and a reduction in component cost and mounting cost.

It is preferable to use a transistor containing a metal oxide (hereinafter also referred to as an oxide semiconductor) in its semiconductor where a channel is formed (hereinafter also referred to as an OS transistor) as at least one of the transistors included in the pixel circuit. An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, the power consumption of the light-emitting apparatus can be reduced with the OS transistor.

When LTPS transistors are used as some of the transistors included in the pixel circuit and OS transistors are used as some of the others, the light-emitting apparatus can have low power consumption and high driving capability. As a favorable example, it is preferable that an OS transistor be used as a transistor functioning as a switch for controlling electrical continuity between wirings and an LTPS transistor be used as a transistor for controlling current. Note that a structure in which an LTPS transistor and an OS transistor are combined is referred to as LTPO in some cases. LTPO enables the display panel to have low power consumption and high driving capability.

For example, one transistor provided in the pixel circuit functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. Thus, current flowing through the light-emitting device in the pixel circuit can be increased.

In contrast, another transistor provided in the pixel circuit functions as a switch for controlling selection and non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

In the case of using an oxide semiconductor as a semiconductor film, the apparatus 720 includes a light-emitting device including an oxide semiconductor as its semiconductor film and having an MML (metal maskless) structure. With this structure, the leakage current that might flow through the transistor and the leakage current that might flow between adjacent light-emitting devices (also referred to as lateral leakage current, side leakage current, or the like) can be extremely reduced. With the structure, a viewer can notice any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with very little leakage of light at the time of black display (what is called black floating) (such display is also referred to as deep black display) can be achieved.

In particular, in the case where a light-emitting device having an MML structure employs the above-described SBS structure, a layer provided between light-emitting devices (for example, also referred to as an organic layer or a common layer which is shared by the light-emitting devices) is divided; accordingly, display with no or very little side leakage can be achieved.

The structure of transistors used in a display panel may be selected as appropriate depending on the screen size of the display panel. For example, single crystal Si transistors can be used in the display panel with a screen diagonal greater than or equal to 0.1 inches and less than or equal to 3 inches. In addition, LTPS transistors can be used in the display panel with a screen diagonal greater than or equal to 0.1 inches and less than or equal to 30 inches, preferably greater than or equal to 1 inch and less than or equal to 30 inches. In addition, an LTPO structure (where an LTPS transistor and an OS transistor are used in combination) can be used in the display panel with a screen diagonal greater than or equal to 0.1 inches and less than or equal to 50 inches, preferably greater than or equal to 1 inch and less than or equal to 50 inches. In addition, OS transistors can be used in the display panel with a screen diagonal greater than or equal to 0.1 inches and less than or equal to 200 inches, preferably greater than or equal to 50 inches and less than or equal to 100 inches.

Note that with use of single crystal Si transistors, an increase in screen size is extremely difficult because of the size of a single crystal Si substrate. Furthermore, since a laser crystallization apparatus is used in the manufacturing process, LTPS transistors are unlikely to respond to an increase in screen size (typically to a screen diagonal greater than 30 inches). By contrast, since the manufacturing process of OS transistors does not necessarily require a laser crystallization apparatus or the like or can be performed at a relatively low process temperature (typically, lower than or equal to 450° C.), OS transistors can be used for a display panel with a relatively large area (typically, a screen diagonal greater than or equal to 50 inches and less than or equal to 100 inches). In addition, LTPO can be used for a display panel with a size midway between the case of using LTPS transistors and the case of using OS transistors (typically, a diagonal size greater than or equal to 1 inch and less than or equal to 50 inches).

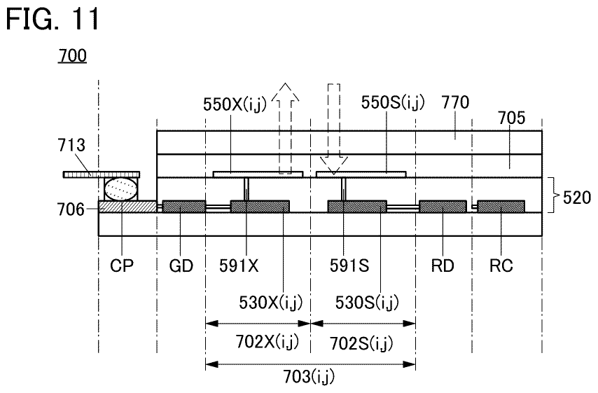

Next, FIG. 11 is a cross-sectional view of a light-emitting and light-receiving apparatus that can be used in FIG. 9A.

The cross-sectional view of FIG. 11 is a cross-sectional view of a part of a region including the FPC 713 and the wiring 706, parts of a driver circuit GD, a driver circuit SD (not illustrated), a driver circuit RD, and a driver circuit RC, a part of the display region 701 including a pixel 703(i, j) that includes a subpixel 702S(i, j) and a subpixel 702X(i, j).

In FIG. 11, the light-emitting and light-receiving apparatus 700 includes the functional layer 520 between the first substrate 510 and the second substrate 770. The functional layer 520 includes, as well as the transistors (M11, M12, M13, M14, M15, M16, and M17), the capacitor (C2 and C3), and the like described with reference to FIG. 10, wirings (VS, VG, V1, V2, V3, V4, and V5) electrically connecting these components, for example. FIG. 11 illustrates the structure of the functional layer 520 including a pixel circuit 530X(i, j), a pixel circuit 530S(i, j), and the driver circuit GD, which is a non-limiting example.

Each pixel circuit (e.g., the pixel circuit 530X(i, j) and the pixel circuit 530S(i, j) in FIG. 11) included in the functional layer 520 is electrically connected to light-emitting devices and light receiving devices (e.g., a light-emitting device 550X(i, j) and a light-receiving device 550S(i, j) in FIG. 11) formed over the functional layer 520. Specifically, the light-emitting device 550X(i, j) is electrically connected to the pixel circuit 530X(i, j) through a wiring 591X, and the light-receiving device 550S(i, j) is electrically connected to the pixel circuit 530S(i, j) through a wiring 591S. The insulating layer 705 is provided over the functional layer 520, the light-emitting devices, and the light-receiving devices and the insulating layer 705 has a function of bonding the second substrate 770 and the functional layer 520.

As the second substrate 770, a substrate where touch sensors are arranged in a matrix can be used. For example, a substrate provided with capacitive touch sensors or optical touch sensors can be used as the second substrate 770. Thus, the light-emitting and light receiving apparatus of one embodiment of the present invention can be used as a touch panel.

Note that the structure described in this embodiment can be used in an appropriate combination with any of the structures described in the other embodiments.

### Embodiment 5

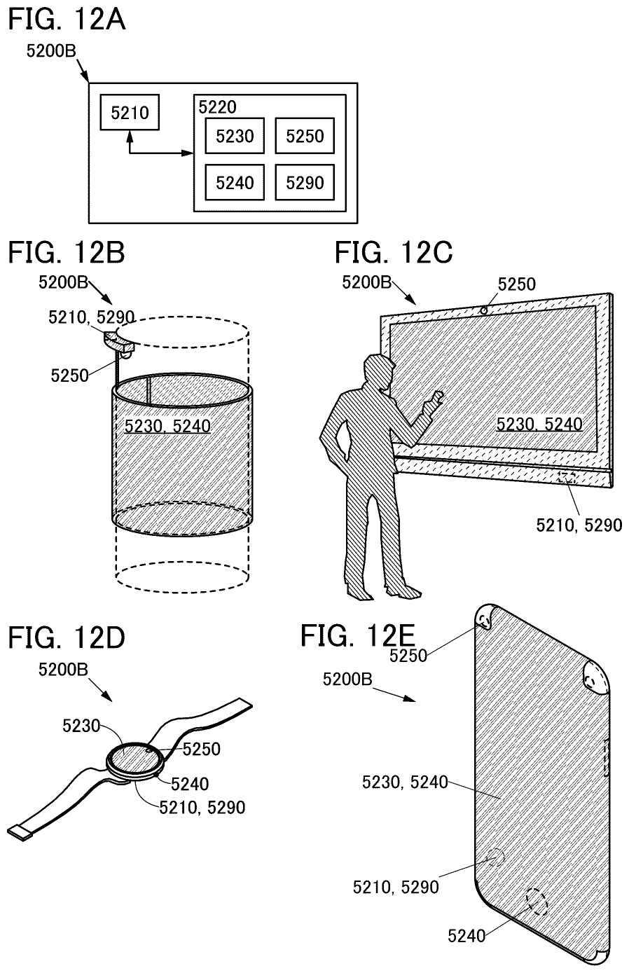

In this embodiment, electronic apparatuses of one embodiment of the present invention will be described with reference to FIG. 12A to FIG. 14B.

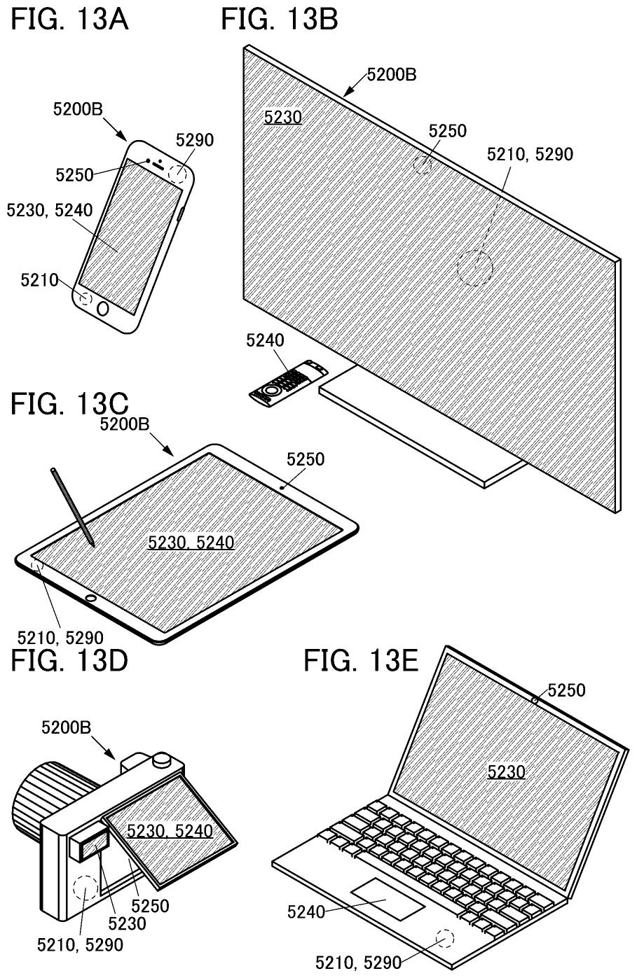

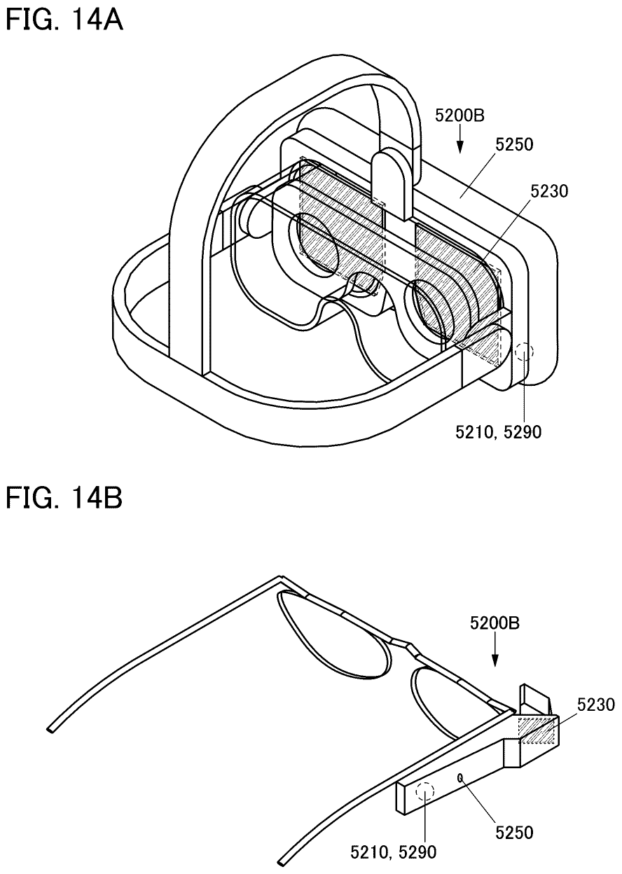

FIG. 12A to FIG. 14B are diagrams illustrating structures of electronic apparatuses of one embodiment of the present invention. FIG. 12A is a block diagram of the electronic apparatus and FIG. 12B to FIG. 12E are perspective views illustrating structures of the electronic apparatuses. FIG. 13A to FIG. 13E are perspective views illustrating structures of electronic apparatuses. FIG. 14A and FIG. 14B are perspective views illustrating structures of electronic apparatuses.

An electronic apparatus 5200B described in this embodiment includes an arithmetic device 5210 and an input/output device 5220 (see FIG. 12A).

The arithmetic device 5210 has a function of being supplied with operation data and has a function of supplying image data on the basis of the operation data.

The input/output device 5220 includes a display portion 5230, an input portion 5240, a detecting portion 5250, and a communication portion 5290 and has a function of supplying operation data and a function of being supplied with image data. The input/output device 5220 also has a function of supplying detection data, a function of supplying communication data, and a function of being supplied with communication data.

The input portion 5240 has a function of supplying operation data. For example, the input portion 5240 supplies operation data on the basis of operation by a user of the electronic apparatus 5200B.

Specifically, a keyboard, a hardware button, a pointing device, a touch sensor, an illuminance sensor, an imaging apparatus, an audio input device, an eye-gaze input device, an attitude detection device, or the like can be used as the input portion 5240.

The display portion 5230 includes a display panel and has a function of displaying image data. For example, the display panel described in Embodiment 3 can be used for the display portion 5230.

The detecting portion 5250 has a function of supplying detection data. For example, the detecting portion 5250 has a function of detecting a surrounding environment where the electronic apparatus is used and supplying detection data.

Specifically, an illuminance sensor, an imaging apparatus, an attitude detection device, a pressure sensor, a human motion sensor, or the like can be used as the detecting portion 5250.

The communication portion 5290 has a function of being supplied with communication data and a function of supplying communication data. For example, the communication portion 5290 has a function of being connected to another electronic apparatus or a communication network through wireless communication or wired communication. Specifically, the communication portion 5290 has a function of wireless local area network communication, telephone communication, near field communication, or the like.

FIG. 12B illustrates an electronic apparatus having an outer shape along a cylindrical column or the like. An example of such an electronic apparatus is digital signage. The display panel of one embodiment of the present invention can be used for the display portion 5230. Note that the electronic apparatus has a function of changing its display method in accordance with the illuminance of a usage environment. Furthermore, the electronic apparatus has a function of changing displayed content in response to detected existence of a person. Thus, for example, the electronic apparatus can be provided on a column of a building. The electronic apparatus can display advertising, guidance, or the like. The electronic apparatus can be used in digital signage or the like.

FIG. 12C illustrates an electronic apparatus having a function of generating image data on the basis of the path of a pointer used by the user. Examples of such an electronic apparatus include an electronic blackboard, an electronic bulletin board, and digital signage. Specifically, the display panel with a diagonal size of 20 inches or longer, preferably 40 inches or longer, and further preferably 55 inches or longer can be used. Alternatively, a plurality of display panels can be arranged and used as one display region. Alternatively, a plurality of display panels can be arranged and used as a multiscreen.

FIG. 12D illustrates an electronic apparatus that is capable of receiving data from another device and displaying the data on the display portion 5230. An example of such an electronic apparatus is a wearable electronic apparatus. Specifically, the electronic apparatus can display several options, or allow a user to choose some from the options and send a reply to the data transmitter. Alternatively, for example, the electronic apparatus has a function of changing its display method in accordance with the illuminance of a usage environment. Thus, the power consumption of the wearable electronic apparatus can be reduced, for example. Alternatively, an image can be displayed on the wearable electronic apparatus so that the wearable electronic apparatus can be suitably used also in an environment under strong external light, e.g., outdoors in fine weather, for example.

FIG. 12E illustrates an electronic apparatus including the display portion 5230 having a surface gently curved along a side surface of a housing. An example of such an electronic apparatus is a mobile phone. The display portion 5230 includes a display panel, and the display panel has a function of performing display on the front surface, the side surfaces, the top surface, and the rear surface, for example. Thus, for example, a mobile phone can display data not only on the front surface but also on the side surfaces, the top surface, and the rear surface.

FIG. 13A illustrates an electronic apparatus that is capable of receiving data via the Internet and displaying the data on the display portion 5230. An example of such an electronic apparatus is a smartphone. For example, a created message can be checked on the display portion 5230. The created message can be sent to another device. The electronic apparatus has a function of changing its display method in accordance with the illuminance of a usage environment, for example. Thus, the power consumption of a smartphone can be reduced. A smartphone can display an image so that the smartphone can be suitably used also in an environment under strong external light, e.g., outdoors in fine weather, for example.

FIG. 13B illustrates an electronic apparatus that can use a remote controller as the input portion 5240. An example of such an electronic apparatus is a television system. For example, the electronic apparatus is capable of receiving data from a broadcast station or via the Internet and performing display on the display portion 5230. An image of a user can be taken using the detecting portion 5250. The image of the user can be transmitted. The electronic apparatus can acquire a viewing history of the user and provide it to a cloud service. The electronic apparatus can acquire recommendation data from a cloud service and display the data on the display portion 5230. A program or a moving image can be displayed on the basis of the recommendation data. The electronic apparatus has a function of changing its display method in accordance with the illuminance of a usage environment, for example. Accordingly, for example, the television system can display an image so that the television system can be suitably used even when irradiated with strong external light that enters a room in fine weather.

FIG. 13C illustrates an electronic apparatus that is capable of receiving educational materials via the Internet and displaying them on the display portion 5230. An example of such an electronic apparatus is a tablet computer. An assignment can be input with the input portion 5240 and sent via the Internet. A corrected assignment or the evaluation of the assignment can be obtained from a cloud service and displayed on the display portion 5230. Suitable educational materials can be selected on the basis of the evaluation and displayed.

For example, the display can be performed on the display portion 5230 using an image signal received from another electronic apparatus. When the electronic apparatus is placed on a stand or the like, the display portion 5230 can be used as a sub-display. Thus, for example, a tablet computer can display an image so that the tablet computer can be suitably used also in an environment under strong external light, e.g., outdoors in fine weather.

FIG. 13D illustrates an electronic apparatus including a plurality of display portions 5230. An example of such an electronic apparatus is a digital camera. For example, the display portion 5230 can display an image that the detecting portion 5250 is capturing. A captured image can be displayed on the detecting portion. A captured image can be decorated using the input portion 5240. A message can be attached to a captured image. A captured image can be transmitted via the Internet. The electronic apparatus has a function of changing its shooting conditions in accordance with the illuminance of a usage environment. Accordingly, for example, the digital camera can display an object so that an image is favorably viewed also in an environment under strong external light, e.g., outdoors in fine weather.

FIG. 13E illustrates an electronic apparatus in which the electronic apparatus of this embodiment is used as a master to control another electronic apparatus used as a slave. An example of such an electronic apparatus is a portable personal computer. As an example, part of image data can be displayed on the display portion 5230 and another part of image data can be displayed on a display portion of another electronic apparatus. Image signals can be supplied to another electronic apparatus. With the communication portion 5290, data to be written can be obtained from an input portion of another electronic apparatus. Thus, a large display region can be utilized by using the portable personal computer, for example.

FIG. 14A illustrates an electronic apparatus including the detecting portion 5250 that detects an acceleration or a direction. An example of such an electronic apparatus is a goggles-type electronic apparatus. The detecting portion 5250 can supply data on the position of the user or the direction in which the user faces. The electronic apparatus can generate image data for the right eye and image data for the left eye in accordance with the position of the user or the direction in which the user faces. The display portion 5230 includes a display region for the right eye and a display region for the left eye. Thus, a virtual reality image that gives the user a sense of immersion can be displayed on the goggles-type electronic apparatus, for example.

FIG. 14B illustrates an imaging device and an electronic apparatus including the detecting portion 5250 that detects an acceleration or a direction. An example of such an electronic apparatus is a glasses-type electronic apparatus. The detecting portion 5250 can supply data on the position of the user or the direction in which the user faces. The electronic apparatus can generate image data in accordance with the position of the user or the direction in which the user faces. Accordingly, the data can be shown together with a real-world scene, for example. An augmented reality image can be displayed on the glasses-type electronic apparatus.

Note that this embodiment can be combined with any of the other embodiments described in this specification as appropriate.

### Embodiment 6

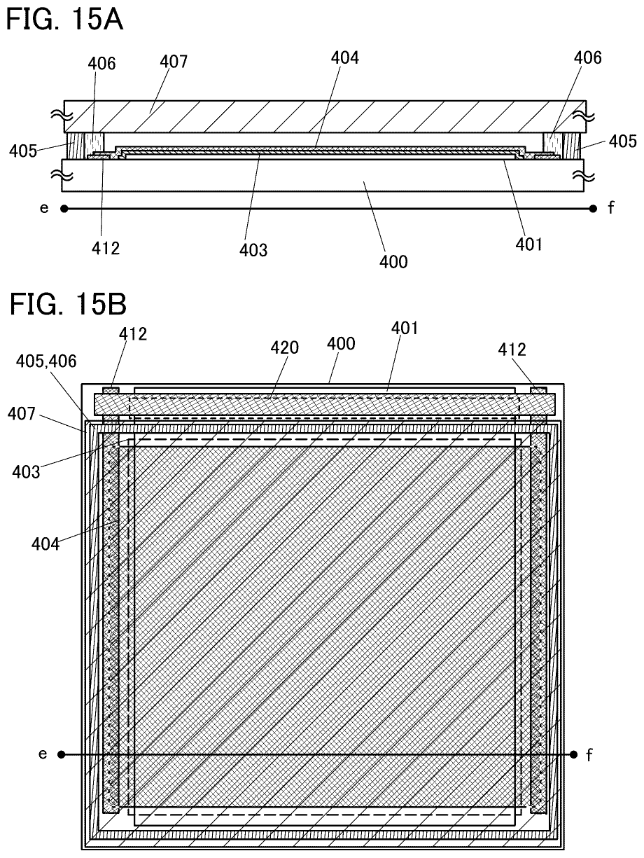

In this embodiment, a structure in which the light-emitting device described in Embodiment 1 and Embodiment 2 is used for a lighting device will be described with reference to FIG. 15. FIG. 15A is a cross-sectional view taken along the line e-f in FIG. 15B which is a top view of a lighting device.

In the lighting device in this embodiment, a first electrode 401 is formed over a substrate 400 which is a support and has a light-transmitting property. The first electrode 401 corresponds to the first electrode 101 in Embodiment 1 and Embodiment 2. In the case where light emission is extracted from the first electrode 401 side, the first electrode 401 is formed with a material having a light-transmitting property.

A pad 412 for supplying a voltage to a second electrode 404 is formed over the substrate 400.

An EL layer 403 is formed over the first electrode 401. The structure of the EL layer 403 corresponds to, for example, the structure of the EL layer 103 in Embodiment 1 and Embodiment 2. Note that for these structures, the corresponding description can be referred to.

The second electrode 404 is formed to cover the EL layer 403. The second electrode 404 corresponds to the second electrode 102 in Embodiment 1 and Embodiment 2. In the case where light-emission is extracted from the first electrode 401 side, the second electrode 404 is formed with a material having high reflectivity. The second electrode 404 is supplied with a voltage when connected to the pad 412.

As described above, the lighting device described in this embodiment includes a light-emitting device including the first electrode 401, the EL layer 403, and the second electrode 404. Since the light-emitting device is a light-emitting device with a high emission efficiency, the lighting device in this embodiment can be a lighting device with low power consumption.

The substrate 400 over which the light-emitting device having the above structure is formed is fixed to a sealing substrate 407 with sealants (405 and 406) and sealing is performed, whereby the lighting device is completed. It is possible to use either the sealant 405 or the sealant 406. In addition, the inner sealant 406 (not illustrated in FIG. 15B) can be mixed with a desiccant, which enables moisture to be adsorbed, resulting in improved reliability.

When parts of the pad 412 and the first electrode 401 are provided to extend to the outside of the sealant 405 and the sealant 406, they can serve as external input terminals. An IC chip 420 mounted with a converter or the like may be provided over the external input terminals.

### Embodiment 7

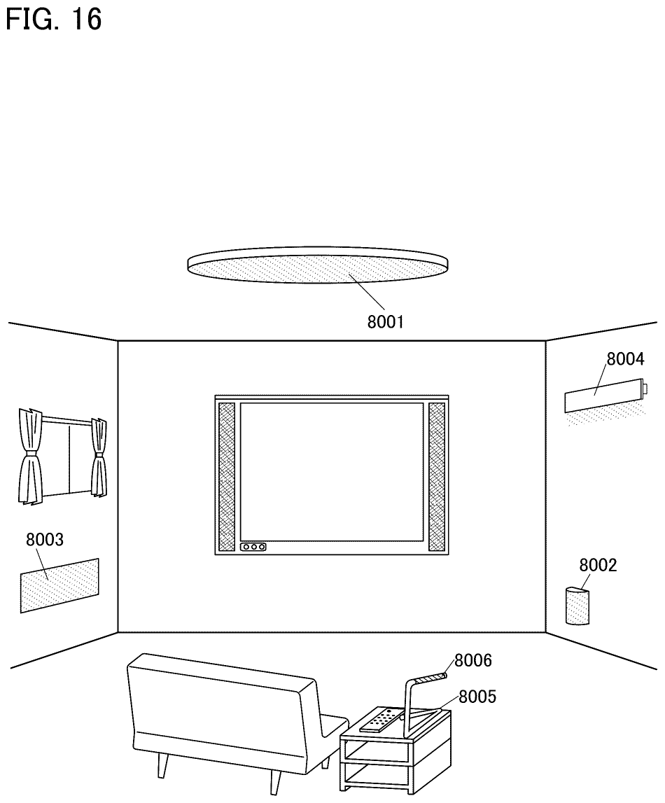

In this embodiment, application examples of lighting devices fabricated using the light-emitting apparatus of one embodiment of the present invention or the light-emitting device, which is part of the light-emitting apparatus, will be described with reference to FIG. 16.

A ceiling light 8001 can be used as an indoor lighting device. Examples of the ceiling light 8001 include a direct-mount light and an embedded light. Such lighting devices are fabricated using the light-emitting apparatus in combination with a housing and a cover. Other than that, application to a cord pendant light (light that is suspended from the ceiling by a cord) is also possible.

A foot light 8002 lights the floor so that safety on the floor can be improved. It can be effectively used in a bedroom, on a staircase, or in a passage, for example. In that case, the size or shape of the foot light can be changed in accordance with the area or structure of a room. The foot light can be a stationary lighting device made by the combination of the light-emitting apparatus and a support.

A sheet-like lighting 8003 is a thin sheet-like lighting device. The sheet-like lighting, which is attached to a wall when used, is space-saving and thus can be used for a wide variety of applications. Furthermore, the area of the sheet-like lighting can be easily increased. The sheet-like lighting can also be used on a wall or housing having a curved surface, for example.

In addition, a lighting device 8004 in which the light from a light source is controlled to be only in a desired direction can be used.

A desk lamp 8005 includes a light source 8006. As the light source 8006, the light-emitting apparatus of one embodiment of the present invention or the light-emitting device, which is part of the light-emitting apparatus, can be used.

In addition to the above examples, when the light-emitting apparatus of one embodiment of the present invention or the light-emitting device which, is part of the light-emitting apparatus, is used as a part of furniture in a room, a lighting device with a function of furniture can be obtained.

As described above, a variety of lighting devices that include the light-emitting apparatus can be obtained. Note that these lighting devices are also embodiments of the present invention.

The structures described in this embodiment can be used in an appropriate combination with any of the structures described in the other embodiments.

### Embodiment 8

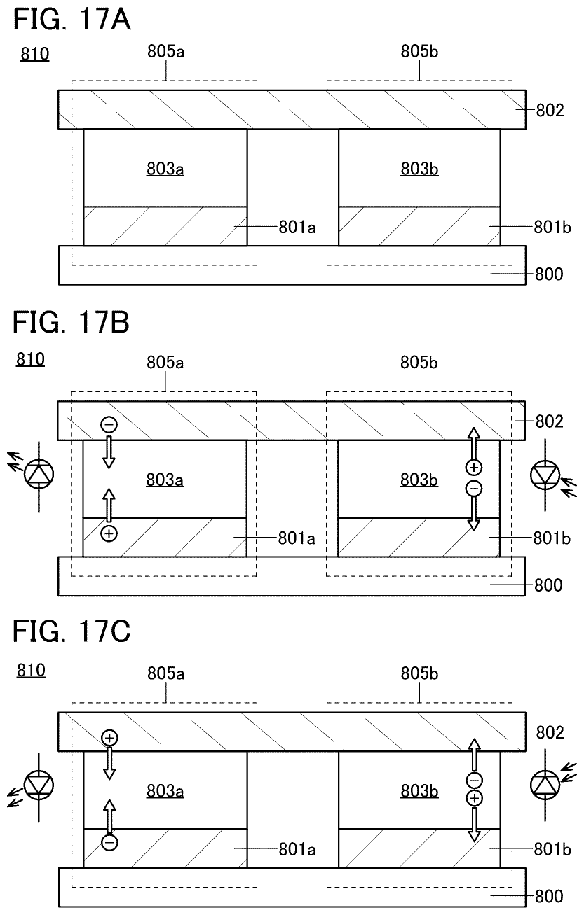

In this embodiment, a light-emitting device and a light-receiving device that can be used in a display apparatus of one embodiment of the present invention will be described with reference to FIG. 17

FIG. 17A is a schematic cross-sectional view illustrating a light-emitting device 805a and a light-receiving device 805b included in a light-emitting and light-receiving apparatus 810 of one embodiment of the present invention.

The light-emitting device 805a has a function of emitting light (hereinafter also referred to as a light-emitting function). The light-emitting device 805a includes an electrode 801a, an EL layer 803a, and an electrode 802. The light-emitting device 805a is preferably a light-emitting device utilizing organic EL (an organic EL device) described in Embodiment 1 and Embodiment 2. The EL layer 803a interposed between the electrode 801a and the electrode 802 includes at least a light-emitting layer. The light-emitting layer contains a light-emitting substance. The EL layer 803a emits light when voltage is applied between the electrode 801a and the electrode 802. The EL layer 803a may include any of a variety of layers such as a hole-injection layer, a hole-transport layer, an electron-transport layer, an electron-injection layer, a carrier-blocking (hole-blocking or electron-blocking) layer, and a charge-generation layer, in addition to the light-emitting layer.

The light-receiving device 805b has a function of detecting light (hereinafter also referred to as a light-receiving function). For example, a pn or pin photodiode can be used as the light-receiving device 805b. The light-receiving device 805b includes an electrode 801b, alight-receiving layer 803b, and the electrode 802. The light-receiving layer 803b interposed between the electrode 801b and the electrode 802 includes at least an active layer. Note that for the light-receiving layer 803b, any of materials that are used for the variety of layers (e.g., the hole-injection layer, the hole-transport layer, the light-emitting layer, the electron-transport layer, the electron-injection layer, the carrier (hole or electron)-blocking layer, and the charge-generation layer) included in the above-described EL layer 803a can be used. The light-receiving device 805b functions as a photoelectric conversion device and generates charge on the basis of incident light on the light-receiving layer 803b, and the charge can be extracted as a current. At this time, voltage may be applied between the electrode 801b and the electrode 802. The amount of generated charge is determined depending on the amount of light incident on the light-receiving layer 803b.

The light-receiving device 805b has a function of detecting visible light. The light-receiving device 805b has sensitivity to visible light. The light-receiving device 805b further preferably has a function of detecting visible light and infrared light. The light-receiving device 805b preferably has sensitivity to visible light and infrared light.

In this specification and the like, a blue (B) wavelength range is greater than or equal to 400 nm and less than 490 nm, and blue (B) light has at least one emission spectrum peak in the wavelength range. A green (G) wavelength range is greater than or equal to 490 nm and less than 580 nm, and green (G) light has at least one emission spectrum peak in the wavelength range. A red (R) wavelength range is greater than or equal to 580 nm and less than 700 nm, and red (R) light has at least one emission spectrum peak in the wavelength range. In this specification and the like, a visible light wavelength range is greater than or equal to 400 nm and less than 700 nm, and visible light has at least one emission spectrum peak in the wavelength range. An infrared (IR) wavelength range is greater than or equal to 700 nm and less than 900 nm, and infrared (IR) light has at least one emission spectrum peak in the wavelength range.

The active layer of the light-receiving device 805b includes a semiconductor. Examples of the semiconductor include an inorganic semiconductor such as silicon and an organic semiconductor including an organic compound. As the light-receiving device 805b, an organic semiconductor device (or an organic photodiode) including an organic semiconductor in the active layer is preferably used. An organic photodiode, which is easily made thin, lightweight, and large in area and has high flexibility in shape and design, can be employed for a variety of display apparatuses. With use of an organic semiconductor, the EL layer 803a included in the light-emitting device 805a and the light-receiving layer 803b included in the light-receiving device 805b can be formed by the same method (e.g., a vacuum evaporation method) with the same manufacturing apparatus, which is preferable. Note that the organic compound of one embodiment of the present invention can be used for the light-receiving layer 803b in the light-receiving device 805b.

In the display apparatus of one embodiment of the present invention, an organic EL device can be suitably used as the light-emitting device 805a and an organic photodiode can be suitably used as the light-receiving device 805b. The organic EL device and the organic photodiode can be formed over the same substrate. Thus, the organic photodiode can be incorporated in the display apparatus using the organic EL device. The display apparatus of one embodiment of the present invention has one or both of an image capturing function and a sensing function in addition to an image displaying function.

The electrode 801a and the electrode 801b are provided on the same plane. In FIG. 17(A), the electrode 801a and the electrode 801b are provided over a substrate 800. The electrode 801a and the electrode 801b can be formed by processing a conductive film formed over the substrate 800 into island-like shapes, for example. In other words, the electrode 801a and the electrode 801b can be formed through the same process.

As the substrate 800, a substrate having heat resistance high enough to withstand the formation of the light-emitting device 805a and the light-receiving device 805b can be used. When an insulating substrate is used as the substrate 800, a glass substrate, a quartz substrate, a sapphire substrate, a ceramic substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium or the like, or a semiconductor substrate such as an SOI substrate can be used.

As the substrate 800, it is particularly preferable to use the above-described insulating substrate or semiconductor substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

The electrode 802 is formed of a layer shared by the light-emitting device 805a and the light-receiving device 805b. A conductive film transmitting visible light and infrared light is used as the electrode through which light exits or enters among these electrodes. A conductive film reflecting visible light and infrared light is preferably used as the electrode through which light neither exits nor enters.

The electrode 802 in the display apparatus of one embodiment of the present invention functions as one of the electrodes in each of the light-emitting device 805a and the light-receiving device 805b.

In FIG. 17B, the electrode 801a of the light-emitting device 805a has a potential higher than that of the electrode 802. In this case, the electrode 801a functions as an anode and the electrode 802 functions as a cathode in the light-emitting device 805a. The electrode 801b of the light-receiving device 805b has a potential lower than that of the electrode 802. For easy understanding of the flow direction of current, FIG. 17B illustrates a circuit symbol of a light-emitting diode on the left of the light-emitting device 805a and a circuit symbol of a photodiode on the right of the light-receiving device 805b. The flow directions of carriers (electrons and holes) are also schematically indicated in each device by arrows.

In the structure illustrated in FIG. 17B, when a first potential is supplied to the electrode 801a through a first wiring, a second potential is supplied to the electrode 802 through a second wiring, and a third potential is supplied to the electrode 801b through a third wiring, the following relationship in potential magnitude is satisfied: the first potential>the second potential>the third potential.

FIG. 17C illustrates the case where the electrode 801a of the light-emitting device 805a has a potential lower than that of the electrode 802. In this case, the electrode 801a functions as a cathode and the electrode 802 function as an anode in the light-emitting device 805a. The electrode 801b of the light-receiving device 805b has a potential lower than that of the electrode 802 and a potential higher than that of the electrode 801a. For easy understanding of the flow direction of current, FIG. 17B illustrates a circuit symbol of a light-emitting diode on the left of the light-emitting device 805a and a circuit symbol of a photodiode on the right of the light-receiving device 805b. The flow directions of carriers (electrons and holes) are schematically indicated in each device by arrows.

In the structure illustrated in FIG. 17C, when the first potential is supplied to the electrode 801a through the first wiring, the second potential is supplied to the electrode 802 through the second wiring, and the third potential is supplied to the electrode 801b through the third wiring, the following relationship in potential magnitude is satisfied: the second potential>the third potential>the first potential.

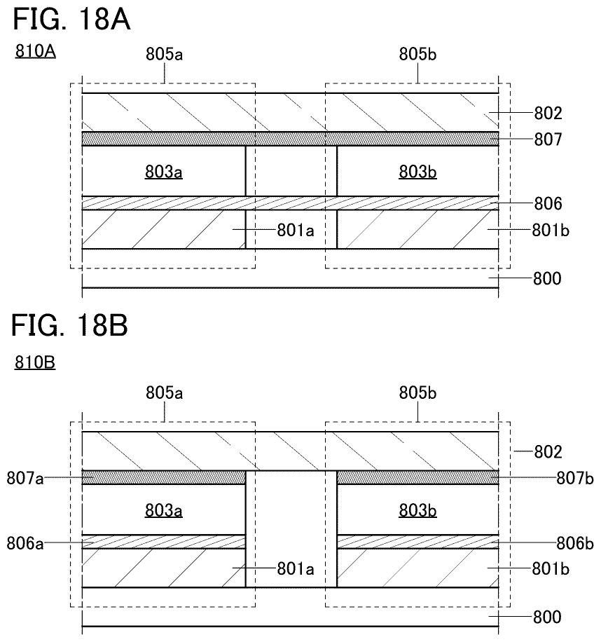

FIG. 18A illustrates a light-emitting and light-receiving apparatus 810A that is a variation example of the light-emitting and light-receiving apparatus 810. The light-emitting and light-receiving apparatus 810A is different from the light-emitting and light-receiving apparatus 810A in including a common layer 806 and a common layer 807. In the light-emitting device 805a, the common layer 806 and the common layer 807 function as part of the EL layer 803a. In the light-receiving device 805b, the common layer 806 and the common layer 807 function as part of the light-receiving layer 803b. The common layer 806 includes a hole-injection layer and a hole-transport layer, for example. The common layer 807 includes an electron-transport layer and an electron-injection layer, for example.

With the common layer 806 and the common layer 807, a light-receiving device can be incorporated without a significant increase in the number of times of separate formation of devices, whereby the light-emitting and light-receiving apparatus 810A can be manufactured with a high throughput.

FIG. 18B illustrates a light-emitting and light-receiving apparatus 810B that is a variation example of the light-emitting and light-receiving apparatus 810. The light-emitting and light-receiving apparatus 810B is different from the light-emitting and light-receiving apparatus 810A in that the EL layer 803a includes a layer 806a and a layer 807a and the light-receiving layer 803b includes a layer 806b and a layer 807b. The layer 806a and the layer 806b are formed using different materials, and each include a hole-injection layer and a hole-transport layer, for example. Note that the layer 806a and the layer 806b may be formed using the same material. The layer 807a and the layer 807b are formed using different materials, and each include an electron-transport layer and an electron-injection layer, for example. Note that the layer 807a and the layer 807b may be formed using the same material.

An optimum material for forming the light-emitting device 805a is selected for the layer 806a and the layer 807a and an optimum material for forming the light-receiving device 805b is selected for the layer 806b and the layer 807b, whereby the light-emitting device 805a and the light-receiving device 805b can have higher performance in the light-emitting and light-receiving apparatus 810B.

Note that the light-receiving devices 805b described in this embodiment can be arranged at a definition higher than or equal to 100 ppi, preferably higher than or equal to 200 ppi, more preferably higher than or equal to 300 ppi, further preferably higher than or equal to 400 ppi, still further preferably higher than or equal to 500 ppi and lower than or equal to 2,000 ppi, lower than or equal to 1,000 ppi, or lower than or equal to 600 ppi, for example. In particular, when the light-receiving devices 805b are arranged at a definition higher than or equal to 200 ppi and lower than or equal to 600 ppi, preferably higher than or equal to 300 ppi and lower than or equal to 600 ppi, the light-receiving devices can be suitably used for image capturing of a fingerprint. In the case where fingerprint authentication is performed with the display apparatus of one embodiment of the present invention, the increased definition of the light-receiving devices 805b enables, for example, highly accurate extraction of the minutiae of fingerprints; thus, the accuracy of the fingerprint authentication can be increased. The definition is preferably higher than or equal to 500 ppi, in which case the authentication conforms to the standard by the National Institute of Standards and Technology (NIST) or the like. On the assumption that the definition at which the light-receiving devices are arranged is 500 ppi, the size of each pixel is 50.8 μm, which indicates that the definition is adequate for image capturing of a fingerprint ridge distance (typically, greater than or equal to 300 μm and less than or equal to 500 μm).

The structures described in this embodiment can be used in an appropriate combination with any of the structures described in the other embodiments.

### Example 1

In this example, resistance to oxygen addition of the organic compound that can be used as the first organic compound included in the light-emitting device of one embodiment of the present invention was examined. Note that a material that can be used as the first organic compound was fabricated as Sample A, and Sample B and Sample C for comparison were fabricated, and evaluation results of the characteristics are described.

Structure formulas of organic compounds used for Sample A to Sample C are shown below.

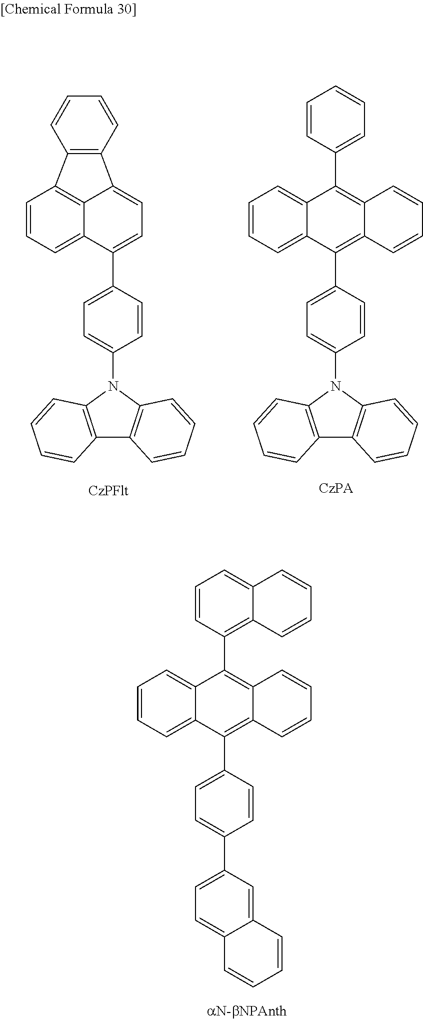

### <Method for Fabricating Sample A>

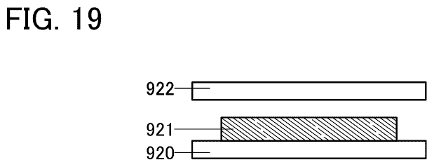

Sample A has a structure in which a film-like organic compound layer 921 was formed over a quartz substrate 920 as illustrated in FIG. 19. Note that the area of the organic compound layer 921 was 9 cm² (3 cm×3 cm). A quartz substrate was placed as a counter substrate 922 so that dust or the like is not attached to the organic compound layer 921. Note that the quartz substrate was placed such that the surface of the quartz substrate was not in contact with the organic compound layer 921.

First, over the quartz substrate 920, 9-[4-(3-fluoranthenyl)phenyl]-9H-carbazole (abbreviation: CzPFlt) was deposited to a thickness of 50 nm by an evaporation method using resistance heating to form the organic compound layer 921.

Next, a sealant was provided over the quartz substrate 920, and the counter substrate 922 was placed so as not to be in contact with the organic compound layer 921.

### <Method for Fabricating Sample B>

Next, a method for fabricating Sample B is described. Note that Sample B is different from Sample A in the structure of the organic compound layer 921.

As Sample B, 9-[4-(10-phenyl-9-anthracenyl)phenyl]-9H-carbazole (abbreviation: CzPA) was deposited to a thickness of 50 nm over the quartz substrate 920 by an evaporation method using resistance heating to form the organic compound layer 921.

The other structures of Sample B were fabricated in a manner similar to those of Sample A.

### <Method for Fabricating Sample C>

Next, a method for fabricating Sample C is described. Note that Sample C is different from Sample A in the structure of the organic compound layer 921.

As Sample B, 9-(1-naphthyl)-10-[4-(2-naphthyl)phenyl]anthracene (abbreviation: αN-βNPAnth) was deposited to a thickness of 50 nm over the quartz substrate 920 by an evaporation method using resistance heating to form the organic compound layer 921.

The other structures of Sample C were fabricated in a manner similar to those of Sample A.

### <Evaluation Method of Samples>

### <<Light Exposure Conditions>>

The fabricated Sample A to Sample C were irradiated with light of a mercury lamp. Specifically, the organic compound layer 921 was irradiated with light through the quartz substrate that is the counter substrate 922. The energy of the irradiation light was set to three levels: 250 mJ/cm², 500 mJ/cm², and 1,000 mJ/cm². Note that the irradiation light includes light with a wavelength of 436 nm, light with a wavelength of 405 nm, and light with a wavelength of 365 nm.

The above samples obtained under different light exposure conditions were subjected to liquid chromatography mass spectrometry (LC-MS). First, a solvent in which acetonitrile and chloroform were mixed at a volume ratio of acetonitrile:chloroform=7:3 and the above samples were each put in a vial bottle, and the vial bottle was irradiated with ultrasonic waves with a ultrasonic cleaning machine for 10 minutes. The solution was removed from the vial bottle and filtered with a porous polytetrafluoroethylene (abbreviation: PTFE) filter having a hole diameter of 0.2 μm to give a filtrate. The filtrate was used as a measurement sample. Note that LC (liquid chromatography) separation was carried out with a Waters ACQUITY UPLC (registered trademark), and MS analysis (mass spectrometry) was carried out with a Waters Xevo G2 Tof MS.

### <Characteristics of Samples>

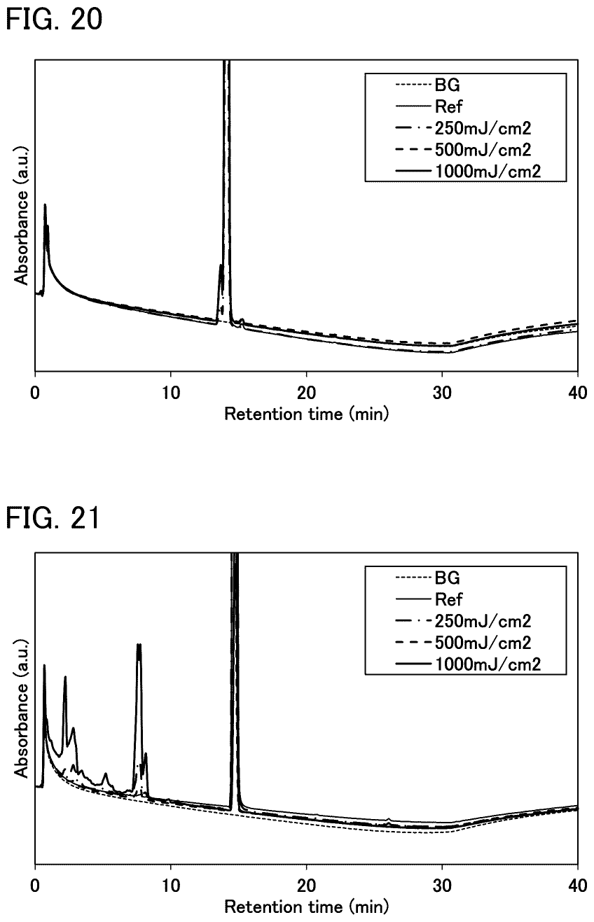

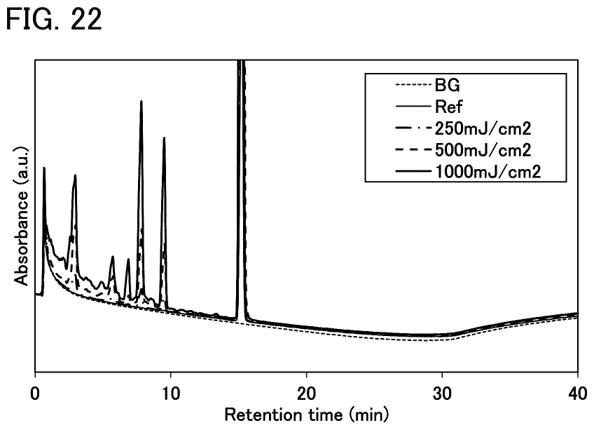

As results of the evaluations, FIG. 20 shows the obtained characteristics of Sample A. FIG. 21 shows the obtained characteristics of Sample B, and FIG. 22 shows the obtained characteristics of Sample C. For each sample, results of the light exposure conditions (250 mJ/cm², 500 mJ/cm², and 1,000 mJ/cm²), a result of no light exposure (Ref), and a result of only a solvent (BG) are shown. The structures and evaluation results of Sample A to Sample C are shown in the following table.

TABLE 2

| | | Generation of |
|---|---|---|
| | Organic compound | deterioration product |
| | layer 921 | after light exposure |
| Sample A | CzPFlt | — |
| Sample B | CzPA | ◯ |
| Sample C | αN-βNPAnth | ◯ |

As shown in FIG. 20, a signal derived from CzPFlt was observed as a result of liquid chromatography mass spectrometry analysis of Sample A. There is no significant difference between the sample that was not exposed to light and the samples that were exposed to light.

Meanwhile, as for Sample B and Sample C shown in FIG. 21 and FIG. 22, peaks attributed to the deterioration product were observed in the samples that were exposed to light. FIG. 21 confirms that at least two kinds of molecular structures to which oxygen was added (deterioration products) were generated in Sample B. In addition, FIG. 22 confirms that at least three kinds of molecular structures to which oxygen was added were generated in Sample C. This suggests that as the energy of the irradiation light increases, structures to which oxygen was added tended to be easily generated in Sample B and Sample C.

### Example 2

### Synthesis Example 1

A synthesis method of 3,11-bis(2,7-di-tert-butyl-9H-carbazol-9-yl)-7-[2,7-di(3,5-di-tert-butylphenyl)-9H-carbazol-9-yl]-5,9-diphenyl-5H,9H-[1,4]benzazaborino[2,3,4-kl]phenazaborine (abbreviation: BD-1), which is a compound of one embodiment of the present invention represented by Structural Formula (100) in Embodiment 1, is described in this example. The structure of BD-1 is shown below.

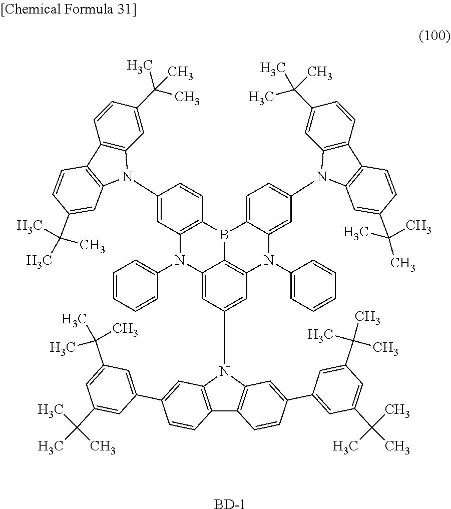 [SMILES: CC(C)(C)c1cc(-c2ccc3c4ccc(-c5cc(C(C)(C)C)cc(C(C)(C)C)c5)cc4n(-c4cc5c6c(c4)N(c4ccccc4)c4cc(-n7c8cc(C(C)(C)C)ccc8c8ccc(C(C)(C)C)cc87)ccc4B6c4ccc(-n6c7cc(C(C)(C)C)ccc7c7ccc(C(C)(C)C)cc76)cc4N5c4ccccc4)c3c2)cc(C(C)(C)C)c1 ; "BD-1"]

### <Step 1: 2,7-Di-Tert-Butyl-9-(3-Chlorophenyl)Carbazole>

Into a 500 mL three-neck flask were put 7.6 g (40 mmol) of 1-bromo-3-chlorobenzene, 10 g (36 mmol) of 2,7-di-tert-butylcarbazole, and 6.9 g (72 mmol) of sodium-t-butoxide, and the air in the flask was replaced with nitrogen. Then, 200 mL of toluene was added to the mixture, the flask was degassed under reduced pressure, and then, 2.5 mL of tri-tert-butylphosphine (a 10 w % hexane solution) and 0.22 g (0.38 mmol) of bis(dibenzylideneacetone)palladium(0) were added to the mixture and the mixture was stirred under a nitrogen stream at 100° C. for 7 hours.

After the stirring, 500 mL of toluene was added to the obtained mixture, which was then subjected to suction filtration through Florisil (Wako Pure Chemical Industries, Ltd., Catalog Number: 066-05265), Celite (Wako Pure Chemical Industries, Ltd., Catalog Number: 537-02305), and aluminum oxide to give a filtrate. The obtained filtrate was concentrated to give a brown solid.

This solid was purified by silica gel column chromatography to give 10.5 g of a target substance in a yield of 75%. The synthesis scheme of Step 1 is shown in (a-1) below.

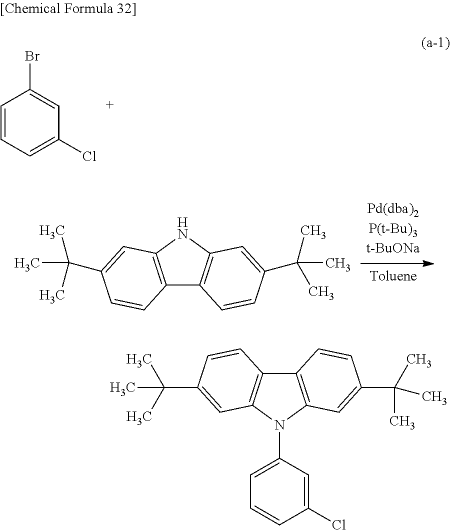

Results of ¹H NMR measurement of the solid obtained in Step 1 described above are shown below. The result reveals that 2,7-di-tert-butyl-9-(3-chlorophenyl)carbazole was obtained. ¹H NMR (CDCl₃, 300 MHz): σ=8.01-7.98 (in, 2H), 7.60-7.54 (m, 2H), 7.50-7.44 (m, 2H), 7.35-7.32 (m, 4H), 1.37 (s, 18H).

### Step 2: Synthesis of 3-(2,7-di-tert-butylcarbazol-9-yl)diphenylamine

Into a 500 mL three-neck flask were put 6.5 g (17 mmol) of 2,7-di-tert-butyl-9-(3-chlorophenyl)carbazole, 1.9 g (21 mmol) of aniline, and 3.8 g (40 mmol) of sodium-t-butoxide, and the air in the flask was replaced with nitrogen. Then, 170 mL of xylene was added to the mixture, the flask was degassed under reduced pressure, and then, 0.12 g (0.34 mmol) of di-tert-butyl(2,2-diphenyl-1-methyl-1-cyclopropyl)phosphine (abbreviation: cBRIDP) and 60 mg (0.16 mmol) of allylpalladium(II)chloride dimer were added to the mixture and the mixture was stirred under a nitrogen stream at 120° C. for 4 hours.

After the stirring, 400 mL of toluene was added to the obtained mixture, which was then subjected to suction filtration through Florisil (Wako Pure Chemical Industries, Ltd., Catalog Number: 066-05265), Celite (Wako Pure Chemical Industries, Ltd., Catalog Number: 537-02305), and aluminum oxide to give a filtrate. The obtained filtrate was concentrated to give a brown solid.

The obtained oily substance was purified by silica gel column chromatography to give 7.0 g of a target white solid in a yield of 95%. The synthesis scheme is shown in (a-2) below.

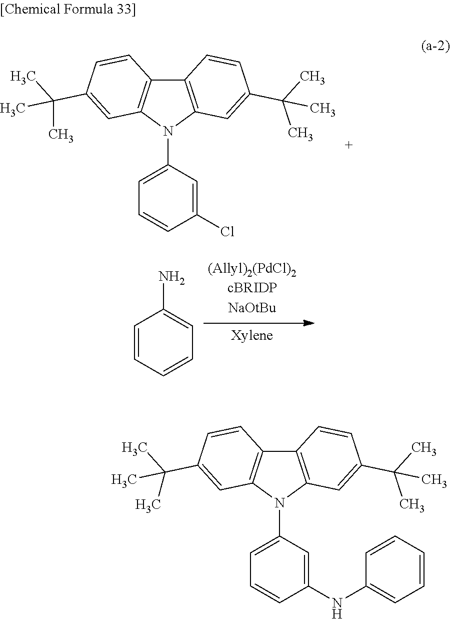

Results of ¹H NMR measurement of the white solid obtained in Step 2 described above will be described below. The results reveals that 3-(2,7-di-tert-butylcarbazol-9-yl)diphenylamine was obtained.

¹H NMR (CDCl₃, 300 MHz): σ=7.99-7.97 (m, 2H), 7.52 (t, J=8.1 Hz, 1H), 7.43 (d, J=1.8 Hz, 2H), 7.33-7.27 (m, 5H), 7.21-7.17 (m, 2H), 7.12-7.07 (m, 2H), 6.99-6.94 (m, 1H), 5.87 (bs, 1H), 1.38 (s, 18H).

### Step 3: Synthesis of N,N-bis[3-(2,7-di-tert-butylcarbazol-9-yl)phenyl]-N′,N′-diphenyl-1-chlorobenzene-3,5-diamine

Into a 200 mL three-neck flask were put 0.9 g (3.3 mmol) of 3,5-dibromo-1-chlorobenzene, 3.0 g (6.8 mmol) of 3-(2,7-di-tert-butylcarbazol-9-yl)diphenylamine, and 1.3 g (18 mmol) of sodium-t-butoxide, and the air in the flask was replaced with nitrogen. To this mixture was added 35 mL of toluene, the flask was degassed under reduced pressure, and then, 0.3 mL of tri-tert-butylphosphine (a 10 w % hexane solution) and 20 mg (35 μmol) of bis(dibenzylideneacetone)palladium(0) were added to the mixture and the mixture was stirred under a nitrogen stream at 80° C. for 7 hours.

After the stirring, 400 mL of toluene was added to the obtained mixture, which was then subjected to suction filtration through Florisil (Wako Pure Chemical Industries, Ltd., Catalog Number: 066-05265), Celite (Wako Pure Chemical Industries, Ltd., Catalog Number: 537-02305), and aluminum oxide to give a filtrate. The obtained filtrate was concentrated to give a brown solid.

This solid was purified by silica gel column chromatography to give 3.5 g of the target substance. The synthesis scheme of Step 3 is shown in (a-3) below.

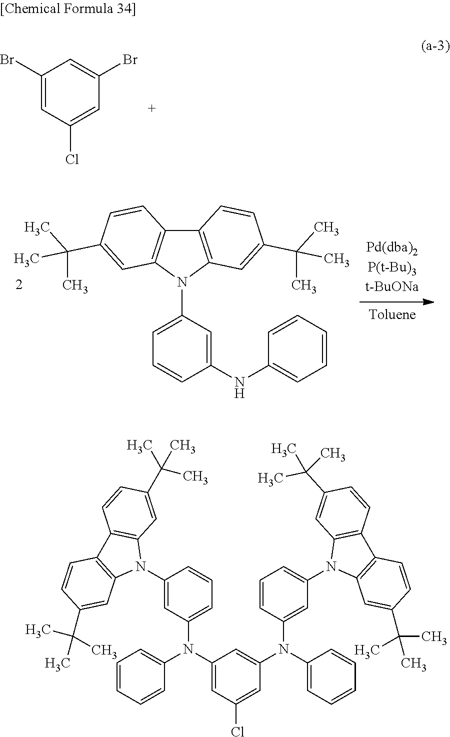

Results of ¹H NMR measurement of the brown solid obtained in Step 3 described above will be described below. The result reveals that N,N-bis[3-(2,7-di-tert-butylcarbazol-9-yl)phenyl]-N′N′-diphenyl-1-chlorobenzene-3,5-diamine was obtained.

¹H NMR (CDCl₃, 300 MHz): σ=7.97-7.94 (m, 4H), 7.47-7.41 (m, 2H), 7.30-7.11 (m, 22H), 6.98-6.94 (m, 2H), 6.77 (m, 1H), 6.72-6.71 (m, 2H), 1.34 (s, 36H).

### Step 4: Synthesis of 2,7-bis(3,5-di-tert-butylphenyl)-9H-carbazole

Into a 500 mL three-neck flask, 5.5 g (17 mmol) of 2,7-dibromocarbazole, 8.7 g (37 mmol) of 3,5-di-tert-butylphenylboronic acid, and 0.12 g (0.39 mmol) of tri-(o-tolyl)phosphine were put, and the air in the flask was replaced with nitrogen. To the mixture, 150 mL of toluene, 40 mL of ethanol, and 34 mL of an aqueous solution of 2 M potassium carbonate were added, the flask was degassed under reduced pressure, then 40 mg (0.18 mmol) of palladium(II) acetate was added to the mixture, and the mixture was stirred under a nitrogen stream at 90° C. for 7 hours.

After the stirring, water was added to this mixture, and an aqueous layer was subjected to extraction with toluene. The obtained extracted solution and an organic layer were combined, washed with water and saturated saline, and dried with magnesium sulfate. This mixture was separated by gravity filtration, and the filtrate was concentrated to give a gray solid.

Then, toluene and hexane were added to the obtained solid, and the obtained mixture was irradiated with ultrasonic waves and purified by silica gel column chromatography to give a target white solid. The synthesis scheme is shown in (a-4) below.

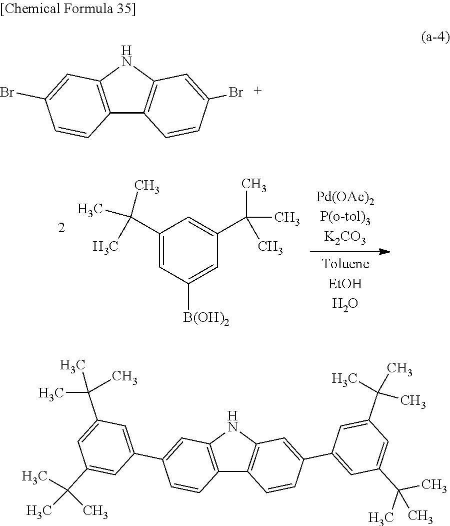 [SMILES: Brc1ccc2c(c1)[nH]c1cc(Br)ccc12 ; CC(C)(C)c1cc(B(O)O)cc(C(C)(C)C)c1 ; CC(C)(C)c1cc(-c2ccc3c(c2)[nH]c2cc(-c4cc(C(C)(C)C)cc(C(C)(C)C)c4)ccc23)cc(C(C)(C)C)c1]

Results of ¹H NMR measurement of the white solid obtained in Step 4 described above will be described below. The result reveals that 2,7-bis(3,5-di-tert-butylphenyl)-9H-carbazole was obtained.

¹H NMR(CDCl₃, 300 MHz): σ=8.16-8.11 (m, 3H), 7.65 (m, 2H), 7.54-7.46 (m, 8H), 1.42 (s, 36H).

### Step 5: Synthesis of N,N-bis[3-(2,7-di-tert-butylcarbazol-9-yl)phenyl]-N′,N′-diphenyl-1-[2,7-bis(3,5-di-tert-butylphenyl)-9H-carbazol-9-yl]-3,5-diamine

Into a 200 mL three-neck flask were put 3.5 g of N,N-bis[3-(2,7-di-tert-butylcarbazol-9-yl)phenyl]-N′,N′-diphenyl-1-chlorobenzene-3,5-diamine, 2.1 g (3.9 mmol) of 2,7-bis(3,5-di-tert-butylphenyl)-9H-carbazole, and 0.75 g (7.8 mmol) of sodium-t-butoxide, and the air in the flask was replaced with nitrogen. Then, 30 mL of xylene was added to the mixture, the flask was degassed under reduced pressure, then, 40 mg (0.11 mmol) of di-tert-butyl(2,2-diphenyl-1-methyl-1-cyclopropyl)phosphine (abbreviation: cBRIDP) and 20 mg (55 μmol) of allylpalladium(II)chloride dimer were added to the mixture, and the mixture was stirred under a nitrogen stream at 120° C. for 4 hours.

After the stirring, 300 mL of toluene was added to the obtained mixture, which was then subjected to suction filtration through Florisil (Wako Pure Chemical Industries, Ltd., Catalog Number: 066-05265), Celite (Wako Pure Chemical Industries, Ltd., Catalog Number: 537-02305), and aluminum oxide to give a filtrate. The obtained filtrate was concentrated to give a brown solid.

This solid was purified by silica gel column chromatography to give 5.1 g of the target substance. The synthesis scheme of Step 5 is shown in (a-5) below.

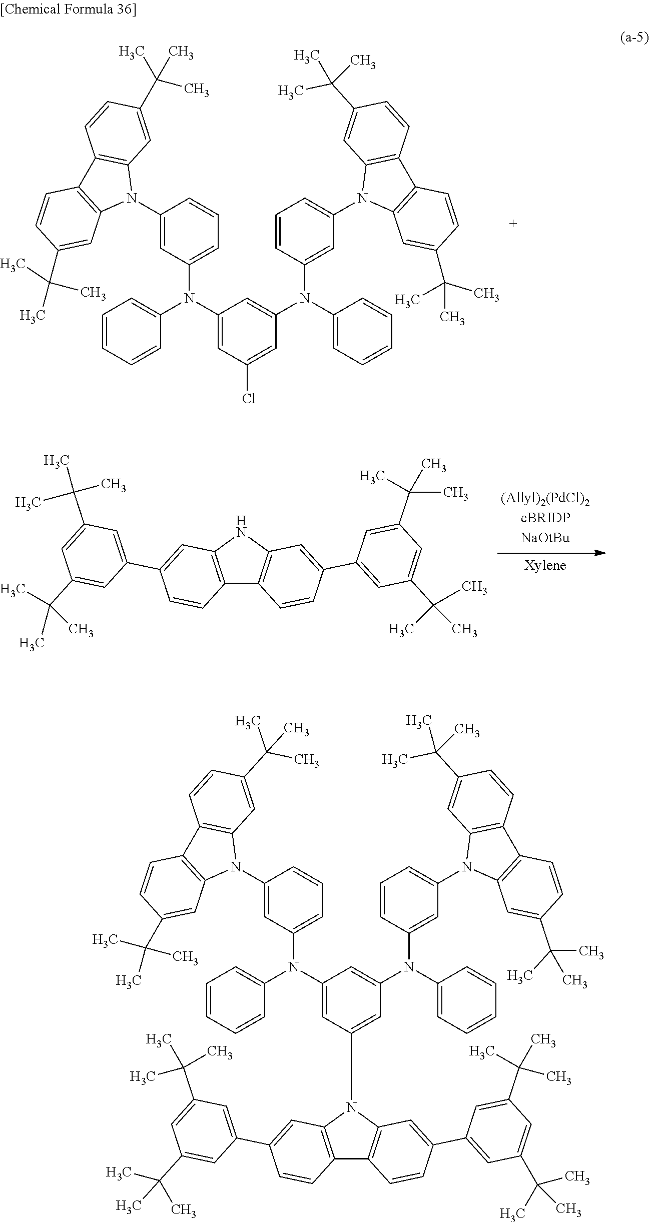

Results of ¹H NMR measurement of the brown solid obtained in Step 5 described above will be described below. The result reveals that N,N-bis[3-(2,7-di-tert-butylcarbazol-9-yl)phenyl]-N′,N′-diphenyl-1-[2,7-bis(3,5-di-tert-butylphenyl)-9H-carbazol-9-yl]-3,5-diamine was obtained.

¹H NMR (CDCl₃, 300 MHz): σ=8.16-8.12 (m, 2H), 7.93 (d, J=7.8 Hz, 4H), 7.68-7.65 (m, 2H), 7.51-7.46 (m, 8H), 7.33-7.05 (m, 26H), 6.89-6.84 (in, ³H), 1.38 (s, 36H), 1.26 (s, 36H).

### Step 6: Synthesis of BD-1

Into a 200 mL three-neck flask was put 5.1 g of N,N-bis[3-(2,7-di-tert-butylcarbazol-9-yl)phenyl]-N′,N′-diphenyl-1-[2,7-di(3,5-di-tert-butylphenyl)-9H-carbazol-9-yl]-3,5-diamine, and the air in the flask was replaced with nitrogen. Then, 20 mL of 1,2-dichlorobenzene was added to the mixture, and the mixture was stirred at room temperature. To this solution was added 1.2 mL (13 mmol) of boron tribromide, and the mixture was stirred under a nitrogen stream at 180° C. for 14 hours.

After the stirring, 20 mL of diisopropylmethylamine and 500 mL of toluene were added to the mixture, which was then subjected to suction filtration through Florisil (Wako Pure Chemical Industries, Ltd., Catalog Number: 066-05265) and Celite (Wako Pure Chemical Industries, Ltd., Catalog Number: 537-02305) to give a filtrate. The obtained filtrate was concentrated to give a brown solid.

The obtained solid was purified by silica gel column chromatography, methanol was added thereto, and the mixture was irradiated with ultrasonic waves to give 3.3 g of the target substance. The synthesis scheme of Step 6 is shown in (a-6) below.

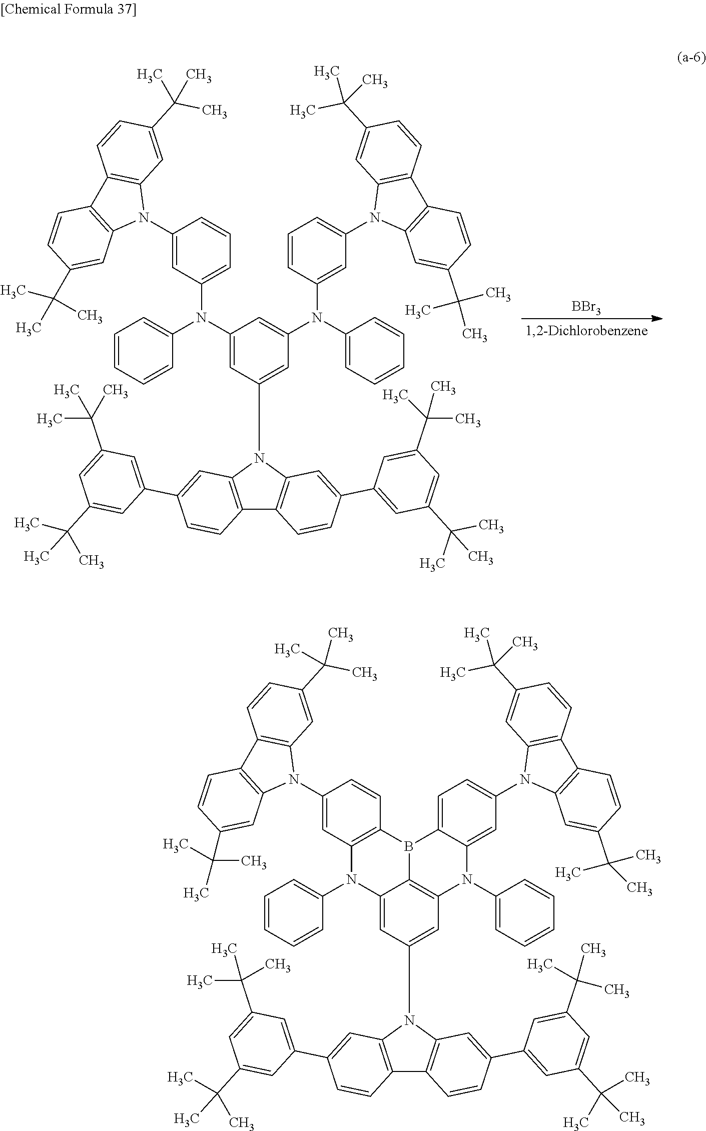

By the train sublimation method, 1.6 g of the obtained yellow solid was sublimated and purified. In the sublimation purification, the yellow solid was heated under a pressure of 3.5×10⁻² Pa at 350° C. for 15 hours. After the sublimation purification, 1.4 g of the target yellow solid was obtained at a collection rate of 87%.

The molecular weight of the yellow solid obtained in Step 6 was measured by LC/MS, in which case m/z=1517 was obtained and the molecular weight of the target substance was 1517, which indicates that BD-1 (structure formula (100)) was obtained.

### <Characteristics of Organic Compound>

The obtained BD-1 was analyzed. As a comparative example, an analysis result of 3,10PCA2Nbf(IV)-02, which is a structure shown below, is described.

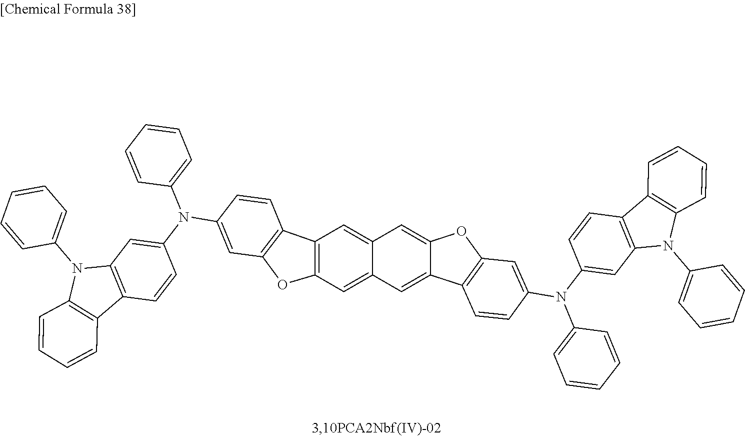 [SMILES: c1ccc(N(c2ccc3c(c2)oc2cc4cc5c(cc4cc23)oc2cc(N(c3ccccc3)c3ccc4c6ccccc6n(-c6ccccc6)c4c3)ccc25)c2ccc3c4ccccc4n(-c4ccccc4)c3c2)cc1]

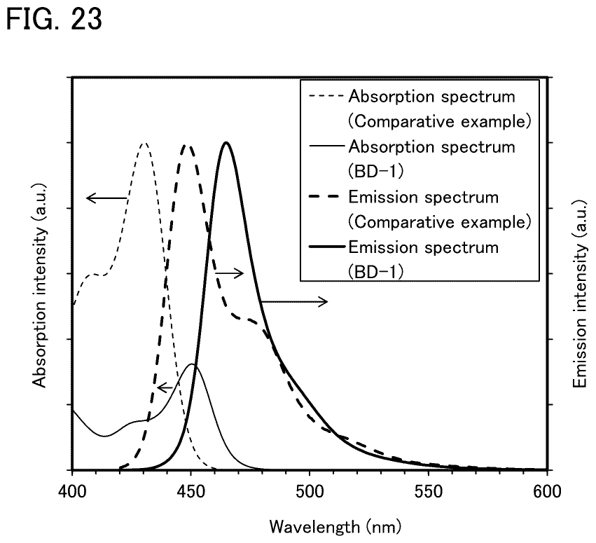

The ultraviolet-visible absorption spectra (hereinafter, simply referred to as “absorption spectra”) and emission spectra of BD-1 in a toluene solution and 3,10PCA2Nbf(IV)-02 in a toluene solution serving as a comparative example were measured. The absorption spectrum was measured with an ultraviolet-visible spectrophotometer (V-550DS, JASCO Corporation). The emission spectrum of BD-1 was measured with a spectrofluorometer (FP-8600DS, JASCO Corporation) and the emission spectrum of 3,10PCA2Nbf(IV)-02 was measured with a quantum yield measurement apparatus (C11348-01, Hamamatsu Photonics). FIG. 23 shows the obtained measurement results of the absorption spectrum and the emission spectrum in the toluene solution. The horizontal axis represents wavelength and the vertical axis represents absorption intensity.

As shown in FIG. 23, BD-1 in the toluene solution has the longest wavelength absorption peak at around 450 nm and the shortest wavelength emission peak at 465 nm (excitation wavelength: 410 nm). In addition, 3,10PCA2Nbf(IV)-02 in the toluene solution has the longest wavelength absorption peak at around 430 nm and the shortest wavelength emission peak at 448 nm (excitation wavelength: 410 nm).

As shown in FIG. 23, BD-1 has a half width of 25 nm and a 1/e value width of 33 nm. Furthermore, 3,10PCA2Nbf(IV)-02 has a half width of 27 nm and a 1/e value width of 49 nm.

### Example 3

In this example, a light-receiving device 1 of one embodiment of the present invention described in the above embodiments, a comparative device 2, and a comparative device 3 were fabricated and the measurement results of the characteristics are described.

Structural Formulas of organic compounds used for the light-emitting device 1, the comparative light-emitting device 2, and the comparative light-emitting device 3 are shown below.

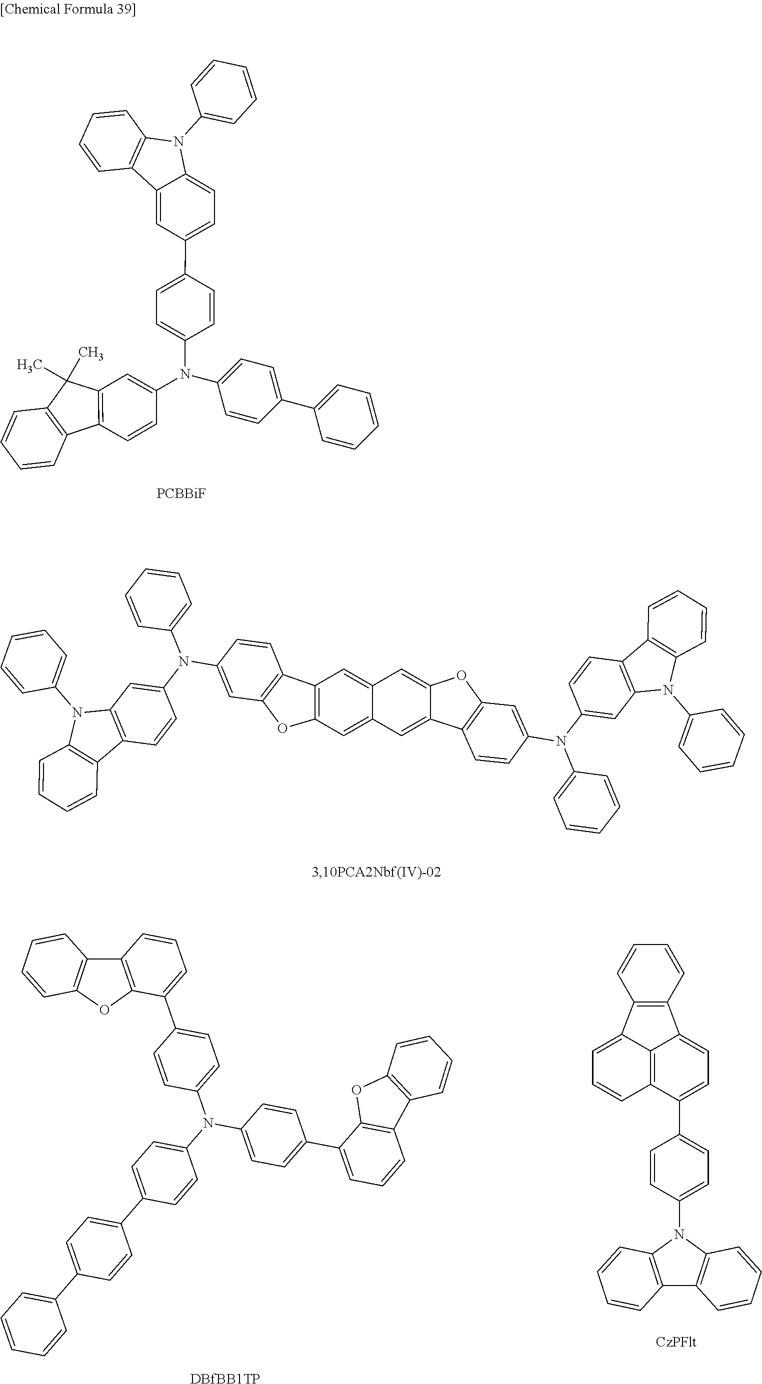

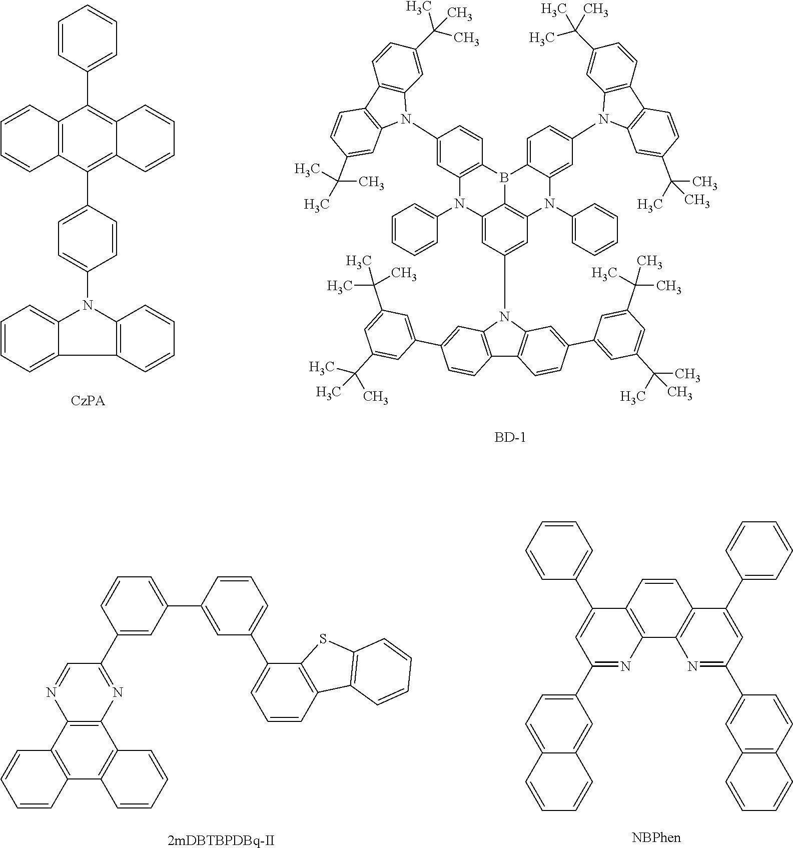

### <Method for Fabricating Light-Emitting Device 1>

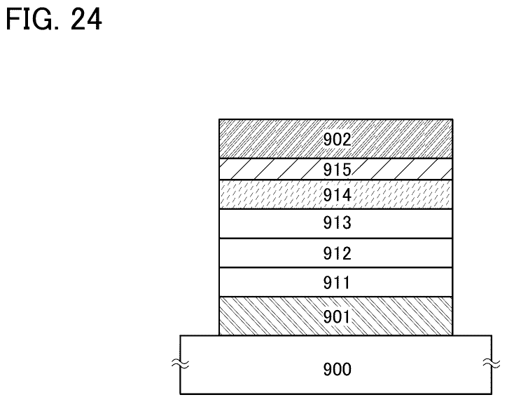

The light-receiving device 1 has a structure in which a hole-injection layer 911, a hole-transport layer 912, a light-emitting layer 913, an electron-transport layer 914, and an electron-injection layer 915 are sequentially stacked over a first electrode 901 formed over a glass substrate 900, and a second electrode 902 is stacked over the electron-injection layer 915, as illustrated in FIG. 24.

First, indium oxide-tin oxide containing silicon or silicon oxide (abbreviation: ITSO) was deposited by a sputtering method, whereby the first electrode 901 was formed over the glass substrate 900. Note that the film thickness was 70 nm and the area of the electrode was 4 mm² (2 mm×2 mm).

Next, in pretreatment for forming the light-emitting device 1 over the substrate, a surface of the substrate was washed with water and baking was performed at 200° C. for 1 hour. After that, the substrate was introduced into a vacuum evaporation apparatus, and vacuum baking was performed at 170° C. for 60 minutes in a heating chamber of the vacuum evaporation apparatus having a pressure reduced to approximately 10⁻⁴ Pa. After that, natural cooling was performed for approximately 30 minutes.

Next, the substrate over which the first electrode 901 was formed was fixed to a substrate holder provided in the vacuum evaporation apparatus such that the surface over which the first electrode 901 was formed faced downward. Over the first electrode 901, N-(1,1′-biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron-acceptor material with a molecular weight of 672 (OCHD-003) were deposited to a thickness of 10 nm by co-evaporation using resistance heating at the weight ratio of PCBBiF:OCHD-003=1:0.03, whereby the hole-injection layer 911 was formed.

Subsequently, over the hole-injection layer 911, PCBBiF was deposited to a thickness of 20 nm by evaporation, and then N,N-bis[4-(dibenzofuran-4-yl)phenyl]-4-amino-p-terphenyl (abbreviation: DBfBB31TP) was deposited to a thickness of 10 nm by evaporation, whereby the hole-transport layer 912 was formed.

Next, the light-emitting layer 913 was formed over the hole-transport layer 912. In the light-emitting layer 913 of the light-emitting device 1 in this example, the organic compound having a fluoranthene skeleton described in Embodiment 1 was used as the host material, and the dopant with a narrow emission spectrum width was used as the guest material. By an evaporation method using resistance heating, 9-[4-(3-fluoranthenyl)phenyl]-91H-carbazole (abbreviation: CzPFlt) and 3,11-bis(2,7-di-tert-butyl-9H-carbazol-9-yl)-7-[2,7-di(3,5-di-tert-butylphenyl)-9H-carbazol-9-yl]-5,9-diphenyl-5H,9H-[1,4]benzazaborino[2,3,4-kl]phenazaborine (abbreviation: BD-1) were co-deposited to 25 nm at the weight ratio of BD-1:0.015, whereby the light-emitting layer 913 was formed.

Then, over the light-emitting layer 913, 2-[3′-(dibenzothiophen-4-yl)biphenyl-3-yl]dibenzo[f,h]quinoxaline (abbreviation: 2mDBTBPDBq-II) was deposited to a thickness of 10 nm by evaporation, and then 2,9-di(2-naphthyl)-4,7-diphenyl-1,10-phenanthroline (abbreviation: NBPhen) was deposited to a thickness of 15 nm by evaporation, whereby the electron-transport layer 914 was formed.

Next, lithium fluoride (LiF) was deposited to a thickness of 1 nm by evaporation over the electron-transport layer 914, whereby the electron-injection layer 915 was formed.

Next, 150 nm of aluminum (abbreviation: A1) was deposited by evaporation over the electron-injection layer 915 using a resistance-heating method to form the second electrode 902, so that the light-emitting device was fabricated.

### <Method for Fabricating Comparative Light-Emitting Device 2>

Next, a method for fabricating the comparative light-emitting device 2 is described.

The comparative light-emitting device 2 is different from the light-emitting device in the structure of the light-emitting layer 913. That is, in the comparative light-emitting device 2, 9-[4-(10-phenyl-9-anthracenyl)phenyl]-9H-carbazole (abbreviation: CzPA) and BD-1 were co-deposited to a thickness of 25 nm over the hole-transport layer 912 at the weight ratio of BD-1=1:0.015 by an evaporation method using resistance heating, whereby the light-emitting layer 913 was formed.

Other components were fabricated in a manner similar to that for the light-emitting device 1.

### <Method for Fabricating Comparative Light-Emitting Device 3>

Next, a method for fabricating the comparative light-emitting device 3 is described.

The comparative light-emitting device 3 is different from the light-emitting device in the structure of the light-emitting layer 913. That is, in the comparative light-emitting device 3, CzPFlt and 3,10-bis[V-(9-phenyl-9H-carbazol-2-yl)-N-phenylamino]naphtho[2,3-b; 6,7-b′]bisbenzofuran (abbreviation: 3,10PCA2Nbf(IV)-02) were co-deposited to a thickness of 25 nm over the hole-transport layer 912 at the weight ratio of CzPFlt:3,10PCA2Nbf(IV)-02=1:0.015 by an evaporation method using resistance heating, whereby the light-emitting layer 913 was formed.

Other components were fabricated in a manner similar to that for the light-emitting device 1.

The stacked-layer structures of the light-emitting device 1, the comparative light-emitting device 2, and the comparative light-emitting device 3 are listed in the following table.

TABLE 3

| | Thickness | Light-emitting | Comparative light- | Comparative light- |
|---|---|---|---|---|
| | [nm] | device 1 | emitting device 2 | emitting device 3 |
| Second electrode | 150 | Al | | |
| Electron-injection | 1 | LiF | | |
| layer | | | | |
| Electron- | 15 | NBPhen | | |
| transport layer | 10 | 2mDBTBPDBq-II | | |
| Light-emitting | 25 | CzPFlt:BD-1 | CzPA:BD-1 | CzPFlt:3,10PCA2Nbf(IV)-02 |
| layer | | (1:0015) | (1:0015) | (1:0015) |

| | | |
|---|---|---|
| Hole-transport | 10 | DBfBB1TP |
| layer | 20 | PCBBiF |
| Hole-injection | 10 | PCBBiF:OCHD-003 |
| layer | | (1:0.03) |
| First electrode | 70 | ITSO |

In the above manner, the light-emitting device 1, the comparative light-emitting device 2, and the comparative light-emitting device 3 were fabricated.

### <Characteristics of Light-Emitting Device>

The light-emitting device 1, the comparative light-emitting device 2, and the comparative light-emitting device 3 were each subjected to sealing with a glass substrate (a sealant was applied to surround the devices, followed by UV treatment and one-hour heat treatment at 80° C. at the time of sealing) in a glove box having a nitrogen atmosphere so that the light-emitting devices are not exposed to the air. After that, the emission characteristics of the light-emitting device 1, the comparative light-emitting device 2, and the comparative light-emitting device 3 were measured.

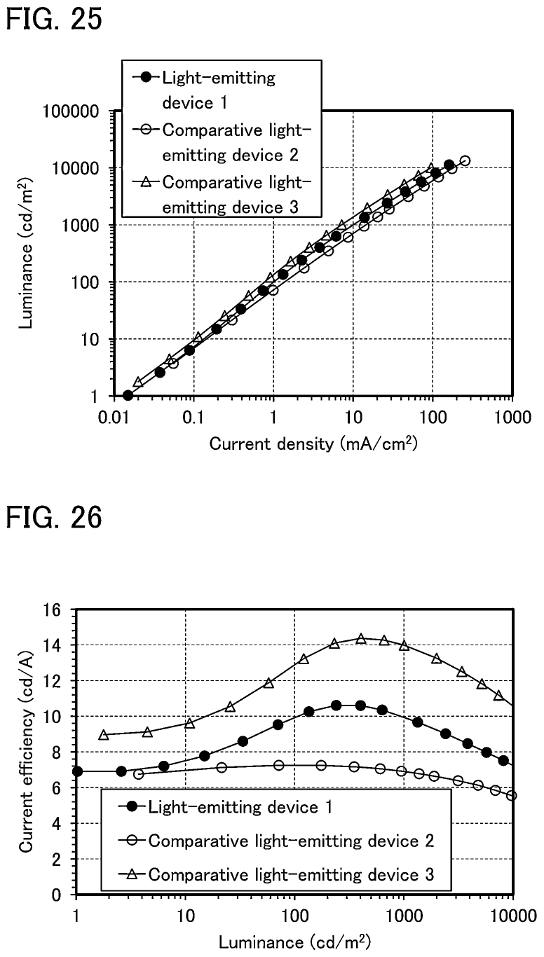

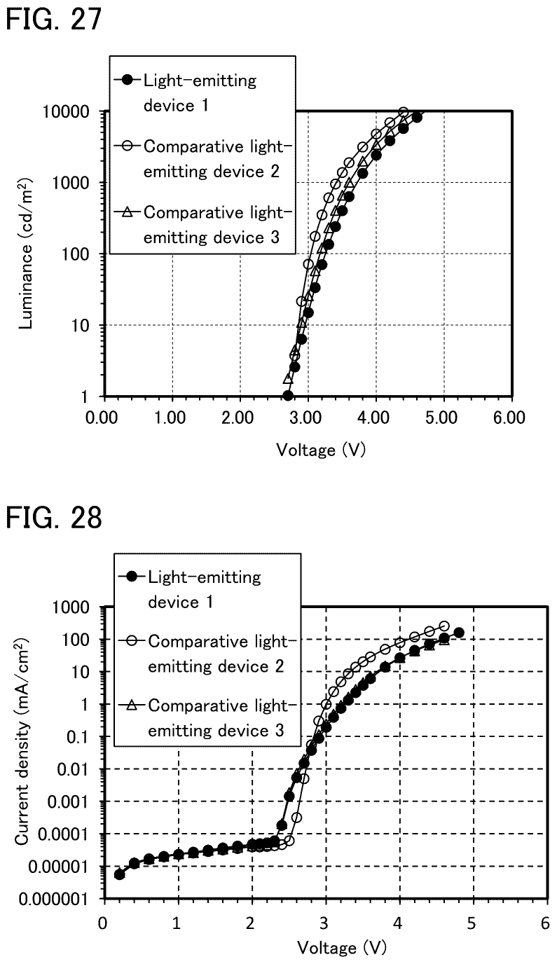

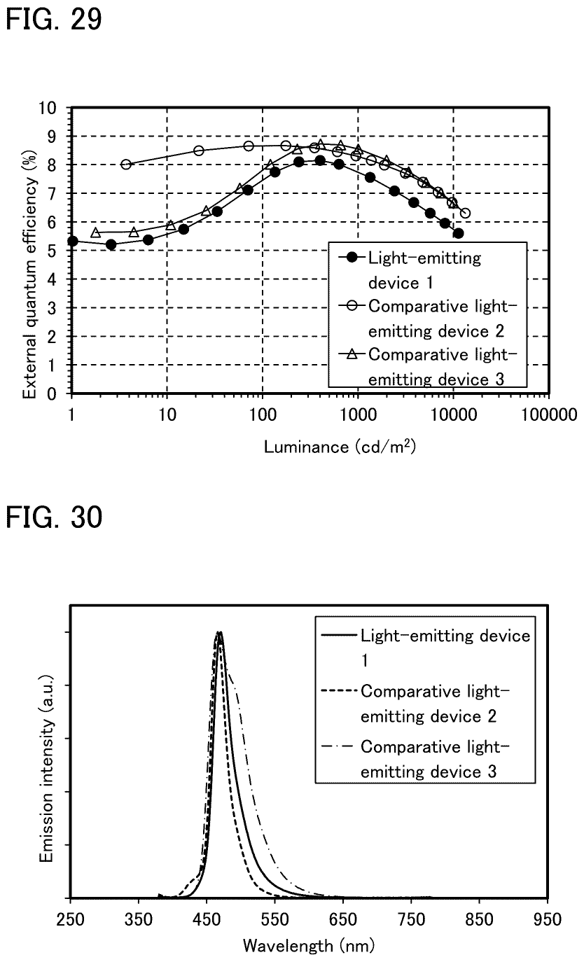

As for the light-emitting device 1, the comparative light-emitting device 2, and the comparative light-emitting device 3, FIG. 25 shows the luminance-current density characteristics; FIG. 26 shows the current efficiency-luminance characteristics; FIG. 27 shows the luminance-voltage characteristics; FIG. 28 shows the current density-voltage characteristics; FIG. 29 shows the external quantum efficiency-luminance characteristics; and FIG. 30 shows the emission spectra. The following table shows the main characteristics of the light-emitting device 1, the comparative light-emitting device 2, and the comparative light-emitting device 3 at around 1,000 cd/M². The luminance, CIE chromaticity, and emission spectra were measured using a spectroradiometer (SR-UL1R, TOPCON TECHNOHOUSE CORPORATION). The external quantum efficiency was calculated from the luminance and the emission spectra measured from the front of the emission surface of the substrate with the spectroradiometer, on the assumption that the devices had Lambertian light-distribution characteristics.

TABLE 4

| | | Current | | | Current | External quantum |
|---|---|---|---|---|---|---|
| | Voltage | density | Chromaticity | Chromaticity | efficiency | efficiency |
| | (V) | (mA/cm²) | x | y | (cd/A) | (%) |
| Light-emitting device 1 | 3.80 | 13.8 | 0.130 | 0.179 | 9.67 | 7.55 |
| Comparative light-emitting | 3.40 | 13.7 | 0.129 | 0.100 | 6.92 | 8.31 |
| device 2 | | | | | | |
| Comparative light-emitting | 3.60 | 7.2 | 0.142 | 0.237 | 13.99 | 8.55 |
| device 3 | | | | | | |

As shown in device characteristics in FIG. 25, the light-emitting device 1, the comparative light-emitting device 2, and the comparative light-emitting device 3 can be driven at low voltages of 3.40 to 3.80 V for the luminance of 1,000 [cd/m²].

As shown in the external quantum efficiency characteristics in FIG. 29, the light-emitting device 1, the comparative light-emitting device 2, and the comparative light-emitting device 3 each have the maximum external quantum efficiency of 8% or higher, and the devices are extremely high-efficiently fluorescent devices.

Moreover, FIG. 30 shows that the 1/e widths of the EL emission spectra of the light-emitting device 1 and the comparative light-emitting device 2 are 44 nm and 35 nm, respectively, and the light-emitting device 1 and the comparative light-emitting device 2 can exhibit light with a spectrum narrower than 70 nm that is the 1/e width of the comparative light-emitting device 3. In addition, the half widths of the EL emission spectra of the light-emitting device 1 and the comparative light-emitting device 2 are 33 nm and 27 nm, respectively, and the light-emitting device 1 and the comparative light-emitting device 2 can exhibit light with a spectrum narrower than 58 nm that is the half width of the comparative light-emitting device 3.

A compound having a fluoranthene skeleton, such as CzPFlt, is used as a host material of a light-emitting layer, and a light-emitting substance is added to the light-emitting layer, resulting in abroad emission spectrum in many cases. However, it is found that the light-emitting device 1 of one embodiment of the present invention exhibits light emission with a narrower spectrum, like the comparative light-emitting device 2, and exhibits favorable characteristics as a blue fluorescent device.

That is, an organic compound with a narrow emission spectrum width such as BD-1 is used as a dopant, whereby a device with favorable characteristics can be provided. The result in Example 2 shows that the organic compound in a toluene solution, which is used as the dopant, preferably has a half width of the emission spectrum of greater than or equal to 5 nm and less than or equal to 30 nm, further preferably less than or equal to 26 nm, and a 1/e value width of greater than or equal to 5 nm and less than or equal to 48 nm, further preferably less than or equal to 45 nm.

### <Reliability Test Result>

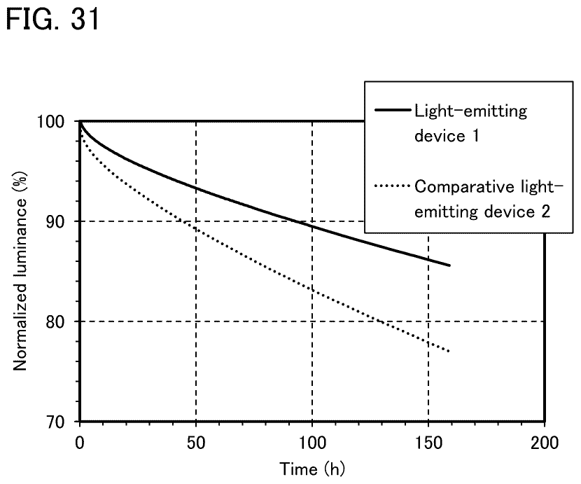

Next, reliability tests were performed on the light-emitting device 1 and the comparative light-emitting device 2. FIG. 31 shows a time-dependent change in normalized luminance at the time of constant current density driving (50 [mA/cm²]). In FIG. 31, the vertical axis represents the luminance (%) normalized with the luminance at the time of the start of emission as 100%, and the horizontal axis represents time (h).

As shown in FIG. 31, the light-emitting device 1 has a 10% deterioration time (LT90) of 93 hours and the comparative light-emitting device 2 has LT90 of 44 hours. This suggests that the device using CzPFlt as the host material in the light-emitting layer has high reliability.

It is found from the above that the light-emitting device 1 of one embodiment of the present invention in which CzPFlt, which is a kind of compound having a fluoranthene skeleton, is used as the host material in the light-emitting layer can achieve both a narrower emission spectrum and higher reliability.

### REFERENCE NUMERALS

101: first electrode, 102: second electrode, 103a: EL layer, 103B: EL layer, 103b: EL layer, 103G: EL layer, 103PS: light-receiving layer, 103R: EL layer, 103: EL layer, 104B: transport layer, 104G: transport layer, 104PS: first transport layer, 104R: transport layer, 105B: light-emitting layer, 105G: light-emitting layer, 105PS: active layer, 105R: light-emitting layer, 106a: charge-generation layer, 106b: charge-generation layer, 106: charge-generation layer, 107B: electron-injection layer, 107BG: insulating layer, 107G: insulating layer, 107R: insulating layer, 107: insulating layer, 108B: electron-transport layer, 108: electron-transport layer, 108PS: second transport layer, 108R: electron-transport layer, 109: electron-injection layer, 110B: sacrificial layer, 110G: sacrificial layer, 110PS: sacrificial layer, 110R: sacrificial layer, 111a: hole-injection layer, 111b: hole-injection layer, 111: hole-injection layer, 112a: hole-transport layer, 112b: hole-transport layer, 112: hole-transport layer, 113a: light-emitting layer, 113b: light-emitting layer, 113c: light-emitting layer, 113: light-emitting layer, 114b: electron-transport layer, 114: electron-transport layer, 115b: electron-injection layer, 115: electron-injection layer, 130: connection portion, 131: connection portion, 140: second insulating layer, 400: substrate, 401: first electrode, 403: EL layer, 404: second electrode, 405: sealant, 406: sealant, 407: sealing substrate, 412: pad, 420: IC chip, 501C: insulating film, 501D: insulating film, 504: conductive film, 506: insulating film, 508A: region, 508B: region, 508C: region, 508: semiconductor film, 510: first substrate, 512A: conductive film, 512B: conductive film, 516A: insulating film, 516B: insulating film, 516: insulating film, 518: insulating film, 520: functional layer, 524: conductive film, 528: partition wall, 530S: pixel circuit, 530X: pixel circuit, 530: pixel circuit, 531: pixel circuit, 550B: light-emitting device, 550G: light-emitting device, 550PS: light-receiving device, 550R: light-emitting device, 550S: light-receiving device, 550X: light-emitting device, 550: light-emitting device, 551B: electrode, 551C: connection electrode, 551G: electrode, 551PS: electrode, 551R: electrode, 552: electrode, 580: space, 591S: wiring, 591X: wiring, 700: light-emitting and light-receiving apparatus, 701: display region, 702G: subpixel, 702PS: subpixel, 702R: subpixel, 703: pixel, 704: circuit, 705: insulating layer, 706: wiring, 710: substrate, 711: substrate, 712: IC, 713: FPC, 720: apparatus, 770: second substrate, 800: substrate, 801a: electrode, 801b: electrode, 802: electrode, 803a: EL layer, 803b: light-receiving layer, 805a: light-emitting device, 805b: light-receiving device, 806a: layer, 806b: layer, 806: common layer, 807a: layer, 807b: layer, 807: common layer, 810A: light-emitting and light-receiving apparatus, 810B: light-emitting and light-receiving apparatus, 810: light-emitting and light-receiving apparatus, 900: glass substrate, 901: first electrode, 902: second electrode, 911: hole-injection layer, 912: hole-transport layer, 913: light-emitting layer, 914: electron-transport layer, 915: electron-injection layer, 920: quartz substrate, 921: organic compound layer, 922: counter substrate, 5200B: electronic apparatus, 5210: arithmetic device, 5220: input/output device, 5230: display portion, 5240: input portion, 5250: detecting portion, 5290: communication portion, 8001: ceiling light, 8002: foot light, 8003: sheet-like lighting, 8004: lighting device, 8005: desk lamp, 8006: light source, 8600: SGI

1.-6. (canceled)

7. A light-emitting device comprising:
at least a light-emitting layer between an anode and a cathode,
wherein the light-emitting layer comprises a first organic compound that is a light-emitting substance emitting fluorescent light and a second organic compound comprising a fluoranthene skeleton, and
wherein the first organic compound is a heterocyclic compound comprising boron.

8. A light-emitting device comprising:
at least a light-emitting layer between an anode and a cathode,
wherein the light-emitting layer comprises a first organic compound that is a light-emitting substance emitting fluorescent light and a second organic compound comprising a fluoranthene skeleton,
wherein the first organic compound is represented by General Formula (G1), 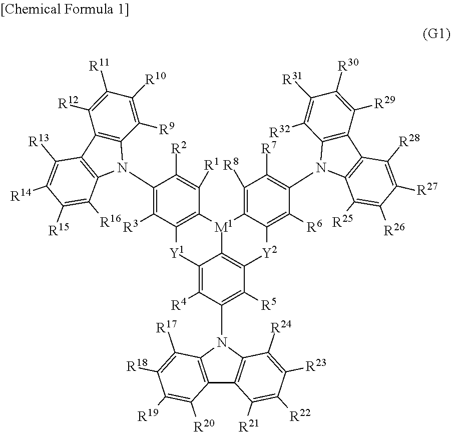
wherein M¹ represents any one of boron, nitrogen, aluminum, gallium, indium, phosphorus, arsenic, silicon, germanium, tin, antimony, and bismuth,
wherein Y¹ and Y² each independently represent any one of oxygen, sulfur, and nitrogen: when the Y¹ and the Y² are nitrogen, the nitrogen comprises a fourth substituent;
the fourth substituent is any one of a substituted or unsubstituted aryl group having 6 to 25 carbon atoms and a substituted or unsubstituted heteroaryl group having 1 to 25 carbon atoms, and
wherein R¹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

9. The light-emitting device according to claim 8,
wherein the first organic compound is represented by General Formula (G2), 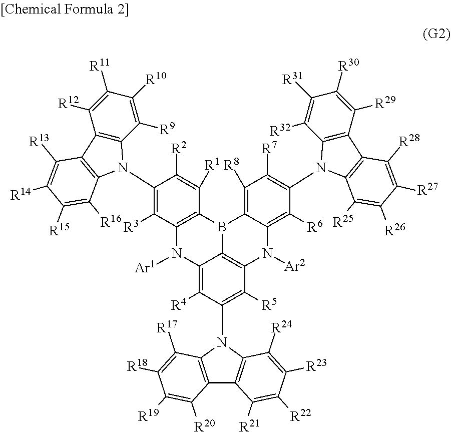
wherein Ar¹ and Ar² each independently represent any one of a substituted or unsubstituted aryl group having 6 to 25 carbon atoms and a substituted or unsubstituted heteroaryl group having 3 to 30 carbon atoms; when Ar¹ and Ar² each comprise a substituent, the substituent represents deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, or a substituted or unsubstituted aryl group having 6 to 25 carbon atoms, R¹ to R⁸ each independently represent any one of hydrogen and deuterium, and R⁹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

10. The light-emitting device according to claim 8,
wherein the first organic compound is represented by any one of Structural Formula (100) to Structural Formula (105),

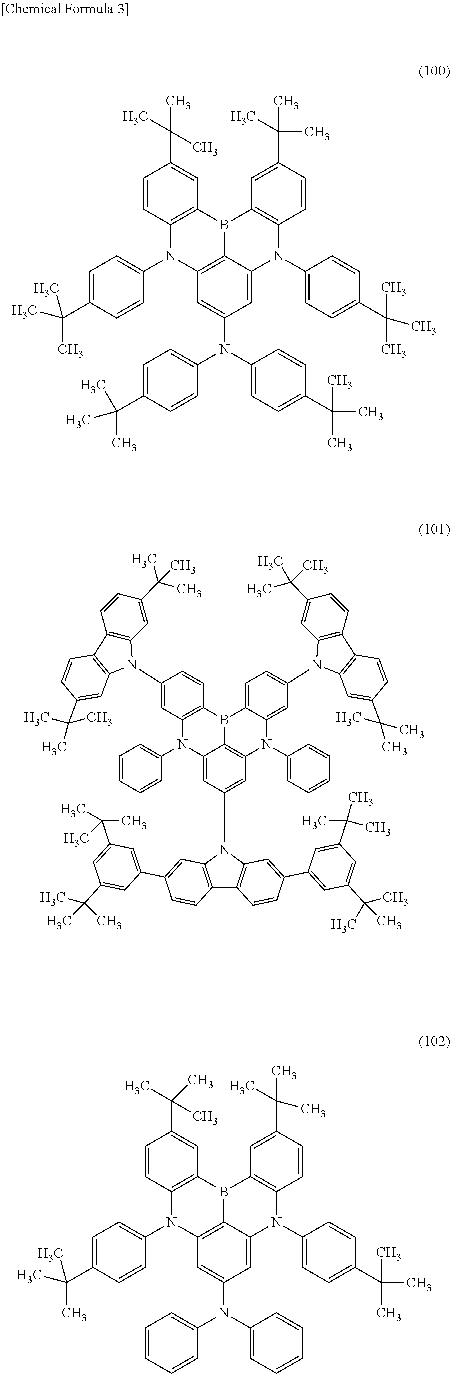

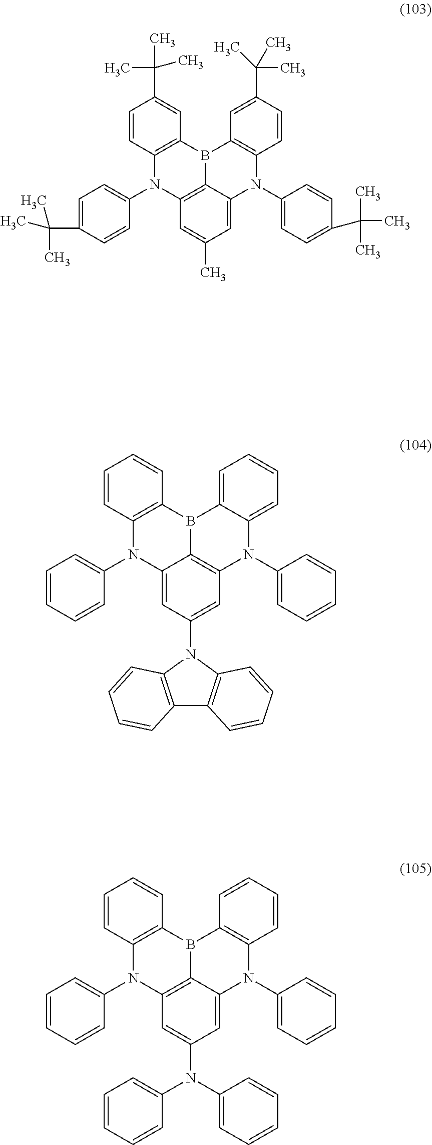 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; c1ccc(N2c3ccccc3B3c4ccccc4N(c4ccccc4)c4cc(-n5c6ccccc6c6ccccc65)cc2c43)cc1 ; c1ccc(N(c2ccccc2)c2cc3c4c(c2)N(c2ccccc2)c2ccccc2B4c2ccccc2N3c2ccccc2)cc1]

11. The light-emitting device according to claim 8,
wherein a difference between a lowest singlet excitation energy level and a lowest triplet excitation energy level of the first organic compound is 0.3 eV or greater.

12. The light-emitting device according to claim 8,
wherein the first organic compound emits blue light.

13. The light-emitting device according to claim 8,
wherein the second organic compound comprises a condensed aromatic ring or a condensed heteroaromatic ring.

14. (canceled)

15. An organic compound represented by General Formula (G3), 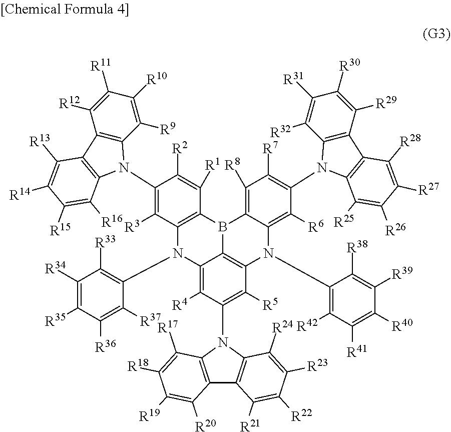
wherein R¹ to R⁸ and R³³ to R⁴² each independently represent any one of hydrogen and deuterium, and R⁹ to R³² each independently represent any one of hydrogen, deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

16. A light-emitting device comprising the organic compound represented by General Formula (G3) according to claim 15.

17.-18. (canceled)

19. A light-emitting apparatus comprising:
the light-emitting device according to claim 8; and
a transistor or a substrate.

20. An electronic device comprising:
the light-emitting apparatus according to claim 19; and
a detecting portion, an input portion, or a communication portion.

21. A lighting device comprising:
the light-emitting apparatus according to claim 19; and
a housing.

22. The light-emitting device according to claim 8,
wherein the phosphorus, the antimony, or the bismuth forms a double bond with oxygen or sulfur.

23. The light-emitting device according to claim 8,
wherein the phosphorus, the antimony, or the bismuth comprises a first substituent and a second substituent, and
wherein the first substituent and the second substituent are each independently any one of a substituted or unsubstituted alkyl group having 1 to 10 carbon atoms, an alkoxy group having 1 to 10 carbon atoms, a substituted or unsubstituted cycloalkyl group having 3 to 10 carbon atoms, and a substituted or unsubstituted aryl group having 6 to 25 carbon atoms.

24. The light-emitting device according to claim 23,
wherein a carbon atom of the first substituent and a carbon atom of the second substituent are bonded to each other with a single bond or a double bond, and
wherein a condensed ring is formed when the double bond is formed.

25. The light-emitting device according to claim 8,
wherein the silicon, the germanium, or the tin comprises a third substituent, and
wherein the third substituent is any one of a substituted or unsubstituted alkyl group having 1 to 10 carbon atoms, an alkoxy group having 1 to 10 carbon atoms, a substituted or unsubstituted cycloalkyl group having 3 to 10 carbon atoms, and a substituted or unsubstituted aryl group having 6 to 25 carbon atoms.

26. The light-emitting device according to claim 8,
wherein the aryl group or the heteroaryl group comprises a plurality of substituents, and
wherein the plurality of substituents each independently represent any one of deuterium, a substituted or unsubstituted alkyl group having 3 to 10 carbon atoms, a substituted or unsubstituted cycloalkyl group having 3 to 10 carbon atoms, a substituted or unsubstituted trialkylsilyl group having 3 to 12 carbon atoms, and a substituted or unsubstituted aryl group having 6 to 25 carbon atoms.

27. The light-emitting device according to claim 8,
wherein when R¹ and R⁸ are directly bonded to each other, one of R¹ and R⁸ is oxygen, sulfur, or nitrogen comprising a substituent,
wherein when one of R¹ and R⁸ is oxygen, an ether bond is formed,
wherein when one of R¹ and R⁸ is sulfur, a thioether bond is formed, and
wherein when one of R¹ and R⁸ is nitrogen, a secondary or tertiary amine is formed and the nitrogen comprises any one of a substituted or unsubstituted alkyl group having 3 to 10 carbon atoms, a substituted or unsubstituted cycloalkyl group having 3 to 10 carbon atoms, a substituted or unsubstituted aryl group having 6 to 25 carbon atoms, a substituted or unsubstituted heteroaryl group having 1 to 25 carbon atoms, hydrogen, and deuterium.

28. The light-emitting device according to claim 8,
wherein a maximum peak wavelength of the first organic compound is λₘₐₓ (nm), and
wherein in a case where λₙ(nm) represents a wavelength of an intensity corresponding to 1/e of a maximum peak intensity in an emission spectrum of the first organic compound, λ₁ (nm) represents the shortest wavelength λₙ in a wavelength longer than the λₘₐₓ, and λ₂ (nm) represents the longest wavelength λₙ in a wavelength shorter than λₘₐₓ, a difference between the λ₁ and the λ₂ is greater than or equal to 5 nm and less than or equal to 45 nm.

29. The light-emitting device according to claim 8,
wherein a maximum peak wavelength of the first organic compound is λₘₐₓ (nm),
wherein in a case where λₙ(nm) represents a wavelength of an intensity corresponding to 1/e of a maximum peak intensity in an emission spectrum of the first organic compound, λ₁ (nm) represents the shortest wavelength λₙ in a wavelength longer than the λₘₐₓ, and λ₂ (nm) represents the longest wavelength λₙ in a wavelength shorter than λₘₐₓ, a difference between the λ₁ and the λ₂ is greater than or equal to 5 nm and less than or equal to 45 nm, and
wherein a difference between an absorption peak located at the longest wavelength of the first organic compound and an emission peak located at the shortest wavelength of the first organic compound is 30 nm or less.
